(19) United States
(12) Patent Application Publication
(10) Pub. No.: US 2025/0070527 A1
(43) Pub. Date: Feb. 27, 2025

(54) Monolithic Integrated Enclosure

(71) Applicant: Industrial Laser Machines, LLC, Winter Park, FL (US)

(72) Inventor: Dwight Evans Kimberlin, Winter Park, FL (US)

(21) Appl. No.: 18/236,242

(22) Filed: Aug. 21, 2023

(51) Int. Cl. H01S 3/02; B33Y 80/00; H01S 3/04; H01S 3/042; H01S 3/109

(52) U.S. Cl. CPC H01S 3/025; B33Y 80/00; H01S 3/0407; H01S 3/042; H01S 3/109

(57) ABSTRACT

Techniques are disclosed for a monolithic enclosure preferably made out of metal foam for integrating any type of optoelectronic device. Only the essential elements of the optoelectronic components of the device are needed and are directly fastened into the respective pockets/cavities of the enclosure. The instant enclosure also has channels that carry electrical/electronic connections between the components, channels that allow light to travel between the components and channels that carry a coolant to/from the heated components. Preferably, the instant enclosure is 3D-printed. The present design affords better business economics by greatly reducing the required inventory of parts, complexity of design and costs compared to prevailing techniques. It also accrues many desirable technical properties to the optoelectronic device including higher optical reliability, robustness, better heat absorption and light weight among others.

### FIELD OF THE INVENTION

The present invention generally relates to construction/manufacturing and packaging of optoelectronic devices and more specifically to integrating optoelectronic devices in monolithic enclosures.

### BACKGROUND

Various types of enclosures are used to house components of apparatus, instruments and devices. Enclosures are required to house the components as well as printed circuit boards (PCBs) on which such components may have already been mounted. Enclosures are also used to include power supplies for the apparatus as well as cooling systems for transporting away the heat generated by various components of such apparatus.

There are many techniques in the prior art for making enclosures for housing components of electronic devices. U.S. Pat. No. 8,050,893 B2 to Lilley et al. discloses a method, a computer-based system and a computer-readable medium having computer-readable code. This is to accomplish creating the specifications for the fabrication of a fully customized enclosure for housing internal components. First a suitable three-dimensional (3D) template representing a basic form of the enclosure is chosen from a plurality of predetermined 3D templates and sizes. Each face of the enclosure is selected and customized by selecting specific design features from a range of predetermined design options as necessary until a complete set of specifications for the enclosure are obtained.

U.S. Patent Publication No. 2006/0207780 A1 to Shinmura et al. discloses a structural body including a first housing body accommodating electronic components and a second housing body accommodating electronic components. Fitting plane of the first and second housing bodies include a liquid passage area and a communicating passage area. The liquid passage area includes a cooling passage in which cooling liquid flows. The communicating passage area includes a communicating passage that connects housing chambers of the first and second housing bodies. Furthermore, a single sealing member is disposed on the fitting plane to independently surround and seal the liquid passage area and the communicating passage area.

U.S. Patent Publication No. 2023/0156978 A1 to Aal teaches a central compute unit configured for a vehicle and a pocket module for electronics. The main frame for mounting and connecting vehicular components in the vehicle includes a plurality of slots configured to support a plurality of pocket modules. A main frame interface is configured to connect the plurality of pocket modules with a communication network, and to couple the plurality of pocket modules with a cooling circuit.

U.S. Patent Publication No. 2022/0354028 A1 to Verhoog discusses an alveolar cooling structure configured to dissipate the heat generated by at least one electronic component placed on an upper surface of a substrate. The alveolar cooling structure remains in contact with an inner surface of the substrate. The alveolar cooling structure comprises cells, the cell edges of which increase a total contact surface between the alveolar cooling structure and a cooling fluid. The structure contains pores defined by the cells and distributed in the volume of the alveolar cooling structure. The cooling fluid circulates through the pores and/or through the spaces between the pores.

The prior art is also replete with techniques for packaging individual components of electronic devices. U.S. Patent Publication No. 2022/0127463 A1 to Waterloo et al. teaches a method of manufacturing such a package. In one example, a package for encapsulating an electronic component includes a first cured mold compound, wherein the first cured mold compound includes a resin and filler particles embedded in the resin. The filler particles include a second cured mold compound. The first cured mold compound is based on a first curing act and the second cured mold compound is based on a second curing act different from the first curing act.

U.S. Patent Publication No. 2020/0254663 A1 to Kazuno et al. describes a method of manufacturing an electronic device that includes a step of housing an electronic component in a metal mold. The metal mold is filled with a molding material, wherein the metal mold includes a cavity having a rectangular planar shape housing the electronic component. Also included is a dummy cavity communicated with a side surface having the smallest gap with the electronic component out of four side surfaces included in the cavity. The molding material inflows into the cavity in the step of filling the metal mold with the molding material, and the molding material in the cavity also inflows into the dummy cavity.

When it comes to enclosing or housing optoelectrical or optoelectronic apparatus, instruments or devices, or optoelectronic apparatus for short, the typical approach is to mount or fasten the various components onto a honeycomb plate or onto an underlying platform engineered from a suitably stiff material for providing optical stability to the components. Such a honeycomb plate is also sometimes referred to as an optical breadboard or just a breadboard. One example of such an optoelectronic apparatus is a laser resonator module, or simply a laser resonator or a laser device or module. The laser resonator/module may be a standalone apparatus or a building block of a larger laser system.

Regardless, the components of the laser module are first secured in their respective housings. The housings are then attached or fastened to their mounts and the mounts are then in turn attached/fastened to the optical breadboard or platform. The optical components or optics are also aligned or registered to each other as needed to perform their requisite functions. Now, there are two ways to align/register these optical components or optics in the traditional art.

In the first prior art approach, the optics are attached or fastened to adjustable mounts. For this purpose, an optic may be clamped in/to an adjustable mount with the aid of mounting plates or retaining rings or it may be bonded to the adjustable mount. The adjustable mount can be adjusted (via adjusting/adjustment screws) at the factory or the production facility or thereafter as needed during the operation of the device i.e. in the “field”. In short, in the first prior art approach, the optics are fastened to adjustable mounts and are aligned by adjusting these adjustable mounts.

In the second prior art approach, the optics are aligned using (temporary) external fixturing that has adjustments to align the optics. An optic is attached to the fixturing and aligned. In close proximity to the external fixturing holding the optic is a fixed or non-adjustable mount. The optic is then bonded/glued to the non-adjustable mount while maintaining the correct alignment obtained by the fixturing. Once the glue cures, the (temporary) external fixturing is removed and the optic is permanently fixed to its non-adjustable mount without being adjustable thereafter. A given prior art device may also use a combination of the above two approaches for aligning/registering its optics.

The problems with the first prior art approach include complexity of the adjustable mount with very fine pitch adjusting screws, springs, pivot points, and other parts. Furthermore, the alignment of these mounts is prone to shifting during shipping and handling due to shocks, vibrations, or thermal shifts/changes. Among the shortcomings of the second prior art approach is that an optic can shift during curing because of the difficulty of making the external fixturing rigid enough. Further, the optic can still move due to thermal shifts of its fixed/non-adjustable mount since it sticks up in the air. When either of these scenarios happens, the fixed mount cannot be adjusted. Also, the entire device/resonator must be returned to the factory if an optic gets damaged and needs to be replaced.

The optical breadboard or platform also has a substantial thickness so as to afford rigidity and stability to the optical components of the laser module and to discourage their misalignment during the operational lifetime of the system. In general, traditional laser systems are thus characterized by their size, weight, and complexity. Numerous components need to be separately manufactured, assembled and aligned. Further, they often require substantial cooling systems and are susceptible to environmental interference including vibration and electromagnetic interference.

A top view of one such optoelectronic apparatus or laser module 10 of the prior art utilizing a honeycomb breadboard plate 12 is shown in FIG. 1A. The various components of the laser module, which is a folded laser resonator, are mounted on breadboard 12. These components are first packaged in their housings. The housings are then attached to their mounts and the mounts in turn are mounted to breadboard 12. There are also electrical connections or cables and cooling hoses between various components that are not shown in FIG. 1A for clarity of the drawing. There are also accommodations for light paths between various optical components as needed for the device to perform its requisite functions.

The various components of prior art laser resonator 10 in their respective housings are as follows. There is a high-reflection (HR) mirror assembly 14, a vertical quenching switch or Q-switch 16, a horizontal Q-switch 18, a first fold/folding mirror 20, a diode pump module (DPM) assembly 22, a second fold mirror 24, a second harmonic generation (SHG) assembly 26 and an optical shutter 28 from which laser beam 30 comes out. The “Q” in Q-switch refers to the quality factor of a resonant system. In the context of lasers, the quality factor represents the efficiency of the optical cavity of the laser to store energy. Because of the folded design afforded by fold mirrors 20 and 24, prior art laser module 10 is also sometimes referred to as a folded resonator.

FIG. 1B shows a trimetric view of the prior art device 10 of FIG. 1 showing breadboard 12 onto which various components are mounted. Not all elements from FIG. 1A are marked by reference numerals in FIG. 1B to avoid repetition. FIG. 1C shows a top view picture of a complete laser device of FIG. 1A-B with all the electrical connections and cooling hoses. Again shown in FIG. 1C is the honeycomb breadboard 12 onto which various electronic and optical components are mounted. FIG. 1D shows a rear-view picture of same system 10 of FIG. 1A-C showing honeycomb breadboard plate 12 onto which the other components are mounted per above. Also shown are the interfaces of various optoelectronic connections as well as coolant ducts for the laser device. Notice the thickness of honeycomb plate 12 that is required to provide sufficient rigidity and stability to the optical components of the device so that they do not easily lose alignment.

FIG. 1E through FIG. 1L illustrate engineering drawings of the assemblies and housings of the various components of prior art system 10 of FIG. 1A-D. More specifically, FIG. 1E shows an engineering drawing of an optic mount subassembly 50 that is used by other assemblies of optoelectronic device 10. Also illustrated in FIG. 1E are the various parts required by subassembly 50 including a ball, pins, dowels, springs and various other parts as shown. For brevity, these parts are not individually marked in FIG. 1E and will be recognized by a skilled artisan.

FIG. 1F shows an engineering drawing of high reflection (HR) assembly 14 introduced earlier in reference to FIG. 1A. It is evident from FIG. 1F the multitude of parts required by assembly 14, including its optic 52, as well as screws, sockets, washer, holder and other parts as shown. Notice that HR assembly 14 utilizes optic mount subassembly 50 of FIG. 1E for holding optic 52 for the HR assembly or assy. The term “assy” is also sometimes used in literature as a short form for the term assembly.

FIG. 1G shows an engineering drawing of prior art vertical Q-switch assembly 16 of FIG. 1A. Notice again the large number of engineering parts required by the assembly including washers, screws, spacers, mounting plates, shim and other parts as shown. In a similar manner, FIG. 1H shows an engineering drawing of prior art vertical Q-switch assembly 18 of FIG. 1A. Once again, notice the large number of engineering parts required by the assembly as shown.

FIG. 1I shows an engineering drawing of a semi-exploded view of diode pump module (DPM) assembly 22 of FIG. 1A. FIG. 1J shows a fully exploded view of the main portion of DPM assembly 22 showing the laser diodes. Also shown in FIG. 1J is a configuration table 54 showing the stages of the 4-diode DPM. The four laser diodes 56A, 56B, 56C and 56D are visible in the fully exploded view of FIG. 1J while only two diodes 56A and 56D are visible in the semi-exploded view of FIG. 1I. Besides 4 laser diodes 56A-D shown in FIG. 1J of which diodes 56A and 56D are visible in FIG. 1I, notice again the large number of engineering parts required by DPM assembly 22 as shown in FIG. 1I-J. These engineering parts include a number of mounts, plates, washers, spacers, screws, rings and other engineering parts as shown.

FIG. 1K shows an engineering drawing for second harmonic generation (SHG) assembly 26 of FIG. 1A. The SHG optics include an input mirror 58A, an output mirror 58B and an SHG crystal 58C. Notice that SHG assembly 26 also utilizes our optic mount subassembly 50 of FIG. 1E as subassemblies 50A and 50B for holding input and output mirrors 58A and 58B respectively. SHG assembly 26 further includes sealed cover glasses 58D and 58E in FIG. 1K for preventing dust from entering optic mount subassemblies 50A and 50B of input and output mirrors 58A and 58B respectively. Similarly, the fold/folding mirrors 20 and 24 of FIG. 1A also utilize optic mount subassembly 50 of FIG. 1E. FIG. 1L shows an engineering drawing of prior art shutter assembly 28 of FIG. 1A.

Once again, notice from FIG. 1K-L the large number of engineering parts required by SHG and shutter assemblies 26 and 28 respectively.

Table 1 below provides the bill of materials (BOM) 1 of folded laser resonator 10 of the prior art shown in FIG. 1A-L and discussed above.

TABLE 1
Bill of Materials (BOM) 1
101849 - ASSY, RESONATOR, 18 × 18, 24 V
DPM, 2 Q-SWITCHES

| Item | Description | Qty | UM |
|---|---|---|---|
| 101323-003 | ASSY, SHG, 5 mm × 5 mm × 25 mm CRYSTAL, | 1 | ea |
| | HORIZONTAL | | |
| 100027 | BAG, DESICCANT | 2 | ea |
| 100021 | INDIUM SHEET, .004″-.006″ THICK | 0.8 | 1′ In |
| 101345 | CRYSTAL, LBO, SHG, 5 × 5 × 25 mm | 1 | ea |
| 100629 | LABEL, ILM WARRANTY VOID SEAL, 0.5″ × 1″ | 1 | ea |
| 101323-000 | SUB-ASSY, SHG, NO CRYSTAL | 1 | ea |
| 100004 | COVER, TOP, SHG HOUSING | 1 | ea |
| 100009 | PLATE, CLAMP, THERMISTOR | 1 | ea |
| 100111 | BEZEL, DUST, .70″ THRU HOLE | 2 | ea |
| 100023 | MIRROR, SHG INPUT, 1″ × ¼″, HR@532 nm, | 1 | ea |
| | HT@1064 nm | | |
| 100024 | MIRROR, SHG OUTPUT, 1″ × ¼″, | 1 | ea |
| | HR@1064 nm, HT@532 nm | | |
| 101328 | TEC, 27.9 W, QMAX, 8.6 V, 20 × 20 × 3.3 mm, SHG | 1 | ea |
| 100030 | THERMISTOR, 10K @ 20° C., EPOXY | 1 | ea |
| | ENCAPSULATED | | |
| 100034 | TERMINAL, INSULATED FEED THROUGH | 4 | ea |
| 100196 | SCREW, SHCS, 6-32 × .3125 SS | 10 | ea |
| 100240 | NUT, KEP, 10-32, SS | 4 | ea |
| 100233 | WASHER, LOCK, #2 | 4 | ea |
| 100235 | WASHER, LOCK, #6 | 4 | ea |
| 101584 | O-RING, .112 × .103, VITON | 4 | ea |
| 100017 | O-RING, 3.737 × .103, VITON | 1 | ea |
| 100019 | O-RING, .145 × .070, VITON | 4 | ea |
| 100088 | FITTING, 10-32 × ⅛″ HOSE BARB, SS | 2 | ea |
| 100036 | ASSY, SHG CABLE, 5″ LONG | 1 | ea |
| 100014 | CABLE, 4 COND, #22 AWG SHIELDED | 5 | in |
| 100412 | CONTACT, MALE, CRIMP, .093″, 18-22GA | 4 | ea |
| 100410 | CONN, 4 CIRCUIT, .093″, PLUG, 4 POS | 1 | ea |
| 100554 | WASHER, FENDER, #4, .125 ID, .344 OD, SS | 4 | ea |
| 100025 | WINDOW.19 mm × 6.35 mm, AR@1064 @ 0° C. | 1 | ea |
| 100026 | WINDOW, 19 mm × 6.35 mm AR@532 @ 0° C. | 1 | ea |
| 100018 | O-RING, .551 × .070, VITON | 2 | ea |
| 101310 | SHG HOUSING, ILM MOUNT | 1 | ea |
| 101311 | BLOCK, CRYSTAL MOUNT, SLIM, SHG | 1 | ea |
| 101312 | COVER, TERMINALS, STACKED, SHG HOUSING | 1 | ea |
| 101314 | PLATE, CRYSTAL MOUNT, .01″ THICK, 5 × 5 × | 2 | ea |
| | 18 mm CRYSTAL, SHG | | |
| 100031-ILM | SUB-ASSY, 1″ OPTIC MOUNT, SHG, TIP/TILT | 2 | ea |
| 101035 | PLATE, ADJUSTMENT, 1″ OPTIC, STAINLESS | 1 | ea |
| | STEEL | | |
| 101036 | PLATE, MOUNTING, 1″ OPTIC, STAINLESS | 1 | ea |
| | STEEL | | |
| 101040 | PIN, DOWEL, .0625″ DIA × .3125″ LONG | 4 | ea |
| 101041 | SPRING, EXTENSION, LOOP END, .138″ OD × | 2 | ea |
| | .602″ LONG, .027″ THICK, 33.06 LBS, SS | | |
| 101039 | BALL, .25″ DIA.S.S. | 1 | ea |
| 101557-001 | SCREW, ADJUSTMENT, 3/16-120 × 1″, O-RING | 2 | ea |
| | GROOVE | | |
| 101322 | WASHER, WAVE, .78 ID × 1.004 OD, .071 | 2 | ea |
| | FREE HEIGHT | | |
| 101324-001 | RETAINING RING, SM1 THREAD, 1″ OPTIC | 2 | ea |
| | MOUNT, STAINLESS STEEL | | |
| 101321 | SCREW, FHP, 6-32 × .625, SILICONE O-RING | 4 | ea |
| 100208 | SCREW, SHCS, 6-32 × .5 SS | 4 | ea |
| 101483 | WASHER, FLAT, #6, .143 ID, .267 OD, | 4 | ea |
| | .015-.018 THK | | |
| 100200 | SCREW, SHCS, 2-56 × .188 SS | 6 | ea |
| 100251 | SCREW, SHCS, 6-32 × .375 SS | 2 | ea |
| 100726 | SLEEVING, TEFLON, #18 AWG, .042 ID, .016 | 0.472 | in |
| | WALL | | |
| 101741 | SPRING, .088 OD, .625 FREE, .25 | 1 | ea |
| | COMPRESSED, 3.2 LB/IN, SS | | |
| 100191 | FITTING, ⅜ BARB × 7/16-20 THREAD, | 2 | ea |
| | WATER IN, DIODE PUMP HEAD | | |
| 100076 | SWITCH, INTERLOCK, DEFEATABLE | 2 | ea |
| 100088 | FITTING, 10-32 × ⅛″ HOSE BARB, SS | 12 | ea |
| 100121 | ASSY, DIODE POINTER | 1 | ea |
| 100073 | PLATE, PINHOLE, DIA.0.062 | 1 | ea |
| 100241 | PLATE, MOUNTING, DIODE POINTER | 1 | ea |
| 100688 | ASSY, IR-FILTERED LASER DIODE | 1 | ea |
| 100043 | ALIGNMENT LASER DIODE | 1 | ea |
| 100651 | LENS, AR-IR, 6.5 mm × 1 mm | 1 | ea |
| 100521 | LUG, FEMALE, 24-26 AWG, YELLOW, 3/16 | 2 | ea |
| | SPADE, FULLY INSULATED | | |
| 100232 | ADAPTER, DIODE POINTER, 1″ MOUNT | 1 | ea |
| 100399 | SCREW, SOCKET SET, 6-32 × .25, NYLON TIP | 1 | ea |
| 100220 | SCREW, SHCS, 8-32 × .5625 SS | 3 | ea |
| 100236 | WASHER, LOCK #8 | 2 | ea |
| 100247 | WASHER, FLAT, #8 | 2 | ea |
| 100083 | SCREW, FHP, 6-32 × .3125 SS | 2 | ea |
| 101417 | PLATE, SPACER, .25″ THK, M1-H MOUNT | 1 | ea |
| 101421 | MOUNT, TIP/TILT, 1″, M1-H | 1 | ea |
| 100122 | ASSY, HR MIRROR | 1 | ea |
| 100224 | BRACKET, MIRROR MOUNT | 1 | ea |
| 100143-001 | HOLDER, ¾″ MIRROR, .78 LONG, BRASS | 1 | ea |
| 100163-001 | ADAPTER, MIRROR HOLDER, ⅞-14 THREAD | 1 | ea |
| 100249 | WASHER, WAVE, .52″ ID, .75″ OD | 1 | ea |
| 100297 | MIRROR, HR@1064 nm, ¾″ × ⅜″, 2 mCC | 1 | ea |
| 100208 | SCREW, SHCS, 6-32 × .5 SS | 2 | ea |
| 100031-ILM-001 | SUB-ASSY, 1″ OPTIC MOUNT, HR & OC, | 1 | ea |
| | TIP/TILT | | |
| 101035 | PLATE, ADJUSTMENT, 1″ OPTIC, STAINLESS | 1 | ea |
| | STEEL | | |
| 101036 | PLATE, MOUNTING, 1″ OPTIC, STAINLESS | 1 | ea |
| | STEEL | | |
| 101040 | PIN, DOWEL, .0625″ DIA × .3125″ LONG | 4 | ea |
| 101041 | SPRING, EXTENSION, LOOP END, .138″ OD × | 2 | ea |
| | .602″ LONG, .027″ THICK, 33.06 LBS, SS | | |
| 101039 | BALL, .25″ DIA.S.S. | 1 | ea |
| 100508-001 | SCREW, ADJUSTMENT, 3/16-120 × .50 | 2 | ea |
| 100210 | SCREW, SOCKET SET, 6-32 × .25 SS | 1 | ea |
| 101279 | ASSY, HEAD, 4 mm ROD, 3-STAGE, 4 DIODES - | 1 | ea |
| | IND. STG. | | |
| 100071 | APERTURE, CERAMIC - 3.8 mm, HEAD | 2 | ea |
| 101445 | SCREW, BHCS, 6-32 × .3125 SS | 8 | ea |
| 100142 | DIODE, 3-BAR, 90 W, 806.5 nm | 4 | ea |
| 100146 | O-RING, .087 × .081, VITON | 16 | ea |
| 100148 | O-RING, .158 × .054, VITON | 24 | ea |
| 100149 | O-RING, .145 × .070, TEFLON, 4 mm ROD | 2 | ea |
| 100151 | O-RING, .364 × .070, VITON | 4 | ea |
| 100153 | O-RING, 2.487 × .103, QUAD-SEAL, VITON | 4 | ea |
| 100180 | HOUSING, HOUR METER | 1 | ea |
| 100181-3D | SPACER INSULATOR, HOUR METER | 1 | ea |
| 100183 | BEZEL, ROD CLAMPING, 4 mm | 2 | ea |
| 100190 | FLOW TUBE 7 mm × 6 mm × 5.812″ - AR COATED | 1 | ea |
| 100191 | FITTING, ⅜ BARB × 7/16-20 THREAD, | 2 | ea |
| | WATER IN, DIODE PUMP HEAD | | |
| 100192 | BEZEL, DUST TUBE & APERTURE HOLDER, HEAD | 2 | ea |
| 100202 | SCREW, SHCS, 2-56 × .25 SS | 4 | ea |
| 100207 | SCREW, DIODE CAPTIVE | 8 | ea |
| 100214 | BLOCK, HEAD CONNECTOR MOUNT | 1 | ea |
| 100216 | DIFFUSER, 2-SLOT, ADJACENT, CERAMIC | 1 | ea |
| 100217 | DUMMY MODULE, 1.68″ LONG, HEAD | 8 | ea |
| 100218 | PLATE, ROD SUPPORT, 4 mm ROD | 2 | ea |
| 101581 | PLATE, BASE, HEAD, UNIVERSAL | 2 | ea |
| 100593 | METER, LCD HOUR, PCB MOUNT | 1 | ea |
| 100653 | NdYAG ROD, 4 mm × 166 mm AR@1064, | 1 | ea |
| | FLAT/FLAT (SERIAL #:___________ ) | | |
| 100499 | LUG, #6 RING 10-12 AWG, YELLOW | 8 | ea |
| 100454 | HEATSHRINK, POLY ⅛″ BLK | 1.2 | in |
| 100503 | WIRE, #22 AWG BLACK TEFLON | 1 | ft |
| 100504 | WIRE, #22 AWG RED TEFLON | 1 | ft |
| 100505 | WIRE, #16 AWG BLACK TEFLON | 14 | in |
| 100507 | WIRE, #16 AWG GREY TEFLON | 42 | in |
| 100629 | LABEL, ILM WARRANTY VOID SEAL, 0.5″ × 1″ | 1 | ea |
| 100311 | O-RING, .277 × .076, VITON | 2 | ea |
| 100946 | RES, 100 OHM ⅛ W 1% | 1 | ea |
| 101780 | SCREW, FHH, 4-40 × .25, SS | 8 | ea |
| 100253 | SCREW, SHCS, 10-32 × .3125 SS | 4 | ea |
| 101798 | PLATE, HEAD, CENTER STAGES, O-RING | 4 | ea |
| | GROOVE | | |
| 101283 | PLATE, HEAD, FLOW TUBE CLAMP, 4 mm ROD | 2 | ea |
| 101280 | END BLOCK, HEAD, SPLIT, RING, 3.500″ OD | 2 | ea |
| 101797 | END BLOCK, HEAD, SPLIT, ROTATION PLATE, | 2 | ea |
| | 4 mm ROD | | |
| 101286 | COVER, HEAD, 3-STAGE, ELECTRICAL SIDE, | 1 | ea |
| | BRACKET MOUNT | | |
| 101287 | COVER, HEAD, 3-STAGE, WATER SIDE, | 1 | ea |
| | BRACKET MOUNT | | |
| 101284 | SPACER, HEAD, ALUMINUM, 1.360″ × .66″ × .58″ | 12 | ea |
| 101285 | BLOCK, COVER MOUNTING, HEAD | 4 | ea |
| 101294 | O-RING, .426 × .070, QUAD SEAL, VITON | 2 | ea |
| 101293 | O-RING, 1.301 × .070, QUAD SEAL, VITON | 2 | ea |
| 100927 | SCREW, SHCS, M2.5 × 0.45 × 5 mm LONG, SS | 8 | ea |
| 101721 | SCREW, FLAT HEAD TORX -PLUS, 6-32 × .50, SS | 40 | ea |
| 101437 | SCREW, FHH, 6-32 × .625 SS | 4 | ea |
| 100865 | SCREW, THP, 6-32 × .5, SS | 8 | ea |
| 101392 | FITTING, PLUG, 7/16-20, SS | 2 | ea |
| 101594 | SUB-ASSY, DPM POWER CONNECTOR | 1 | ea |
| 101686 | LABEL, SYSTEM VOLTAGE, 24 V | 1 | ea |
| 101684 | SCREW, FLAT HEAD TORX, TAMPER- | 4 | ea |
| | RESISTANT, 6-32 × .3125, SS | | |
| 100083 | SCREW, FHP, 6-32 × .3125 SS | 12 | ea |
| 100227 | DIFFUSER, 1-SLOT, CERAMIC | 2 | ea |
| 100157 | O-RING, 1.114 × .070, VITON | 2 | ea |
| 100529 | SCREW, SHCS, 4-40 × .25, SS | 6 | ea |
| 101733 | PCB ASSY, DIODE & RESISTOR, DPM | 4 | ea |
| 101777 | ASSY, SHUTTER, SENSOR PCB, METER, | 1 | ea |
| | PHOTODET, 532 nm | | |
| 100111 | BEZEL, DUST, .70″ THRU HOLE | 2 | ea |
| 100061 | COVER, TOP, SHUTTER HOUSING | 1 | ea |
| 100063 | SOLENOID, ROTARY, 45°, 24 VDC | 1 | ea |
| 100067 | LENS, SHUTTER, 12.7 mm × −12.5 mm | 1 | ea |
| 100068 | MOUNT, SHUTTER MIRROR | 1 | ea |
| 100088 | FITTING, 10-32 × ⅛″ HOSE BARB, SS | 4 | ea |
| 100196 | SCREW, SHCS, 6-32 × .3125 SS | 4 | ea |
| 100225 | SCREW, SHCS, 6-32 × 1.375 SS | 4 | ea |
| 100234 | WASHER, LOCK #4, HI-COLLAR | 2 | ea |
| 100235 | WASHER, LOCK, #6 | 4 | ea |
| 100246 | SCREW, SOCKET-SET, 4-40 × .125 SS | 2 | ea |
| 101450 | ASSY, PHOTODETECTOR | 1 | ea |
| 100408 | CONN, 2 CIRCUIT, .093″, PLUG, 2 POS | 1 | ea |
| 100412 | CONTACT, MALE, CRIMP, .093″, 18-22GA | 2 | ea |
| 100597 | LUG, #2 RING, 22-26 AWG, CLEAR YELLOW | 1 | ea |
| 100248 | PHOTODETECTOR, 200-1100 nm, 1 ns RISE | 1 | ea |
| | TIME, SM1 THREAD | | |
| 100430 | CABLE, 2 COND 24 AWG GRAY | 9 | in |
| 100453 | HEATSHRINK, POLY 3/16″ BLK | 1 | in |
| 100453-001 | HEATSHRINK, POLY 3/16″ BLK, ADHESIVE | 1 | in |
| 100301 | MIRROR, SHUTTER, HR@532 nm, 18 mm × 14 mm × | 1 | ea |
| | 3 mm | | |
| 100223 | SCREW, SHCS, 6-32 × .625 SS | 2 | ea |
| 100374 | FITTING, PLUG, 10-32, SS | 1 | ea |
| 100443 | TUBING, TYGON, ⅛″ ID, ¼″ OD, 1/16″ | 4 | in |
| | WALL, CLEAR | | |
| 100057 | POWER METER, 150 W, 532 nm | 1 | ea |
| 101544 | GASKET, 9-PIN D-SUB | 1 | ea |
| 100051-001 | JACKSCREW, 4-40 × .25, D-CONN | 2 | ea |
| 101666 | LABEL, SHUTTER, 532 nm ONLY | 1 | ea |
| 100399 | SCREW, SOCKET SET, 6-32 × .25, NYLON TIP | 1 | ea |
| 101776 | HOUSING, SHUTTER, SENSOR PCB | 1 | ea |
| 101768 | HOUSING, 5 mm LED, CHROME | 2 | ea |
| 101769 | LED, 5 mm, 3 V-12 V, WIRE LEADS, RED | 1 | ea |
| 101770 | LED, 5 mm, 3 V-12 V, WIRE LEADS, YELLOW | 1 | ea |
| 101778 | BRACKET, SENSOR PCB MOUNT, SHUTTER | 1 | ea |
| 101779 | STANDOFF, 2-56 × .50, FEMALE, ⅛″ OD, SS | 2 | ea |
| 100202 | SCREW, SHCS, 2-56 × .25 SS | 2 | ea |
| 101822 | SCREW, FHP, 2-56 × .50, SS | 2 | ea |
| 101787 | CONN, HOUSING, 2-POS, .098″ PITCH, JST | 3 | ea |
| 101806 | SOCKET, 26-30 AWG, CRIMP, TIN | 6 | ea |
| 101881 | SUB-ASSY, SHUTTER PCBS | 1 | ea |
| 101700 | PCB ASSY, SHUTTER | 1 | ea |
| 101701 | PCB ASSY, SHUTTER, PROXIMITY SENSORS | 1 | ea |
| 101800-001 | CABLE, RIBBON, 10 COND, 1″ LONG, .098″ | 1 | ea |
| | PITCH | | |
| 100194 | SCREW, FHP, 10-32 × .375 SS | 20 | ea |
| 100254 | MANIFOLD, RESONATOR | 1 | ea |
| 100342 | POST, .75″ TALL, RESONATOR SUPPORT | 3 | ea |
| 100077 | SCREW, SHCS, ¼-20 × .75 SS | 19 | ea |
| 100543 | ASSY, OUTPUT COUPLER | 1 | ea |
| 100224 | BRACKET, MIRROR MOUNT | 1 | ea |
| 100143-001 | HOLDER, ¾″ MIRROR, .78 LONG, BRASS | 1 | ea |
| 100163-001 | ADAPTER, MIRROR HOLDER, ⅞-14 THREAD | 1 | ea |
| 100278 | MIRROR, OUTPUT COUPLER, ¾″ × ⅜″, 70% | 1 | ea |
| | REFLECTIVITY AT 1064 nm | | |
| 100249 | WASHER, WAVE, .52″ ID, .75″ OD | 1 | ea |
| 100208 | SCREW, SHCS, 6-32 × .5 SS | 2 | ea |
| 100031-ILM-001 | SUB-ASSY, 1″ OPTIC MOUNT, HR & OC, | 1 | ea |
| | TIP/TILT | | |
| 101035 | PLATE, ADJUSTMENT, 1″ OPTIC, STAINLESS | 1 | ea |
| | STEEL | | |
| 101036 | PLATE, MOUNTING, 1″ OPTIC, STAINLESS | 1 | ea |
| | STEEL | | |
| 101040 | PIN, DOWEL, .0625″ DIA × .3125″ LONG | 4 | ea |
| 101041 | SPRING, EXTENSION, LOOP END, .138″ OD × | 2 | ea |
| | .602″ LONG, .027″ THICK, 33.06 LBS, SS | | |
| 101039 | BALL, .25″ DIA.S.S. | 1 | ea |
| 100508-001 | SCREW, ADJUSTMENT, 3/16-120 × .50 | 2 | ea |
| 100210 | SCREW, SOCKET SET, 6-32 × .25 SS | 1 | ea |
| 100544 | ASSY, TARGET | 1 | ea |
| 100073 | PLATE, PINHOLE, DIA.0.062 | 1 | ea |
| 100241 | PLATE, MOUNTING, DIODE POINTER | 1 | ea |
| 100211 | SCREW, FHP, 6-32 × .375 SS | 2 | ea |
| 101434 | FITTING, ½ BARB TO ⅝-18 THREAD, SS | 2 | ea |
| 100484 | ASSY, Q-SWITCH MOUNT, HORIZONTAL | 1 | ea |
| 100242 | PLATE, Q-SWITCH/FIBER FOCUS | 1 | ea |
| 101158 | PLATE, SPACER, HORIZONTAL Q-SWITCH, | 1 | ea |
| | .25″ THK | | |
| 101161 | PLATE, MOUNTING, HORIZONTAL Q-SWITCH, | 1 | ea |
| | .125″ THK | | |
| 100213 | SCREW, SHCS, 8-32 × .5 SS | 3 | ea |
| 100236 | WASHER, LOCK #8 | 3 | ea |
| 100243 | SCREW, SHCS, 6-32 × .25 SS | 3 | ea |
| 101276-001 | SUB-ASSY, TIP/TILT MOUNT, Q-SWITCH | 1 | ea |
| 101154-001 | BRACKET, ADJUSTMENT, HORIZONTAL Q- | 1 | ea |
| | SWITCH, STAINLESS STEEL | | |
| 101155-001 | BRACKET, MOUNTING, HORIZONTAL Q-SWITCH, | 1 | ea |
| | STAINLESS STEEL | | |
| 101039 | BALL, .25″ DIA.S.S. | 1 | ea |
| 101040 | PIN, DOWEL, .0625″ DIA × .3125″ LONG | 4 | ea |
| 101041 | SPRING, EXTENSION, LOOP END, .138″ OD × | 2 | ea |
| | .602″ LONG, .027″ THICK, 33.06 LBS, SS | | |
| 100508-002 | SCREW, ADJUSTMENT, 3/16-120 × .75 | 1 | ea |
| 100508-003 | SCREW, ADJUSTMENT, 3/16-120 × 1.5″ | 1 | ea |
| 101483 | WASHER, FLAT, #6, .143 ID, .267 OD, | 3 | ea |
| | .015-.018 THK | | |
| 100247 | WASHER, FLAT, #8 | 3 | ea |
| 101715 | SCREW, FHP, 8-32 × .625, SS | 4 | ea |
| 100443 | TUBING, TYGON, ⅛″ ID, ¼″ OD, 1/16″ | 10 | ft |
| | WALL, CLEAR | | |
| 100431 | WIRE TIE MOUNT, ¼-20 SCREW | 5 | ea |
| 100721 | WASHER, SHIM, ¼ ID, ⅜ OD, .025 THK, SS | 22 | ea |
| 100587 | HOSE CLAMP, ¼″ TO ⅝″ | 4 | ea |
| 100588 | HOSE CLAMP, ⅜″ TO ⅞″ | 2 | ea |
| 100980 | ASSY, LEAK DETECTOR | 1 | ea |
| 100464 | SENSOR, LEAK DETECTOR | 1 | ea |
| 100410 | CONN, 4 CIRCUIT, .093″, PLUG, 4 POS | 1 | ea |
| 100412 | CONTACT, MALE, CRIMP, .093″, 18-22GA | 4 | ea |
| 100504 | WIRE, #22 AWG RED TEFLON | 5 | in |
| 100503 | WIRE, #22 AWG BLACK TEFLON | 3 | in |
| 100498 | SCREW, BHCS, ¼-20 × .375 | 1 | ea |
| 100547 | CABLE, 4 COND 24 AWG GRAY, SHIELDED | 8 | in |
| 101592-3D | CLAMP, CABLE, LEAK DETECTOR | 6 | ea |
| 100453 | HEATSHRINK, POLY 3/16″ BLK | 16 | in |
| 100454 | HEATSHRINK, POLY ⅛″ BLK | 4 | in |
| 101855 | CONVERTER, DC-DC, 3.3 V, 3.3 W | 1 | ea |
| 101856 | RELAY, DPDT, 3 VDC, 1A | 1 | ea |
| 101865 | PCB BARE BOARD, LEAK DETECTOR | 1 | ea |
| 100609 | TAPE, VINYL PINSTRIPE, 2″, WHITE | 2 | in |
| 100428 | CLAMP, REFERENCE, ¼ × 1.5″ SLOT | 4 | ea |
| 101165 | ASSY, Q-SWITCH MOUNT, VERTICAL | 1 | ea |
| 100242 | PLATE, Q-SWITCH/FIBER FOCUS | 1 | ea |
| 100161 | PLATE, ADJUSTMENT, VERTICAL Q-SWITCH | 1 | ea |
| 100162 | PLATE, MOUNTING, VERTICAL Q-SWITCH | 1 | ea |
| 101090 | POST, HEX, .375 DIA × .625 LONG, 6-32 | 1 | ea |
| | THREAD, Q-SWITCH LOCKING | | |
| 101091 | SPACER, #6 CLEARANCE × ⅛″ THK × ½″ OD | 2 | ea |
| 101092 | BUSHING, BRONZE FLANGED, .3135 ID × .502 | 1 | ea |
| | OD × ⅜ LONG | | |
| 101093 | SPRING, COMPRESSION, 1.25/.635 LONG × | 1 | ea |
| | .480 OD × 58.5 LBS | | |
| 101094 | SPRING, COMPRESSION, SS, .500″/.265″ | 1 | ea |
| | LONG × .480″ × 98.0 LBS | | |
| 101095 | SCREW, ADJUSTMENT, ¼-80 × .85″, SS | 1 | ea |
| 101100 | SCREW, SHSS, ¼-20 × .438 THREAD, .312 | 1 | ea |
| | SHOULDER DIA.× .75 SHOULDER LENGTH | | |
| 100541 | SCREW, SHCS, 8-32 × .75 SS | 2 | ea |
| 100208 | SCREW, SHCS, 6-32 × .5 SS | 1 | ea |
| 100223 | SCREW, SHCS, 6-32 × .625 SS | 3 | ea |
| 100236 | WASHER, LOCK #8 | 2 | ea |
| 100247 | WASHER, FLAT, #8 | 2 | ea |
| 100721 | WASHER, SHIM, ¼ ID, ⅜ OD, .025 THK, SS | 2 | ea |
| 100085 | SCREW, BHCS, 6-32 × .625 SS | 1 | ea |
| 100555 | HOSE, ½″ ID, NYLON REINFORCED | 24 | ft |
| 100556 | HOSE, ⅜″ ID, NYLON REINFORCED | 22 | in |
| 100907 | Q-SWITCH, 27.12 MHz, 4 mm APERTURE, SHEAR | 2 | ea |
| | WAVE, FS, G&H | | |
| 100907-000 | Q-SWITCH, 27.12 MHz, 4 mm APERTURE, SHEAR | 1 | ea |
| | WAVE, FS, G&H | | |
| 100230-001 | BEZEL, Q-SWITCH, PRESS-FIT, G&H | 2 | ea |
| 101468 | VIBRATION ISOLATOR, .75″ TALL, ¼-20 | 3 | ea |
| | STUD & TAP, MALE TO FEMALE, 95LBS | | |
| 101429 | HOSE CLAMP, 17.8 TO 21 mm | 2 | ea |
| 101587 | HOSE CLAMP, SPRING, ¼ ID | 20 | ea |
| 101826 | TABLE, BREADBOARD, 18″ × 18″ 2.3′ | 1 | ea |
| 101831 | BULKHEAD, 17.25″ × 4.50″, OUTPUT | 1 | ea |
| 101832 | BULKHEAD, 17.25″ × 4.50″, SIDE | 3 | ea |
| 101833 | PLATE, ELECTRICAL CONNECTIONS, | 1 | ea |
| | RESONATOR | | |
| 101834 | COVER, 18″ × 18″, RESONATOR | 1 | ea |
| 101246 | CONN, BNC-BNC, ISOLATED | 3 | ea |
| 101838 | CONN, SMA, FEMALE, 50 OHM, BULKHEAD MOUNT | 3 | ea |
| 101842 | GASKET, 25-PIN D-SUB | 1 | ea |
| 101843 | GASKET, DIODE POWER CONN | 1 | ea |
| 101844 | RETAINING RING, M20.5 × 0.5, ALUMINUM | 1 | ea |
| 101845 | O-RING, .926 × .070, VITON | 2 | ea |
| 101846 | SCREW, FHP, ¼-20 × .75, SILICONE O-RING | 2 | ea |
| 101847 | GASKET STRIP, ¾″ × 36″, SILICONE, | 156 | in |
| | ADHESIVE-BACK | | |
| 101850 | SWITCH, POWER, GASKETED, DIODE POINTER | 1 | ea |
| 100016 | O-RING, .208 × .070, VITON | 3 | ea |
| 101852 | O-RING, 4.379 × .070, VITON | 1 | ea |
| 101851 | ASSY, FOLD MIRROR, 1″ | 2 | ea |
| 100031-ILM-001 | SUB-ASSY, 1″ OPTIC MOUNT, HR & OC, | 1 | ea |
| | TIP/TILT | | |
| 101837 | BRACKET, FOLD MIRROR | 1 | ea |
| 101840 | MIRROR, 1″ × 6 mm, 45° AOI, 99.9%, FS | 1 | ea |
| 101324-001 | RETAINING RING, SM1 THREAD, 1″ OPTIC | 1 | ea |
| | MOUNT, STAINLESS STEEL | | |
| 101322 | WASHER, WAVE, .78 ID × 1.004 OD, .071\| | 1 | ea |
| | FREE HEIGHT | | |
| 101848 | SCREW, FHP, 6-32 × .75 SS | 2 | ea |
| 101853 | SCREW, BHCS, ¼-20 × .625, SS | 1 | ea |
| 100083 | SCREW, FHP, 6-32 × .3125 SS | 4 | ea |
| 100560 | BRACKET, INTERLOCK SWITCH, RESONATOR | 2 | ea |
| 101857 | SCREW, FHP, M4 × 8 mm, VITON O-RING, SS | 4 | ea |
| 100298 | LED, RED, 24 VDC, 16 mm PANEL MOUNT, | 1 | ea |
| | RESONATOR | | |
| 100299 | LED, YELLOW, 24 VDC, 16 mm PANEL MOUNT, | 1 | ea |
| | RESONATOR | | |
| | | 1078.472 | Total |
| | | | Qty |

Notice from BOM 1 of Table 1 above the large number of parts or items required by the prior art design. The total quantity of parts in the prior art laser resonator 10 of FIG. 1A-L is 1078 per above. Thus, a difficulty with the prior art techniques is that they require a large number of engineering parts to support the essential elements, such as the optics of optoelectronic or optoelectrical components. These parts are required to construct the housings and assemblies around the essential elements. In most cases, each housing is then mounted to a mount and which is then mounted onto a thick honeycomb breadboard 12 for providing stability to the device as shown and discussed in reference to FIG. 1A-L above. Sometimes, the housing may also be mounted directly to the breadboard.

Regardless, the large number of parts in the prior art need to be machined or manufactured and this increases the cost and production times of the final or end device/product. This complexifies the supply chain of the device. The plethora of parts, including the thick honeycomb breadboard, mounts and housings require additional raw materials to produce that increases the overall weight and cost of the system. This also increases shipping and handling costs for the prior art products.

Moreover, additional steps for the alignment of optics are required to be performed after mounting in the traditional approaches. Such steps further increase the labor and production costs of the product, leading to poor business economics.

Further, unless extreme care is exercised during shipping and handling, the above alignment in the prior art devices is sensitive to mechanical disturbances, which could lead to misalignment. This in turn could lead to poor performance and/or malfunctioning of the devices during operation and overall diminution of reliability.

Furthermore, prior art devices require deionized water under pressure as coolant. Deionized water is used along with a deionizing filter and an ultra-violet (UV) sterilizer. This further necessitates using non-galvanic materials such as stainless steel for all wetted surfaces to keep the water pure and to prevent the build-up of algae as well as galvanization and/or photo-plating of ions on the optical flow tube, laser rod, and other optical components. All of the above increases the cost of the system.

### OBJECTS OF THE INVENTION

In view of the shortcomings of the prior art, it is an object of the invention to provide techniques for a monolithic enclosure in which optoelectronic apparatus/devices can be integrated or embedded.

It is also an object of the invention to construct/produce such a monolithic enclosure from metal foam.

It is also an object of the invention to construct/produce such a monolithic enclosure from a carbon-based material such as carbon fiber, carbon nanotubes and graphene.

It is further an object of the invention to include pockets/cavities in the monolithic enclosure in which various components of the optoelectronic apparatus/device can be fastened/housed.

It is also an object of the invention to include channels in the monolithic enclosure for carrying electrical connections between the components of the optoelectronic apparatus/device.

It is also an object of the invention to contain channels through which light can travel between various components of the optoelectronic apparatus/device.

It is also an object of the invention to include channels through which a coolant can travel to/from the heated components of the optoelectronic apparatus/device.

It is also an object of the invention to 3D-print such a monolithic enclosure.

It is further an object of the invention to have an infill pattern for the monolithic enclosure.

It is also an object of the invention to not require deionized water as a coolant for the optoelectronic apparatus/device.

Still other objects and advantages of the invention will become apparent upon reading the summary and the detailed description in conjunction with the drawing figures.

### SUMMARY OF THE INVENTION

A number of objects and advantages of the invention are achieved by apparatus and methods for a monolithic enclosure of an optoelectronic apparatus or device. The monolithic enclosure of the present design is preferably made out of metal foam or metallic foam and in it the components of the optoelectronic apparatus/device are integrated. Alternatively, the instant monolithic enclosure is constructed out of a carbon-based material including carbon fiber, carbon nanotubes and graphene. The instant monolithic integrated enclosure may also be referred to as an integrated monolithic enclosure or an integrated enclosure or a monolithic enclosure.

There are various advantageous properties found in metal foam that make it suitable for constructing an instant monolithic enclosure of the preferred embodiments. Many of these properties are shared by carbon-based source materials (or just materials for short) used for producing the instant enclosure of the alternative embodiments. These properties include among others, high tensile strength, elevated stiffness/rigidity, light weight, high energy absorption and damping, high thermal insulation and large surface area as well as internal and external electromagnetic interference (EMI) shielding.

The optoelectronic apparatus/device comprises various components. The components may be purely electronic components such as microprocessors, microcontrollers, integrated circuits (ICs) in general, resistors, capacitors and the like. Alternatively or in addition, the components may be purely optical components, such as lenses, mirrors, prisms and the like.

Still alternatively or in addition, the components may be optical-electric or optical-electronic or optoelectronic components for short, consisting of a combination of optical and electrical/electronic elements. Exemplarily, such optoelectronic components include photodiodes (including solar cells), phototransistors, photomultipliers, opto-isolators, integrated optical circuit (IOC) elements, photoresistors, photoconductive camera tubes, charge-coupled devices (CCDs), laser diodes, quantum cascade lasers, light-emitting diodes, optocouplers and the like.

According to the chief aspects, there are a number of pockets or cavities built into the instant integrated enclosure into which are integrated the components of the optoelectronic apparatus/device, such as the ones mentioned above. The integration is accomplished by directly fastening/attaching/bolting/screwing only the essential elements of the components into the enclosure, and more specifically in the pockets/cavities of the enclosure. As a result, the present design eliminates the need for complex housings and mounts that the essential elements of optoelectronic components require in the prior art.

The monolithic enclosure of the present design also has a set of channels for housing and routing electrical/electronic connections between the various components of an instant optoelectronic device. Such connections may take the form of electrical wires or cables, fiberoptic cables, harnesses or any other electrical/electronic interconnects weaved through the connection channels. In short, the first set of channels referred to as connection channels or wiring channels accommodates connections that electrically connect the requisite components to operate the optoelectronic device.

The monolithic enclosure of the present design also has another set of channels for serving as sealed optical paths for light to propagate or travel between the various or optical optoelectronic components of the instant device. These channels, referred to as optical channels, may be used for transmitting and receiving laser beams between the optoelectronic components, and more specifically their optical elements.

The monolithic integrated enclosure of the present design has yet another set of channels for flowing a coolant or cooling fluid to and from various components of the instant device that require cooling. Referred to as coolant channels, these channels transport a coolant, such as water, towards a heated component integrated into the instant enclosure. Because of the large surface area afforded by these channels integrated into the instant enclosure, a more effective heat-exchange from the heated component to the coolant in these channels takes place than the prior art techniques.

The heat absorbing coolant is then brought away from the heated components in these coolant channels and outside of the enclosure for recycling and/or replenishment. Preferably, the coolant utilized in enclosures of the present design is non-deionized water or simply “tap water”. The inside surfaces of the above-mentioned channels of an instant enclosure are solid and smooth and have a given thickness. This ensures hermetic sealing of those channels and consequently of the enclosure. Furthermore, any other internal/external surfaces of the enclosure are also solid and smooth for bonding, and for aesthetic purposes.

In a preferred embodiment, the optoelectronic device integrated into the present metallic foam based monolithic enclosure is a laser apparatus, device or module. A laser module typically contains a variety of optoelectronic components and is ideally suited to benefit from the instant enclosure. Preferably, the optoelectronic components, and more specifically their optical elements, integrated into the instant enclosure are pre-aligned or pre-registered by or within the enclosure. This means that there is no need for performing a separate step of alignment of these optical components post-production as in the techniques of the prior art. Based on the present principles, there is also no need of realignment in the field or returning the device to the factory when an optic needs replacing/replacement.

As mentioned, the instant monolithic enclosure is made out of one of various materials including metallic foams as well as carbon-based materials including but not limited to carbon fiber, carbon nanotubes and graphene. These materials offer a number of desirable properties to the instant enclosure, some of which were mentioned above. As a result, the instant enclosure has a much higher degree of optical stability and precision of the optoelectronic components than otherwise possible. Consequently, the frequency of light used in a laser module integrated into an instant enclosure can be easily multiplied or increased in various embodiments. This increase can be up to doubling of the frequency, tripling, quadrupling or even more. Also, ultrafast lasers including picosecond, femtosecond and attosecond lasers can easily be produced by the present technology.

In the preferred embodiments, the monolithic enclosure of the present design is produced or printed by a three-dimensional printer or a 3D-printer. For this purpose, a 3D model of the enclosure containing all its features is preferably created first, and then provided to the printer for 3D-printing. Advantageously, the 3D-printer can also be used to produce a variety of desirable infill patterns for the enclosure depending on the variations of the present embodiments. The infill patterns may be chosen according to the requirements of a given application of the present technology.

In alternate embodiments, the present enclosure may also be machined from a slab of the source material which is preferably metal foam. The metal foam slab may itself have a desired infill pattern. Still alternatively, the instant monolithic enclosure may be produced by a casting process that utilizes a liquid metal foam poured into a mold to produce the instant enclosure. In the same or related embodiments, the metal foam that the instant enclosure is composed of primarily comprises an aluminum compound or alloy. Alternatively, the metal foam may comprise of any other suitable compound or alloy of metals including copper, nickel, titanium, steel, magnesium and zinc or be composed of any other suitable material.

As a result of the present design, a practitioner achieves much better business economics for producing optoelectronic apparatus/devices that are functionally equivalent to prior art apparatus/devices. This is because the present principles greatly reduce the required inventory of parts, complexity of design and costs as compared to prevailing techniques.

The present approach also has the very desirable attribute that the enclosures as well as any custom designs can be “printed on demand”. This obviates the need to buy large quantities of parts to achieve economy of scale, and without scrapping of obsolete parts when the design is changed. The present design also accrues many desirable technical properties to the optoelectronic device including higher optical reliability, robustness, better heat absorption and light weight among others.

The systems of the present technology provide a monolithic enclosure comprising one or more pockets for integrating components of an optoelectronic apparatus, at least one connection channel for connecting two or more of said components, at least one optical channel for propagating light between two or more of said components and at least one coolant channel for transporting a coolant to and from at least one of said components. The monolithic enclosure is preferably made out of metal foam. Alternatively, it is made out of a suitable carbon-based material including carbon fiber, carbon nanotubes and graphene.

The methods of the present technology comprise the steps of (a) integrating components of an optoelectronic device into one or more cavities of a monolithic enclosure, said monolithic enclosure composed of a metal foam or a suitable carbon-based material, (b) connecting two or more of said components via a first channel of said monolithic enclosure, (c) propagating light between two or more of said components in a second channel of said monolithic enclosure, and (d) transporting in a third channel of said monolithic enclosure, a coolant to and from at least one of said components.

Clearly, the system and methods of the invention find many advantageous embodiments. The details of the invention, including its preferred embodiments, are presented in the below detailed description with reference to the appended drawing figures.

### BRIEF DESCRIPTION OF THE DRAWING FIGURES

FIG. 1A shows a top view of a prior art folded laser resonator whose components are mounted on/to a traditional honeycomb or optical breadboard.

FIG. 1B is a trimetric view of the prior art folded laser resonator of FIG. 1A.

FIG. 1C is a top view picture of the prior art folded laser resonator of FIG. 1A-B.

FIG. 1D is a rear view picture of the prior art folded laser resonator of FIG. 1A-C.

FIG. 1E is an engineering drawing of an optic mount required in the prior art folded laser resonator of FIG. 1A-D.

FIG. 1F is an engineering drawing of a high reflection (HR) mirror assembly of the prior art folded laser resonator of FIG. 1A-E.

FIG. 1G is an engineering drawing of a vertical quenching switch (Q-switch) of the prior art folded laser resonator of FIG. 1A-F.

FIG. 1H is an engineering drawing of a horizontal quenching switch (Q-switch) of the prior art folded laser resonator of FIG. 1A-G.

FIG. 1I-J are engineering drawings of a diode pump module (DPM) assembly of the prior art folded laser resonator of FIG. 1A-H.

FIG. 1K is an engineering drawing of a second harmonic generation (SHG) assembly of the prior art folded laser resonator of FIG. 1A-J.

FIG. 1L is an engineering drawing of a shutter assembly of the prior art folded laser resonator of FIG. 1A-K.

FIG. 2A is a three-dimensional (3D) isometric view of an empty monolithic integrated enclosure or an empty integrated monolithic enclosure or an empty integrated enclosure or an empty monolithic enclosure for a folded laser resonator based on the instant principles.

FIG. 2B shows a 3D transparent hidden-lines isometric view of the instant monolithic enclosure of FIG. 2A with various components of the folded laser resonator integrated.

FIG. 2C shows a 3D solid isometric view of the instant monolithic enclosure of FIG. 2A with various components of the folded laser resonator integrated.

FIG. 2D shows a 3D transparent hidden-lines exploded isometric view of the instant monolithic enclosure of FIG. 2A with various components of the folded laser resonator integrated.

FIG. 2E shows a 3D solid exploded isometric view of the instant monolithic enclosure of FIG. 2A with various components of the folded laser resonator integrated.

FIG. 2F shows a 3D transparent hidden-lines top view of the instant monolithic enclosure of FIG. 2A with various components of the folded laser resonator integrated.

FIG. 2G shows a 3D solid top view of the instant monolithic enclosure of FIG. 2A with various components of the folded laser resonator integrated.

FIG. 2H shows a 3D transparent hidden-lines front view of the instant monolithic enclosure of FIG. 2A with various components of the folded laser resonator integrated.

FIG. 2I shows a 3D solid front view of the instant monolithic enclosure of FIG. 2A with various components of the folded laser resonator integrated.

FIG. 2J shows a 3D transparent hidden-lines left view of the instant monolithic enclosure of FIG. 2A with various components of the folded laser resonator integrated.

FIG. 2K shows a 3D transparent hidden-lines right view of the instant monolithic enclosure of FIG. 2A with various components of the folded laser resonator integrated.

FIG. 3A shows a 3D transparent hidden-lines trimetric view of an instant integrated enclosure with various components of an in-line laser resonator integrated.

FIG. 3B shows a 3D solid trimetric view of the in-line laser resonator of FIG. 3A integrated in/inside an instant monolithic enclosure.

FIG. 3C shows a 3D transparent hidden-lines top view of the in-line laser resonator of FIG. 3A integrated in an instant monolithic enclosure.

FIG. 3D shows a 3D solid top view of the in-line laser resonator of FIG. 3A integrated in an instant monolithic enclosure.

FIG. 3E shows a 3D transparent hidden-lines front view of the in-line laser resonator of FIG. 3A integrated in an instant monolithic enclosure.

FIG. 3F shows a 3D solid front view of the in-line laser resonator of FIG. 3A integrated in an instant monolithic enclosure.

FIG. 3G shows a 3D transparent hidden-lines rear view of the in-line laser resonator of FIG. 3A integrated in an instant monolithic enclosure.

FIG. 3H shows a 3D solid rear view of the in-line laser resonator f FIG. 3A integrated in an instant monolithic enclosure.

FIG. 3I shows a 3D transparent hidden-lines left view of the in-line laser resonator of FIG. 3A integrated in an instant monolithic enclosure.

FIG. 3J shows a 3D transparent hidden-lines right view of the in-line laser resonator of FIG. 3A integrated in an instant monolithic enclosure.

FIG. 4 shows exemplary infill patterns with a variety densities or porosities for instant monolithic enclosures.

FIG. 5 shows exemplary types or geometric shapes for instant monolithic enclosures.

### DETAILED DESCRIPTION

The figures and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable, similar or like reference numbers may be used in the figures and may indicate similar or like functionality. The figures depict embodiments of the present invention for purposes of illustration only. One skilled in the art will readily recognize from the following description that alternative embodiments the structures and methods illustrated herein may be employed without departing from the principles of the invention described herein.

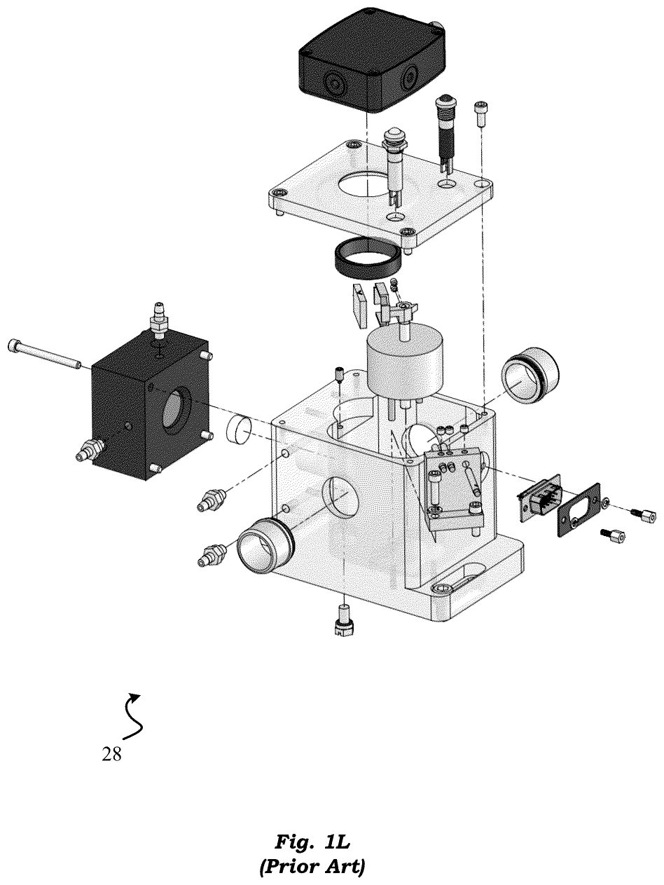

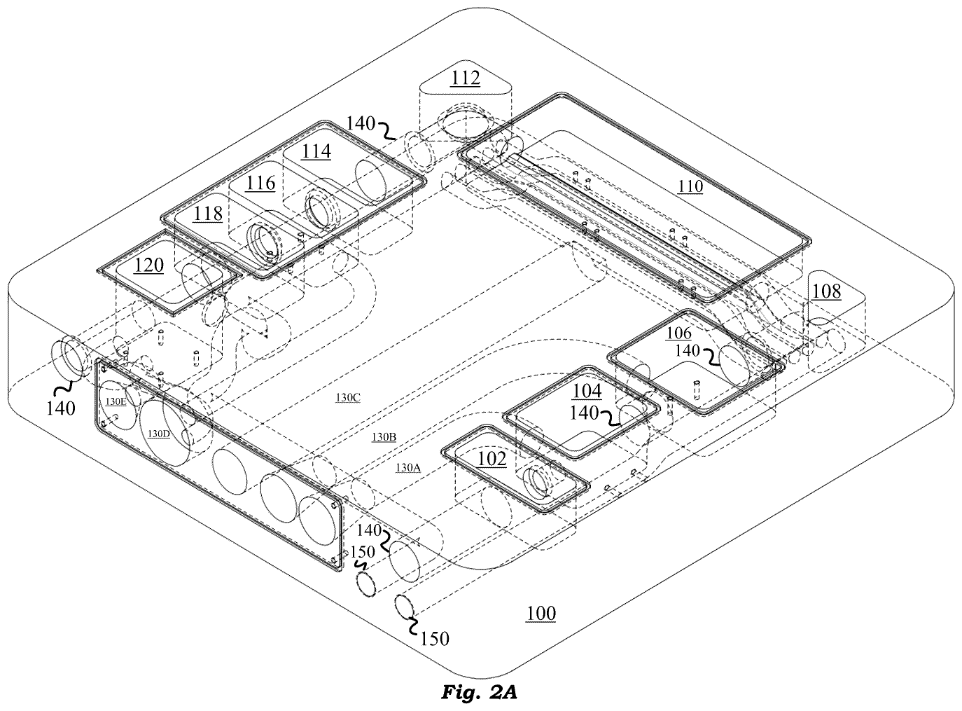

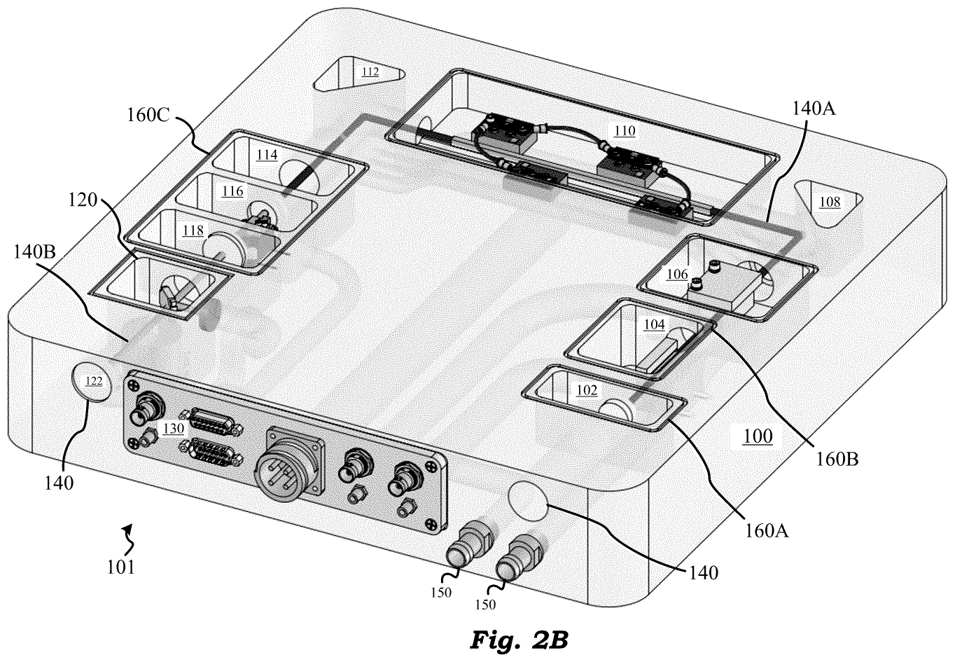

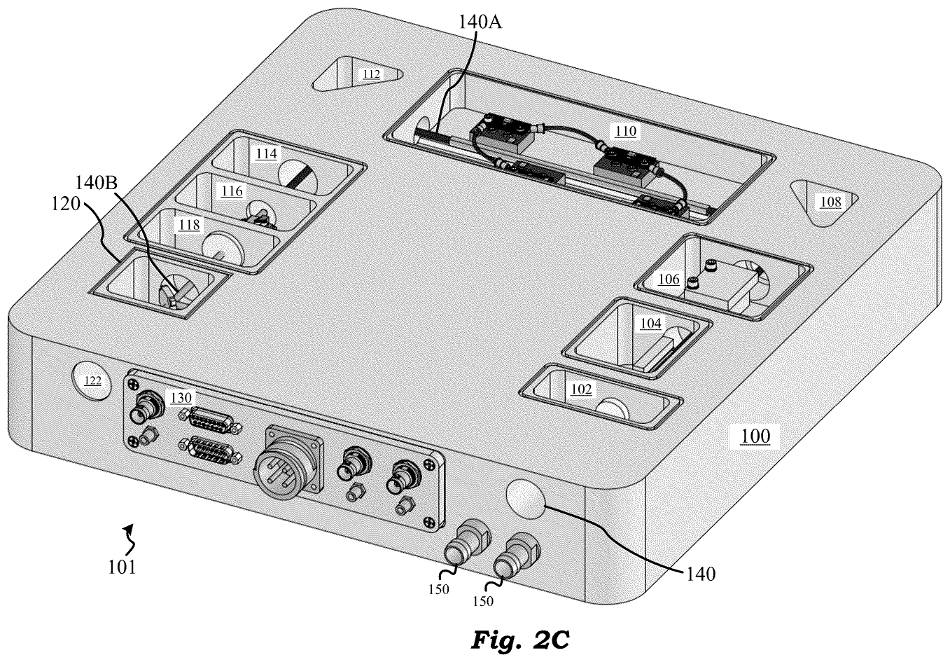

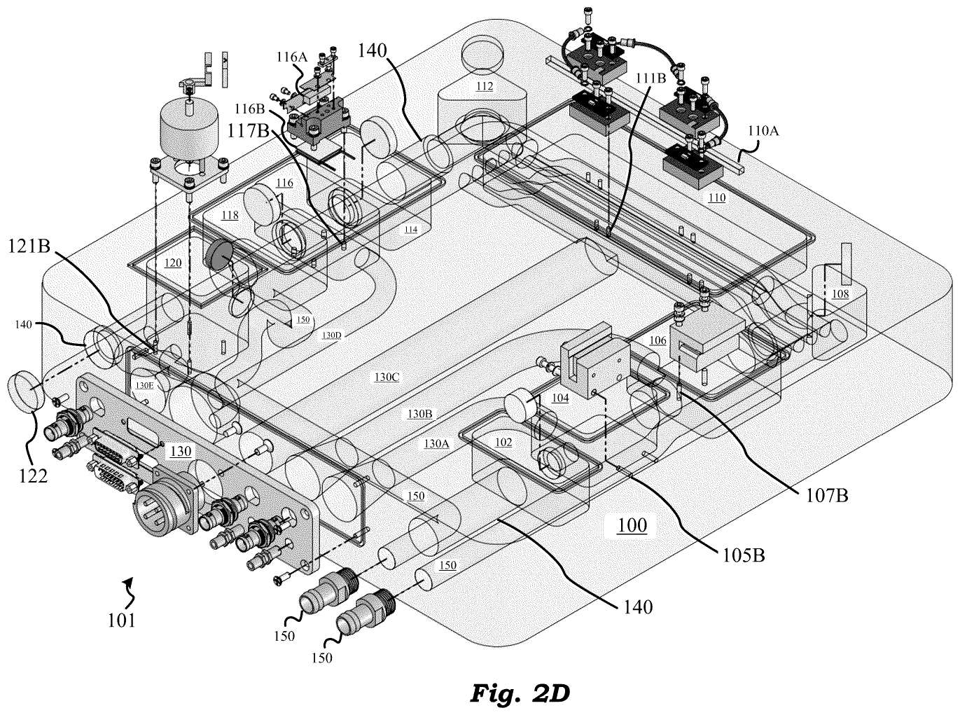

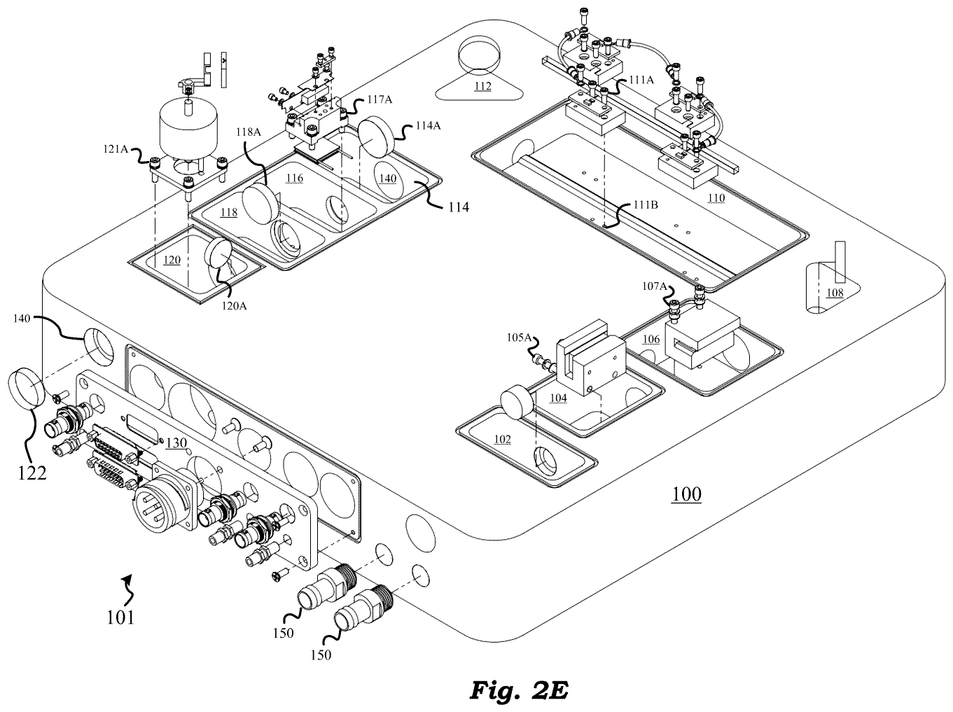

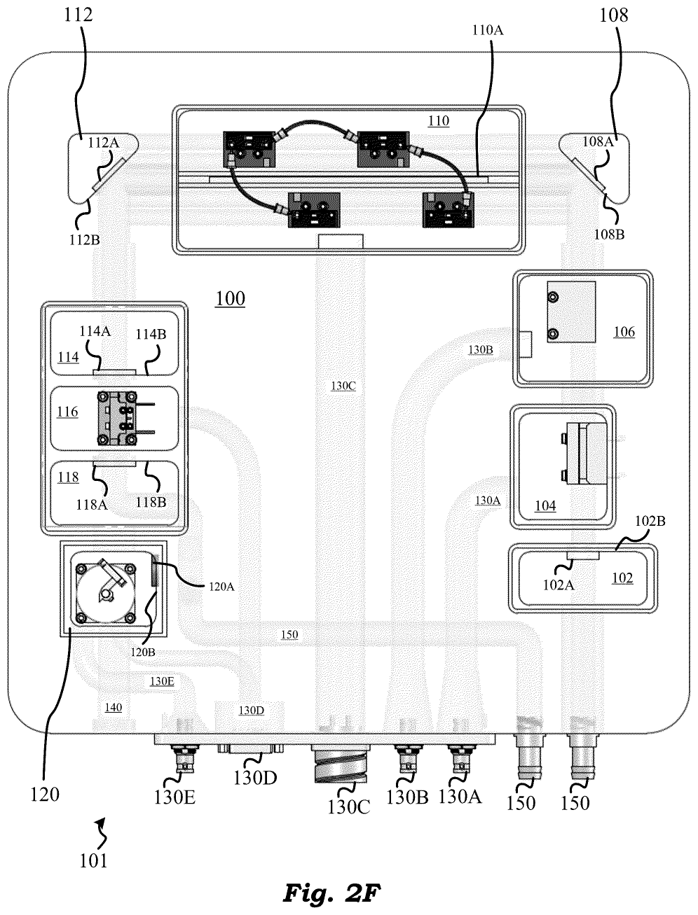

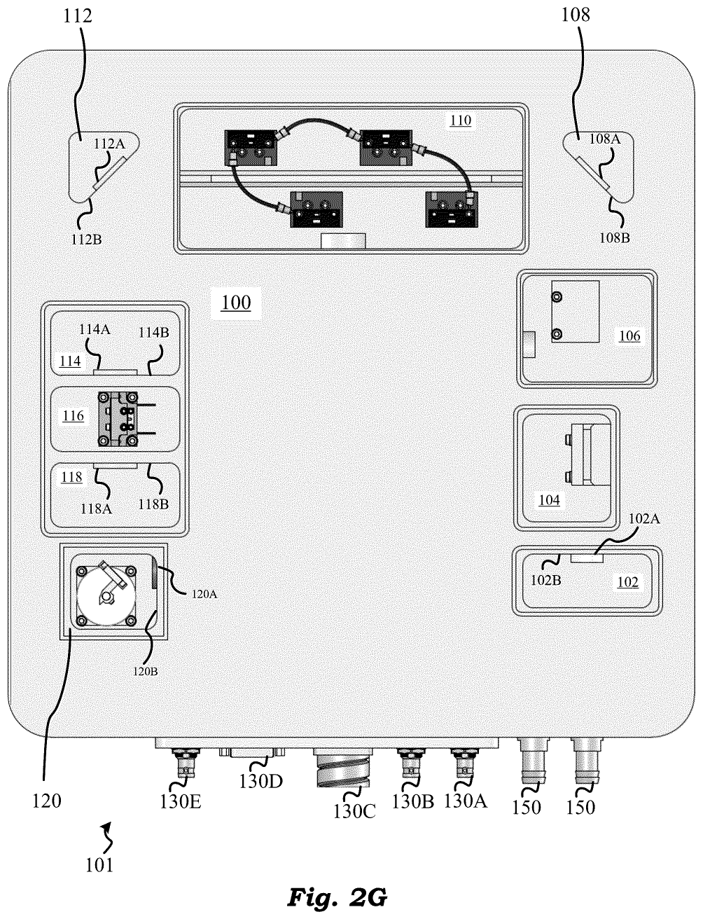

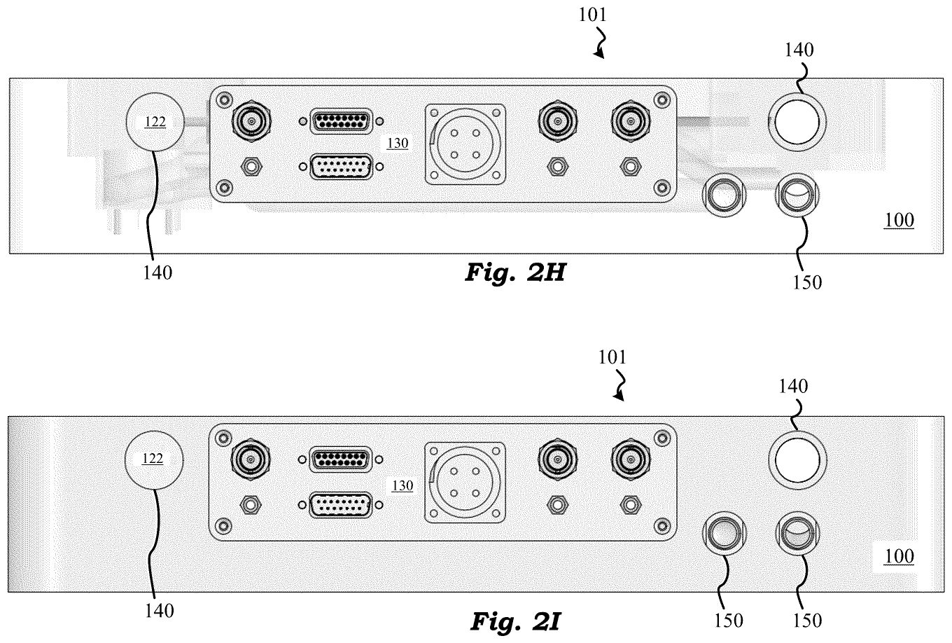

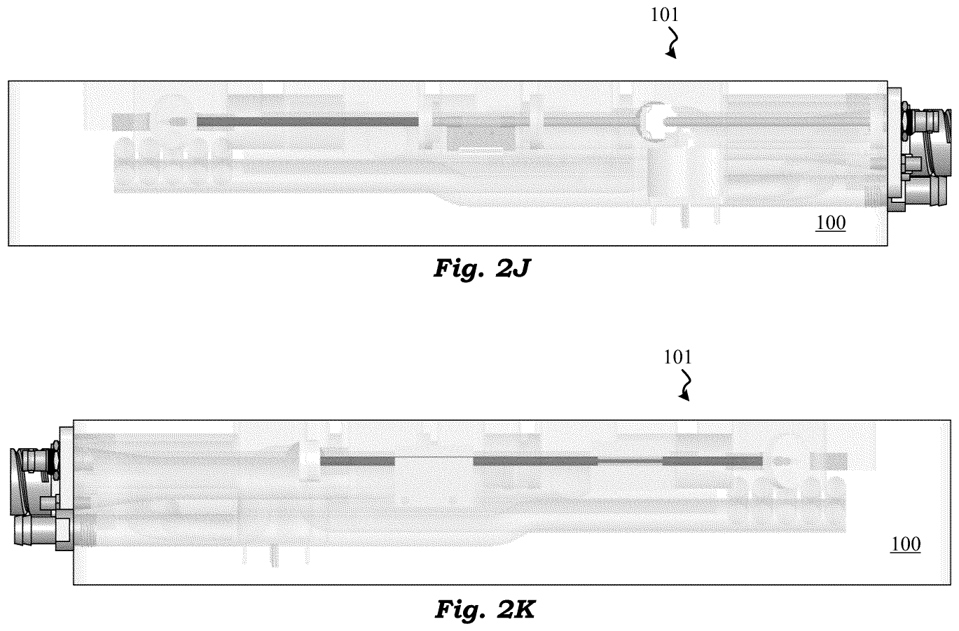

Let us now review the techniques for a monolithic integrated enclosure or an integrated monolithic enclosure or simply a monolithic enclosure or an integrated enclosure for housing modules, implements, optoelectronic devices, apparatus, instruments, systems and the like based on the instant principles, by taking advantage of enclosure/platform 100 as shown in FIG. 2A. An instant enclosure may also be referred to as a platform based on the instant principles to/into which the components of the optoelectronic devices are integrated. FIG. 2A shows such an instant monolithic enclosure or platform 100 for an exemplary optoelectronic device. The optoelectronic device that will be enclosed or encased or housed or packaged by enclosure 100 of FIG. 2A is a folded laser resonator.

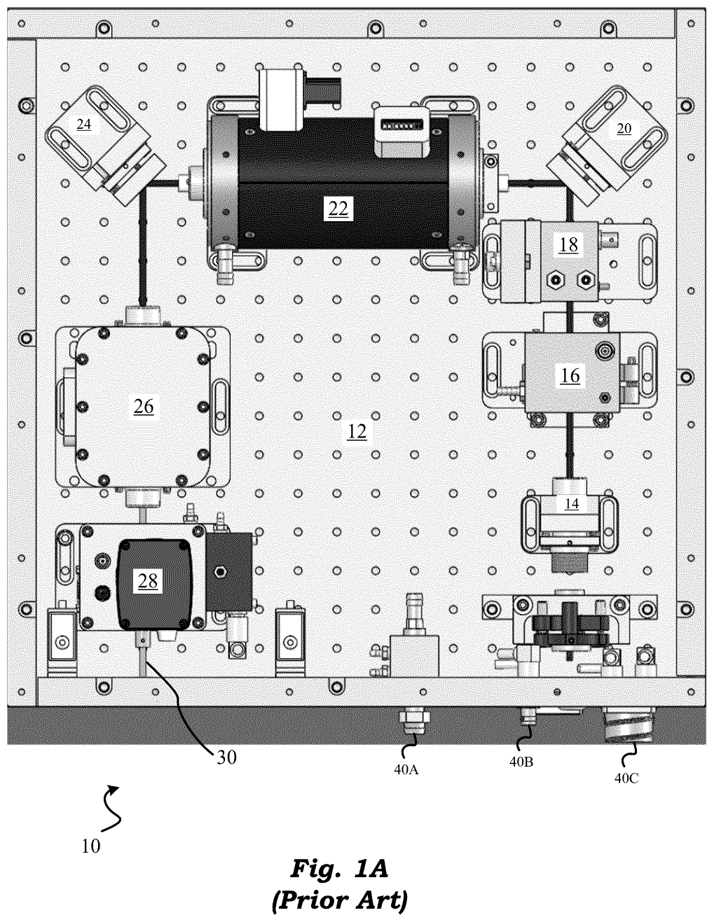

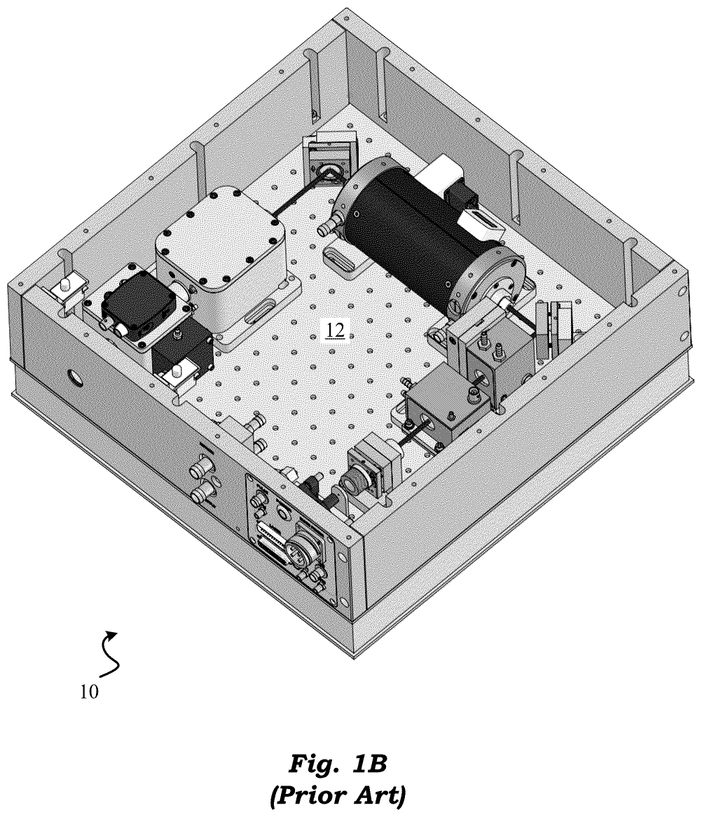

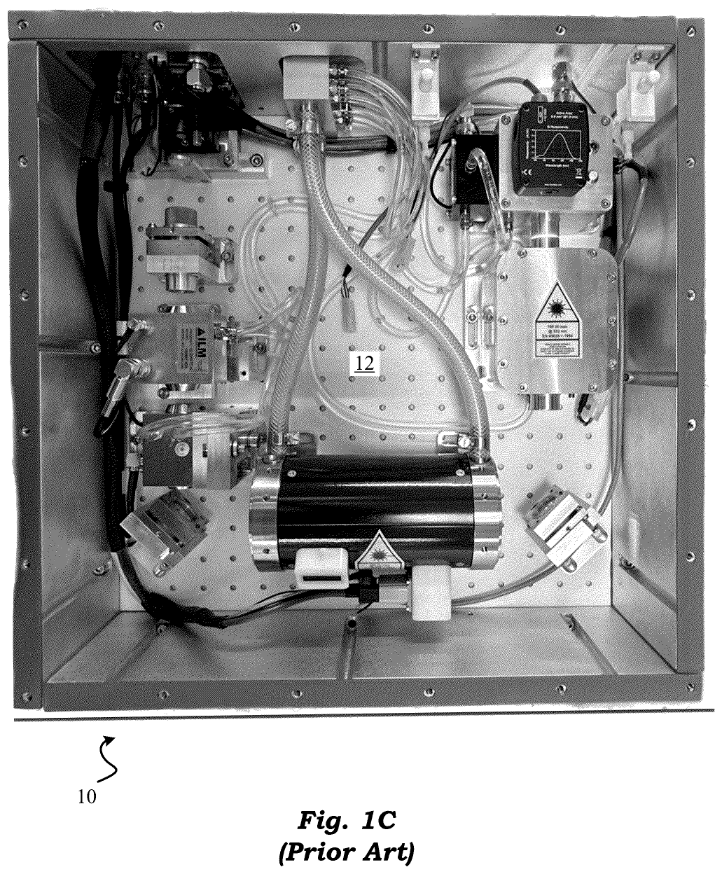

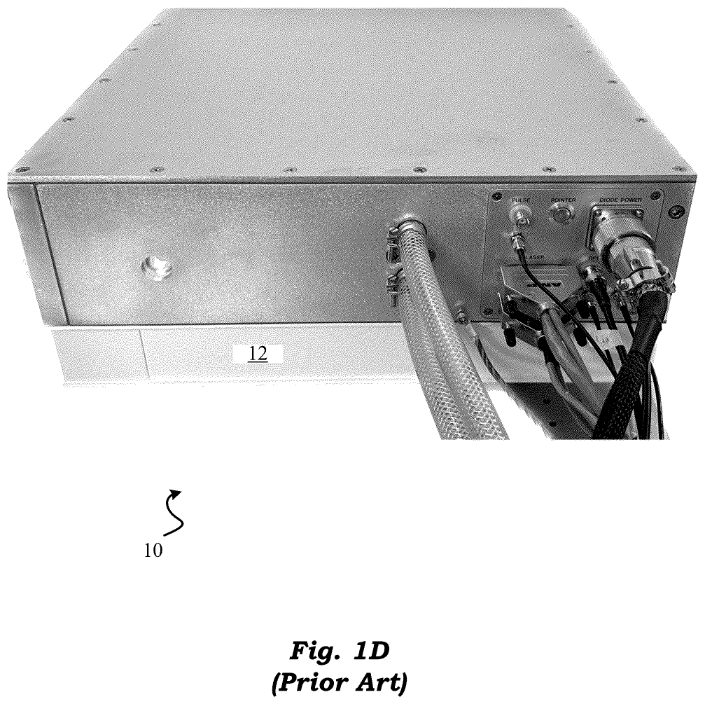

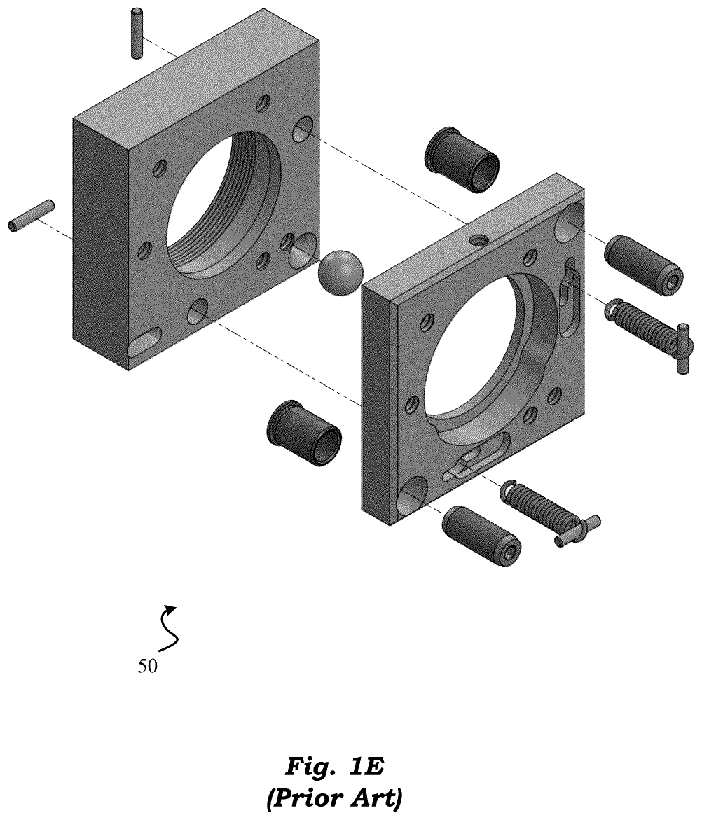

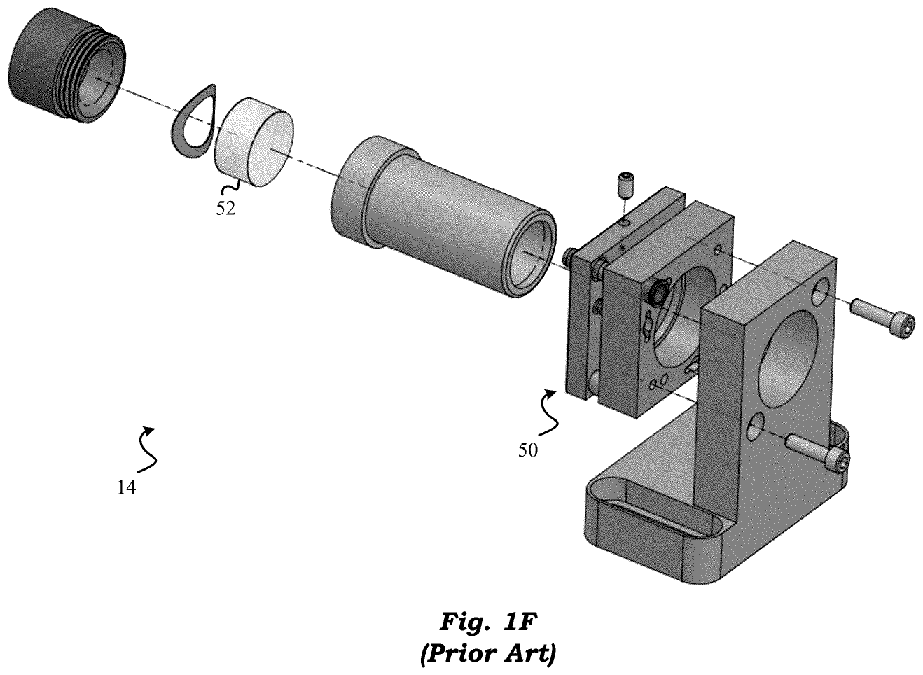

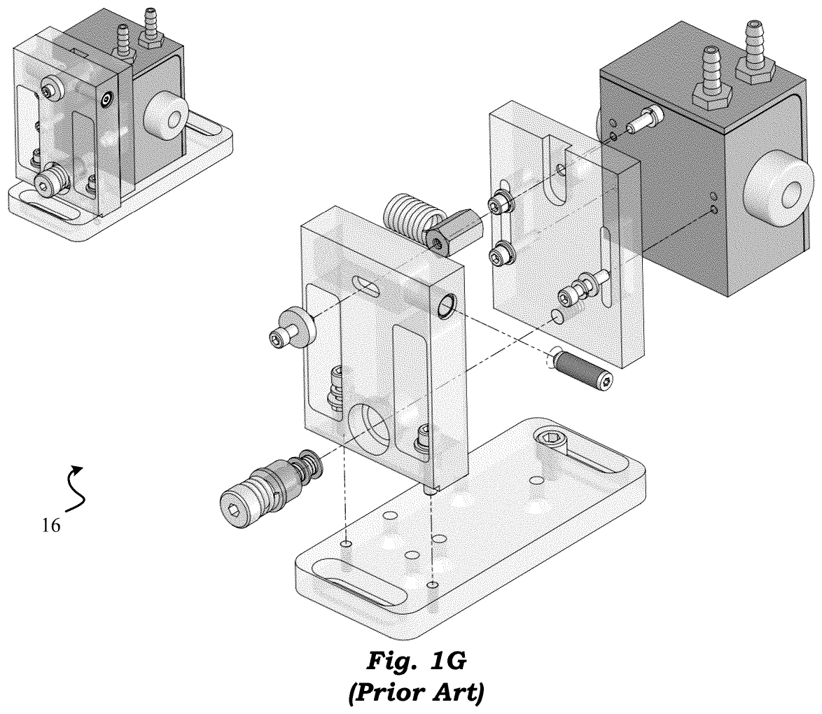

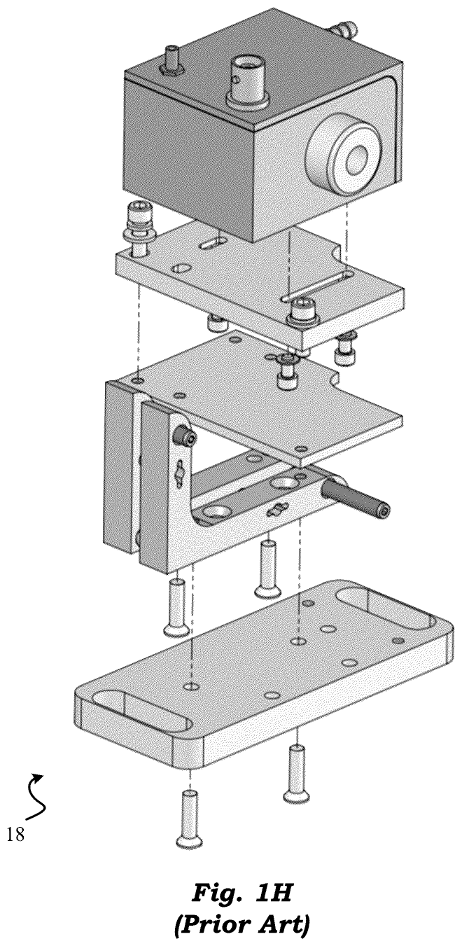

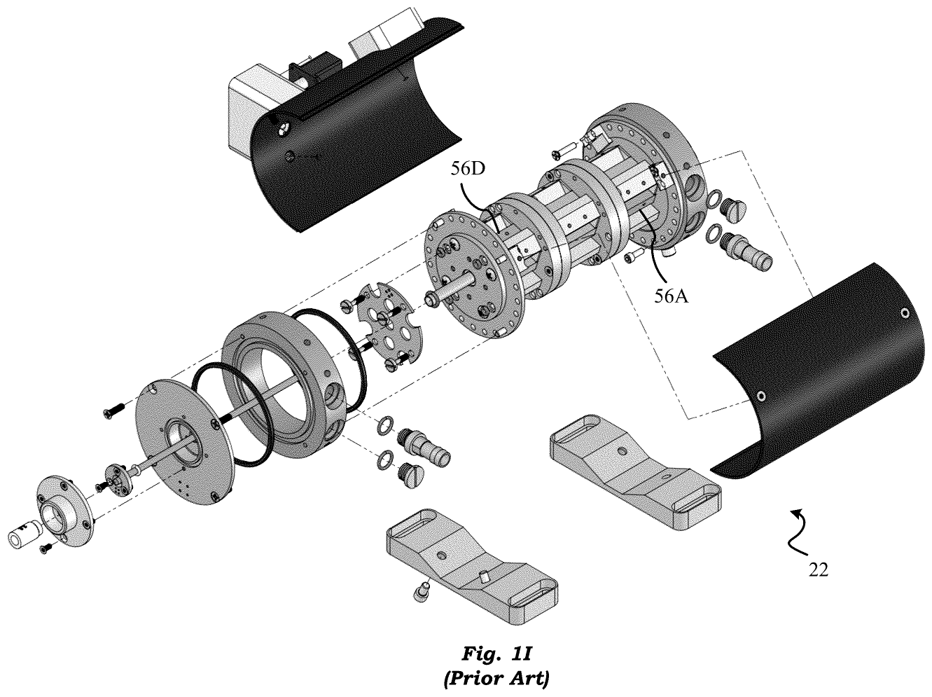

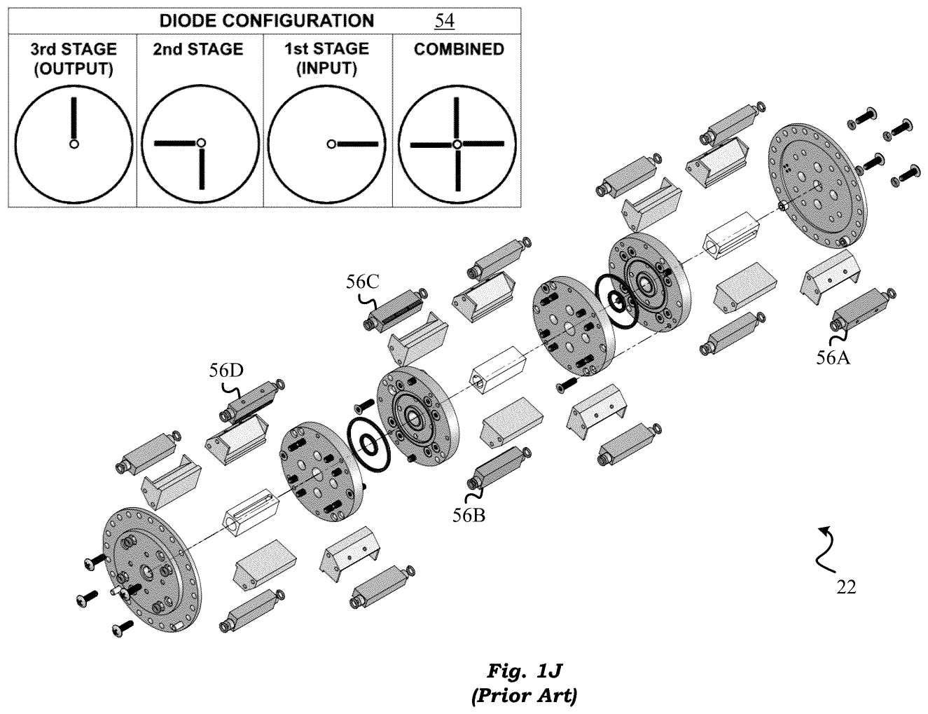

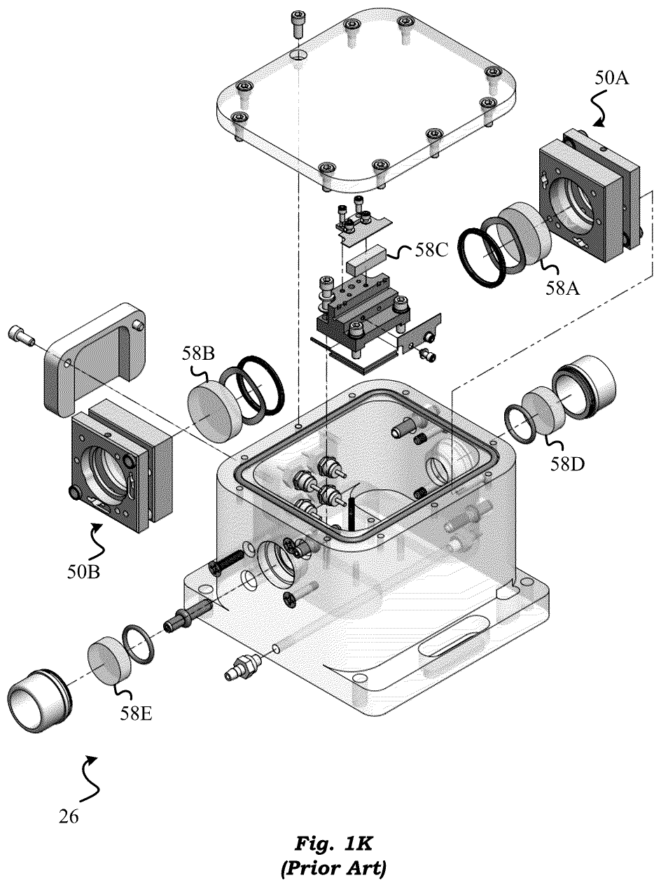

FIG. 2A illustrates a three-dimensional (3D) isometric view of an instant monolithic enclosure 100 that replaces the traditional honeycomb breadboard plate 12 housing the components of laser device 10 of FIG. 1A-L shown and discussed earlier. The view of FIG. 2A of enclosure 100 shows it in its empty state because optoelectronic components have not been integrated into it or attached to it or enclosed by it yet. However, FIG. 2B-K show a complete instant folded resonator 101 whose components have been integrated into enclosure 100 per teachings provided herein.

Now, folded laser resonator 101 shown in FIG. 2B-K integrated into or enclosed by enclosure 100 is functionally equivalent to the prior art folded resonator of FIG. 1A-L. However, it is fundamentally different in construction and structurally when compared to the prior art laser resonator of FIG. 1A-L. This is at least because unlike resonator 10 of FIG. 1 whose components were mounted on honeycomb 12, it is the instant monolithic enclosure 100 of FIG. 2A that encloses/integrates/encases/houses the components of folded resonator 101. In the preferred embodiments, enclosure 100 is made out of metal foam or metallic foam. In alternative embodiments, it is made out of a carbon-based material including carbon fiber, carbon nanotubes and graphene.

According to the chief aspects, the present design does not require elaborate housings for the essential optical and electrical/electronic elements/optics, and then attaching those housings to mounts and mounting the mounts to a honeycomb. Instead, and as practicable, essential elements/optics are now directly attached to instant monolithic enclosure 100.

Consequently, these essential elements/optics are already pre-aligned to each other by the enclosure itself per the teachings provided herein. As noted in the background section in reference to FIG. 1 and BOM 1 in Table 1 above, traditional housings and mounts for attaching to a prior art optical breadboard require a large number of parts that need to be machined or manufactured. That is one of the downsides of prior techniques that the present design overcomes.

We call our instant enclosure 100 of FIG. 2 monolithic because it is constructed out of a single piece of material, such as metal foam. In other words, enclosure 100 does not have multiple portions that are somehow attached or joined or connected to each other for integrating the optoelectronic components of a given optoelectronic module such as optoelectronic module/product/device/apparatus/instrument/implement 101.

Instead, enclosure 100 is produced as a single or singular monolithic object, and is produced using one of a number of possible techniques further discussed below. The various optoelectrical or optoelectronic components of final optoelectronic apparatus/device or product 101 are accommodated in various pockets or cavities built into enclosure 100 as shown in FIG. 2. Note that the laser resonator or resonators discussed herein are mere examples of optoelectronic apparatus that can benefit from instant enclosures without limitation. Besides laser resonators, there is a vast array of other optoelectronic apparatus/devices that may also benefit from the instant monolithic integrated enclosure techniques.

Before proceeding further, it is worthwhile to note that we use the term optoelectrical or optoelectronic to refer to components that may be purely optical, purely electrical or purely electronic components. They may also be hybrid components that comprise any combination of optical, electrical and electronic elements. Sometimes, the term electrotechnical is used to refer to elements or capabilities that encompass both electronic and electrical elements, characteristics/properties or capabilities.

Exemplarily, purely optical components may be lenses, mirrors, prisms and the like. Exemplarily, purely electronic components may be microprocessors, microcontrollers, or integrated circuits (ICs) in general, as well as resistors, capacitors and the like. These electronic components may also already be mounted on a printed circuit board (PCB) using techniques known in the art. Exemplarily, hybrid components include photodiodes (including solar cells), phototransistors, photomultipliers, opto-isolators, integrated circuit optical (IOC) elements, photoresistors, photoconductive camera tubes, charge-coupled devices (CCDs), laser diodes, quantum cascade lasers, light-emitting diodes, optocouplers and the like.

To avoid repetition, we will use the term electronic to include both electronic as well as electrical elements/capabilities/properties i.e. all electrotechnical elements/capabilities/properties. Similarly, we will use the term electrical to include both electronic as well as electrical elements/capabilities/properties i.e. all electrotechnical elements/capabilities/properties. In short, we will use the term optoelectronic components to include any and all optical, electrical, electronic, hybrid and electrotechnical components. Similarly, we will use the term optoelectronic apparatus or device or instrument or implement or module or product to include any and all optical, electrical, electronic, hybrid and electrotechnical apparatus or devices or instruments or implements or modules or products or systems.

Further, in the teachings provided herein, not all the elements in the numerous drawing figures are explicitly shown or marked by reference numerals for reasons of clarity and to maintain focus on the principles being taught. Referring now to FIG. 2, the optoelectronic components reside in pockets or cavities constructed/produced in/into monolithic enclosure 100 that are specifically designed to accommodate these components. Thus, each component resides in a pocket or pockets that is/are specifically designed according to its shape, size and dimensions in enclosure 100. FIG. 2 shows a variety of such pockets in enclosure 100 for a folded laser resonator.

More specifically, and referring now to FIG. 2A-G, there is a pocket or cavity 102 for accommodating a high reflection (HR) laser mirror. The new HR function or submodule in pocket 102 is functionality equivalent to HR assembly 14 of FIG. 1A and FIG. 1F and BOM 1 of the prior art. However, unlike the prior art, it requires no parts that need to be machined or produced. In fact, the new HR submodule comprises simply of mirror optic 102A that is seated against or bonded/affixed to surface or face 102B of pocket 102 as shown in the top view of FIG. 2F-G.

Our new HR function/submodule in pocket/cavity 102 of enclosure 100 has lot better business economics and technical properties than HR assembly 14 of the prior art. This is at least because it does not require parts to produce its housing. It also does not require parts to produce the mounts for the housing. It also does not require parts to attach the housing to the mount and also does not require parts to attach the mount to a honeycomb HR assembly 14 of FIG. 1. Moreover, its alignment is not easily disturbed during shipping/handling and operation of device 101 as compared to the alignment of HR assembly 14 attached to breadboard 12 of the prior art. Because of fewer parts, it also has less “points of failures” and affords better reliability to end product or laser resonator 101.

There is also a pocket 104 for accommodating a vertical quenching switch or Q-switch in instant enclosure 100 and more specifically for accommodating only its essential elements for apparatus 101. The new vertical Q-switch in FIG. 2 is fastened into pocket 104 with the help of fastening/mounting screws that are screwed into respective threaded sockets or receptacles provided directly into enclosure 100. These threaded sockets are produced in the enclosure at the time of its creation/manufacturing per present teachings. Thus, in the preferred embodiment, they are 3D-printed into enclosure 100. Alternatively, they are manufactured or constructed in it using techniques in concert with those used to create the enclosure itself.

One pair of such a screw 105A and its receptacle 105B are marked by reference numerals and a dotted line in the exploded 3D solid and exploded 3D transparent isometric views of FIG. 2E and FIG. 2D respectively. Other screws and sockets for the new vertical Q-switch integrated into enclosure 100 in pocket 104 are not explicitly marked to avoid clutter. This Q-switch is conduction cooled by enclosure 100 itself, thus eliminating the need for a cooling plate and fittings with cooling lines running to it, and eliminating any chance of those components leaking.

Once again, the new vertical Q-switch in pocket 104 is functionality equivalent to vertical Q-switch of assembly 16 of FIG. 1 and BOM 1. However, unlike the prior art, it requires no additional parts aside from the mounting screws. In a manner analogous to the new HR submodule/function in pocket 102, the new vertical Q-switch in pocket 104 of enclosure 100 also has lot better business economics and technical properties than assembly 16 of FIG. 1 and BOM 1 of the prior art.

There is also a pocket 106 for a horizontal Q-switch in instant enclosure 100 of FIG. 2 for accommodating a horizontal Q-switch, and more specifically only its essential elements for device 101. The new horizontal Q-switch is also fastened into pocket 106 with the help of fastening/mounting screws. These screws are screwed into respective threaded sockets or receptacles preferably 3D-printed, or alternatively provided per above teachings, directly into enclosure 100. One pair of such a screw 107A and its receptacle 107B are marked by reference numerals and a dotted line in the exploded 3D solid and exploded 3D transparent isometric views of FIG. 2E and FIG. 2D respectively. Other screws and sockets for the new horizontal Q-switch integrated into enclosure 100 in pocket 106 are not explicitly marked to avoid clutter.

Once again, the new horizontal Q-switch in pocket 106 is functionality equivalent to horizontal Q-switch of assembly 18 of FIG. 1 and BOM 1. However, unlike the prior art, it requires no additional parts aside from the mounting screws. This Q-switch is also conduction cooled by enclosure 100 itself, thus eliminating the need for a cooling plate and fittings with cooling lines running to it, and eliminating any chance of those components leaking. In a manner analogous to the new HR submodule/function in pocket 102 and the new vertical Q-switch in pocket 104, the new horizontal Q-switch in pocket 106 of enclosure 100 also has lot better business economics and technical properties than assembly 18 of FIG. 1 and BOM 1 of the prior art.

As shown in FIG. 2, there is also a pocket 108 for the first fold/folding or a 45° bending mirror. Unlike subassembly 50 of FIG. 1E of the prior art that was used to hold the bending mirror, first fold/bending mirror 108A in enclosure 100 is bonded or glued directly against front surface/face 108B of pocket 108 as shown in FIG. 2F-G. This design obviates the need for any other parts for its housing, supports, mounts and the like. Fold mirror 108A is mechanically seated and referenced on/against front surface/face 108B that the laser beam reflects off of as shown in FIG. 2F-G.

The present design provides a precise alignment and eliminates any concern about a wedge angle on optic 108A. Wedge angle is discussed in detail further below. In a manner analogous to the new HR submodule/function in pocket 102, the new vertical Q-switch in pocket 104 and the new horizontal Q-switch in pocket 106, new first fold mirror 108A of enclosure 100 also has lot better business economics and technical properties than fold mirror 20 of FIG. 1 and BOM 1 of the prior art.

Referring to FIG. 2A-G of the instant monolithic enclosure 100 of the present design, there is also a pocket 110. Per above, enclosure 100 is used to integrate or enclose optoelectronic apparatus 101 and more specifically its components. Pocket 110 is used to hold only the essential optoelectronic elements of a diode pump module (DPM) as compared to DPM assembly 22 of FIG. 1A, FIG. 1I-J and BOM 1. Evidently, the essential elements include four laser diodes for the 4-diode DPM configuration introduced earlier. However, unlike the complex prior art configuration of DPM assembly 22 of FIG. 1I-J, the four laser diodes in our new DPM are connected by jumpers and drive a simple diode-pumped slab 110A in pocket 110 as shown in FIG. 2F. Based on the present design, slab 110A and the laser diodes are all conductively cooled by enclosure 100 itself. This eliminates the need for any heat-sink modules for it, along with any cooling lines or channels, O-ring seals and related fittings.

In practice, there may also be any other requisite electronic components, such as resistors, capacitors and the like that are attached to a printed circuit board (PCB) first. Then, the PCB assembly along with one or more laser diodes is fastened to enclosure 100 as shown in FIG. 2D-E. The new DPM is also fastened into pocket 110 with the help of fastening/mounting screws. These screws are screwed into respective threaded sockets or receptacles preferably 3D-printed, or alternatively provided per above teachings, directly into enclosure 100. One pair of such a screw 111A and its receptacle 111B are marked by reference numerals and a dotted line in the 3D exploded solid and 3D exploded transparent isometric views of FIG. 2E and FIG. 2D respectively. Other screws and sockets for the new DPM integrated into enclosure 100 in pocket 110 are not explicitly marked to avoid clutter.

The instant design eliminates a large number of parts and support structures shown earlier in reference to DPM assembly 22 of the prior art of FIG. 1A, FIG. 1I-J as well as BOM 1 of Table 1. The new DPM in pocket 110 of our instant enclosure 100 has lot better business economics and technical traits than DPM assembly 22 of FIG. 1. Laser resonator 101 shown in FIG. 2 employs 4 laser diodes. However, in other variations, any number of laser diodes may be connected and used in the new DPM to attain the requisite amount of power for a given application. Exemplarily, with a total of 10 laser diodes, laser resonator 101 of FIG. 2 shown and discussed herein can produce up to 500 W in a 16-inch×16-inch×3-inch instant monolithic enclosure 100.

Now, there is also a pocket 112 for a second fold/folding or a 45° bending mirror. Unlike subassembly 50 of FIG. 1E of the prior art that was used to hold the bending mirror, second fold/bending mirror 112A in enclosure 100 is seated against or bonded/affixed/glued directly against front face 112B of pocket 112 as shown in FIG. 2F-G. This design obviates the need for any other parts for its housing, supports, mounts and the like. Fold mirror 112A is mechanically seated and referenced on front surface/face 112B that the laser beam reflects off of as shown in FIG. 2F-G. This design provides a precise alignment and eliminates any concern about a wedge angle on optic 112A.

A wedge angle only becomes a concern when the laser beam is propagating through an optic and not while it is reflecting off the front surface of the optic. When propagating through the optic, any wedge angle will cause refraction of the beam when exiting the optic according to Snell's Law, causing it to deviate from the preferred optical axis, and/or causing multiple reflections within the cavity of the device. In general, a wedge angle of a few arcminutes is often sufficient to prevent multiple reflections or significant refraction in an optical system. Currently, for commercial optics, wedge angles are available on the order of a few arcseconds, making the effect insignificant for some applications.

Per the present design, HR mirror 102A, output or front SHG mirror 118A as well as fold mirrors 108A/112A all reflect off the front surface of the mirrors, thus eliminating any concern of a wedge angle. In a manner analogous to the new HR submodule/function in pocket 102, the new vertical Q-switch in pocket 104, the new horizontal Q-switch in pocket 106, new first fold mirror 108 and new DPM in pocket 110, new second fold mirror 112A of enclosure 100 also has lot better business economics and technical properties than fold mirror 24 of FIG. 1 and BOM 1 of the prior art.

There are further three pockets 114, 116 and 118 for accommodating a respectively second harmonic generator/generation (SHG) input mirror 114A, an SHG crystal 116A and an SHG output mirror 118A as shown in FIG. 2F-G. Unlike SHG assembly 26 of FIG. 1A and FIG. 1K of the prior art, the three stages of our new SHG submodule/function have their own pockets containing only the essential elements of each stage. More specifically, pocket 114 has an input mirror 114A that is seated against and bonded/affixed to its face 114A facing crystal 116A as shown in FIG. 2D-F.

Pocket 116 has an SHG crystal 116A housed in copper blocks as shown in FIG. 2D. There is also a Peltier thermoelectric cooler (TEC) or Peltier device 116B seated beneath the crystal and in turn over coolant in channel 150 and which is meant for transporting away the heat generated by Peltier device 116B. The temperature of Peltier device 116B tunes and precisely controls the temperature of SHG crystal 116A for maximum conversion efficiency of the fundamental wavelength to the second harmonic wavelength.

The new housing for crystal 116A is also fastened into pocket 116 with the help of fastening/mounting screws. These screws are screwed into respective threaded sockets or receptacles preferably 3D-printed, or alternatively provided per above teachings, directly into enclosure 100. One pair of such a screw 117A and its receptacle 117B are marked by reference numerals and a dotted line in the 3D exploded solid and 3D exploded transparent isometric views of FIG. 2E and FIG. 2D respectively. Other screws and sockets for the new SHG crystal subassembly integrated into enclosure 100 in pocket 116 are not explicitly marked to avoid clutter.

Pocket 118 has an output mirror 118A that is seated against and bonded/affixed to its face 118A facing crystal 116A as shown in FIG. 2F. In a manner analogous to the other components/assemblies integrated into instant enclosure 100, the new SHG in pockets 114, 116 and 118 also has lot better business economics and technical properties than SHG assembly 26 of FIG. 1 and BOM 1 of the prior art.

There is also a pocket 120 that integrates only the essential elements of the new shutter assembly for optoelectronic device 101 in enclosure 100 of FIG. 2. Power meter 120A of the new shutter assembly in pocket 120 is shown seated against the back face 120B of the cavity as shown in FIG. 2F-G. The new shutter assembly is also fastened into pocket 120 with the help of fastening/mounting screws. These screws are screwed into respective threaded sockets or receptacles preferably 3D-printed, or alternatively provided per above teachings, directly into enclosure 100. One pair of such a screw 121A and its receptacle 121B are marked by reference numerals and a dotted line in the 3D exploded solid and 3D exploded transparent isometric views of FIG. 2E and FIG. 2D respectively. Other screws and sockets for the new shutter integrated into enclosure 100 in pocket 120 are not explicitly marked to avoid clutter.

The laser beam outputted by our new shutter assembly in pocket 120 exits as output of laser resonator 101 through optic 122 in FIG. 2. Optic 122 is a cover glass that keeps resonator/device 101 hermetically sealed. In a manner analogous to the other components/assemblies integrated in/into/inside instant enclosure 100, the new shutter assembly in pocket 120 also has lot better business economics and technical properties than shutter assembly 28 of FIG. 1 and BOM 1 of the prior art. In a variation of the present embodiment, there is also a pulse width monitor or pulse width control submodule/function. The purpose of such a submodule which resides in its own pocket/cavity is to monitor and/or control the pulse width of the laser beam outputted by the new shutter assembly in pocket 120 of laser device 101.

There are also a number of channels designed into monolithic enclosure 100 of the instant design. The outline of these channels can be seen in the interior of enclosure 100 in several views of FIG. 2, including FIG. 2A-B, FIG. 2D, FIG. 2F and FIG. 2J-K. These channels are used to electrically and optically connect various components that reside in their respective pockets/cavities in enclosure 100 in order to perform the requisite functions of laser apparatus 101. There are also channels that are used to bring fluids into enclosure 100 of FIG. 2. Such fluids may be gaseous or in liquid form. Usually, a cooling fluid/liquid or a coolant is required to transport away heat from hot components of laser device 101.

More specifically and while referring to FIG. 2A and FIG. 2D, there are connection or wiring channels 130A, 130B, 130C, 130D and 130E for carrying or routing electrical connections between of optoelectronic device and more various components specifically laser apparatus/device/instrument/system 101. These connections may take the form of electrical cables including insulated electrical wires, cords, leads, lines, wiring harnesses, electrodes and the like. These electrical connections may also take the form of fiber optic cables that transport optical signals between various optoelectronic components of the laser system.

In short, connection channels 130 are meant to carry/route any type of optoelectronic connections between a given set or plurality of components of the optoelectronic device/system 101 housed by our instant monolithic enclosure 100. In the embodiments of FIG. 2, each connection channel 130A-E carrying optoelectronic connections/signals/power has a corresponding interface or port on electrical panel 130 although that is not a requirement. Further, the channels for carrying optoelectronic connections between the components may have multiple segments in an enclosure. In order to avoid clutter, connection channels 130 and their segments are not always individually marked in the various drawings of FIG. 2. Any number of such optoelectronic connection channels each having one or more segments may be present in an instant enclosure.

There is also an optical channel 140 that goes around the three sides of enclosure 100 as shown. Referring to FIG. 2A and FIG. 2D, channel 140 is meant to provide a sealed optical path for propagating or carrying light between various optoelectronic components of the system as required for the operation of device 101. More specifically for laser resonator 101 of FIG. 2, optical channel 140 is meant to propagate a laser beam between its applicable optoelectronic components. Optical channel 140 may also have multiple segments as needed. Not all segments of optical channel or optical path 140 are individually labeled in FIG. 2 to avoid clutter. Any number of such optical path channels or simply optical channels with any number of segments may be present in an instant monolithic enclosure.

There is also a channel for transporting a coolant to and from the heated elements of the optoelectronic system 101. More specifically, there is a coolant channel 150 shown in FIG. 2 that carries a suitable coolant into enclosure 100 and towards the requisite heated elements. As such, coolant channel 150 may also have any number of segments in enclosure 100 for carrying a coolant to specific components of device 101 as desired. Thereafter a heat exchange takes place between the heated components (and more specifically their heated elements) and the coolant according to the laws of thermodynamics.

The above heat exchange/transfer results in cooling of the heated components and warming/heating up of the coolant. The heated coolant is then transported away from the heated elements and then out of enclosure 100 by channel 150. There are two external ports shown in FIG. 2 for coolant channel 150, one for supplying or inflowing or serving as the ingress of the coolant and the other for outflowing it or serving as its egress after the above heat exchange. One or more of such coolant or cooling channels each with any number of segments may be present in an instant enclosure. In preferred embodiments, and as one of the contributions of the present technology, the coolant utilized for instant enclosures is non-deionized water or simply “tap water”. This results in significant cost savings over prior art techniques.

For exemplary optoelectronic device 101 of instant enclosure 100 of FIG. 2, heated components that may require coolant to be transported to/from them include the vertical and horizontal Q-switches in pockets 104 and 106 respectively, DPM in pocket 110, SHG crystal in pocket 116, and power meter in pocket 120. In some variations, the new shutter assembly in pocket 120 also requires cooling. There may also be any other number and types of channels in an enclosure of the present design as required by a given product. For example, there may also be air or gas ducts in the enclosure for cooling components or for other functional reasons.

As needed, pocket covers are attached/fastened onto enclosure 100 to cover and seal the cavities or pockets containing sensitive optoelectronic components. These covers may be attached using known techniques, either in recesses specifically created for them in enclosure 100, or without such recesses. Preferably, O-ring seals are used with the pocket covers for this purpose. Exemplarily, some of these recesses are explicitly shown in FIG. 2 of which 3 recesses 160A, 160B and 160C are marked by reference numerals in FIG. 2B.

FIG. 2B shows a transparent hidden-lines isometric view of device 101 in our enclosure 100 of FIG. 2A with the various components integrated or attached. Notice the optoelectronic panel 130 containing various optoelectronic connections for the device, including ports for connection channels 130A-E discussed above. Per above discussion, the various components of optoelectronic device 101 housed in enclosure 100 may be attached to enclosure 100 by utilizing one or more of a number of techniques. Such fastening techniques include bolting or screwing a given component into enclosure 100.

For this purpose, suitable threaded boreholes or receptacles for the screws are designed and integrated into enclosure 100 along with its pockets and channels and any other features. Recall the above discussion in reference to screws 105A, 107A, 111A, 117A and 121A and respective receptacles 105B, 107B, 111B, 117B and 121B. The individual components are fastened to the enclosure by passing appropriately-sized fastening screws through fastening holes of the components and screwing them into their respective threaded receptacles designed in the enclosure. These boreholes of enclosure 100, fastening screws and fastening holes of the components are not always explicitly shown in the various views of FIG. 2 for reasons of clarity. Exemplary screw types that may be used in an instant enclosure include Flat Head Phillips (FHP) screws and Socket Head Cap Screws (SHCS).

FIG. 2C shows a solid isometric view of the variation of FIG. 2B where various components are hidden behind solid surfaces. Also shown explicitly in FIG. 2B-C is a laser beam propagating or passing or through optical channel 140 discussed above. More specifically, and for the exemplary laser resonator 101 of FIG. 2, reference numeral 140A in FIG. 2B-C is used to mark a portion of laser beam that is infrared (IR) or fundamental in wavelength/color. Reference numeral 140B marks the portion of the laser beam that is of green or second harmonic wavelength/color.

FIG. 2D and FIG. 2E already introduced earlier respectively show 3D transparent hidden-lines and 3D solid exploded isometric views of optoelectronic device 101 in enclosure 100. FIG. 2F and FIG. 2G respectively show 3D transparent hidden-lines and 3D solid top views of optoelectronic device 101 in enclosure 100. Similarly, FIG. 2H and FIG. 2I respectively show 3D transparent hidden-lines and 3D solid front views of optoelectronic device 101 in enclosure 100. Finally, FIG. 2J and FIG. 2K show 3D transparent hidden-lines left and right views respectively of instant monolithic enclosure 100 with the various components integrated for device 101.

Table 2 below provides the bill of materials (BOM) 2 of folded laser resonator 100 of FIG. 2A-K discussed above when enclosure 100 is made out metal foam. Notice the dramatic improvement over BOM 1 in Table 1 of the functionally equivalent prior art resonator 10 of FIG. 1. More specifically, as compared to the total quantity of 1078 parts of BOM 1, the number of parts in BOM 2 are reduced to approximately 120! This is about 90% reduction of parts, which translates to corresponding reductions in cost, weight, time to production, inventory carrying costs and all other business economics. Moreover, folded resonator 101 of FIG. 2 is technically more robust and more resilient to misalignment caused by disturbances than the prior art resonator of FIG. 1. Those are just some of the contributions of the present technology over prevailing art.

TABLE 2

| | Bill of Materials (BOM) 2 | | |
|---|---|---|---|
| | 101889-ASSY, RESONATOR, METAL FOAM | | |
| Item | Description | Qty | UM |
| 101869 | DIODE, 3-BAR, 90W, 806.5 nm, | 4 | ea |
| | CONDUCTION-COOLED | | |
| 101886 | ENCLOSURE, RESONATOR, | 1 | ea |
| | METAL FOAM, 16 X 16 X 3 | | |
| 101887 | PLATE, CONNECTONS, | 1 | ea |
| | METAL FOAM RESONATOR | | |
| 101311 | BLOCK, CRYSTAL MOUNT, SLIM, SHG | 1 | ea |
| 100022 | CRYSTAL, LBO, SHG, 5 X 5 X 18 mm | 1 | ea |
| 100023 | MIRROR, SHG INPUT, 1″ X ¼″, | 1 | ea |
| | HR@532 nm, HT@1064 nm | | |
| 100024 | MIRROR, SHG OUTPUT, 1″ X ¼″, | 1 | ea |
| | HR@1064 nm, HT@532 nm | | |
| 101434 | FITTING, ½BARB TO ⅝-18 THREAD, SS | 2 | ea |
| 101885 | NdYAG SLAB, 4 mm X 4 mm X | 1 | ea |
| | 166 mm AR@1064, FLAT/FLAT | | |
| 101888 | WINDOW, 1″ X .25″, OUTPUT, | 1 | ea |
| | METAL FOAM RESONATOR | | |
| 100030 | THERMISTOR, 10K @ 20° C., | 1 | ea |
| | EPOXY ENCAPSULATED | | |
| 101328 | TEC, 27.9W, QMAX, 8.6 V, | 1 | ea |
| | 20 × 20 × 3.3 mm, SHG | | |
| 100297 | MIRROR, HR@1064 nm, ¾″ X ⅜″, 2mCC | 1 | ea |
| 101840 | MIRROR, 1″ X 6 mm, 45° AOI, 99.9%, FS | 2 | ea |
| 100063 | SOLENOID, ROTARY, 45º 24 VDC | 1 | ea |
| 100068 | MOUNT, SHUTTER MIRROR | 1 | ea |
| 101700 | PCB ASSY, SHUTTER | 1 | ea |
| 101701 | PCB ASSY, SHUTTER, | 1 | ea |
| | PROXIMITY SENSORS | | |
| 100301 | MIRROR, SHUTTER, HR@532 nm, | 1 | ea |
| | 18 mm X 14 mm X 3 mm | | |
| 100665 | CONN, MALE RECEPTACLE, 4-POS, | 1 | ea |
| | BAYONET LOCK (DIODE POWER) | | |
| 101246 | CONN, BNC-BNC, ISOLATED | 3 | ea |
| 101838 | CONN, SMA, FEMALE, 50 OHM, | 3 | ea |
| | BULKHEAD MOUNT | | |
| 100273 | CONN, D-SUB RCPT 15-PIN, | 1 | ea |
| | STR SOLDER CUP | | |
| 100329 | CONN, D-SUB | 1 | ea |
| | PLUG 15-PIN STR SOLDER CUP | | |
| 101823 | Q-SWITCH, 80 MHz, QUARTZ, G&H | 2 | ea |
| 101890 | COVER, HR POCKET, | 1 | ea |
| | METAL FOAM RESONATOR | | |
| 101891 | COVER, VERTICAL Q-SWITCH POCKET, | 1 | ea |
| | METAL FOAM RESONATOR | | |
| 101892 | COVER, HORIZONTAL Q-SWITCH | 1 | ea |
| | POCKET, METAL FOAM RESONATOR | | |
| 101893 | COVER, FOLD MIRROR POCKET, | 2 | ea |
| | METAL FOAM RESONATOR | | |
| 101894 | COVER, DPM POCKET, | 1 | ea |
| | METAL FOAM RESONATOR | | |
| 101895 | COVER, SHG POCKET, | 1 | ea |
| | METAL FOAM RESONATOR | | |
| 101896 | COVER, SHUTTER POCKET, | 1 | ea |
| | METAL FOAM RESONATOR | | |
| 101897 | O-RING, HR POCKET, | 1 | ea |
| | METAL FOAM RESONATOR | | |
| 101898 | O-RING, VERTICAL Q-SWITCH POCKET, | 1 | ea |
| | METAL FOAM RESONATOR | | |
| 101899 | O-RING, HORIZONTAL | 1 | ea |
| | Q-SWITCH POCKET, METAL | | |
| | FOAM RESONATOR | | |
| 101900 | O-RING, FOLD MIRROR POCKET, | 2 | ea |
| | METAL FOAM RESONATOR | | |
| 101901 | O-RING, DPM POCKET, | 1 | ea |
| | METAL FOAM RESONATOR | | |
| 101902 | O-RING, SHG POCKET, | 1 | ea |
| | METAL FOAM RESONATOR | | |
| 101903 | O-RING, SHUTTER POCKET, | 1 | ea |
| | METAL FOAM RESONATOR | | |
| 101904 | POWER METER DISC | 1 | ea |
| 100211 | SCREW, FHP, 6-32 X .375 SS | 36 | ea |
| 101905 | PLATE, SOLENOID MOUNTING, | 1 | ea |
| | METAL FOAM RESONATOR | | |
| 100198 | SCREW, SHCS, 6-32 X .4375 SS | 8 | ea |
| 100209 | SCREW, SHCS, 4-40 X .375 SS | 8 | ea |
| 100225 | SCREW, SHCS, 6-32 X 1.375 SS | 4 | ea |
| 100298 | LED, RED, 24 VDC, 16 mm PANEL | 1 | ea |
| | MOUNT, RESONATOR | | |
| 100299 | LED, YELLOW, 24 VDC, 16 mm | 1 | ea |
| | PANEL MOUNT, RESONATOR | | |
| 100503 | WIRE, #22 AWG BLACK TEFLON | 0.5 | ft |
| 101733 | PCB ASSY, DIODE & RESISTOR, DPM | 4 | ea |
| 101314 | PLATE, CRYSTAL MOUNT, .01″ THICK, | 2 | ea |
| | 5 X 5 X 18 mm CRYSTAL, SHG | | |
| 100009 | PLATE, CLAMP, THERMISTOR | 1 | ea |
| 100726 | SLEEVING, TEFLON, #18 | 0.426 | in |
| | AWG, .042 ID, .016 WALL | | |
| 101741 | SPRING, .088 OD, .625 FREE, .25 | 1 | ea |
| | COMPRESSED, 3.2 LB/IN, SS | | |
| | | 109.9 | Tot |
| | | | Qty |

Table 3 below provides a comparison between BOM 1 and BOM 2 by adding a column to the right-hand side of BOM 1 in Table 1 indicating the parts that are eliminated and/or simplified by the metal foam embodiments of the present design. Once again, notice the dramatic elimination and/or simplification in the number of parts required and which would result in corresponding economic and technical benefits derived therefrom.

TABLE 3
(BOM 1 & BOM 2 Compared)

| | BOM 1 vs BOM 2 | | | |
|---|---|---|---|---|
| | 101849-ASSY, RESONATOR, | | | |
| | 18 X 18, 24 V DPM, 2 Q- | | | |
| | SWITCHES | | | |
| Item | Description | Qty | UM | Notes |
| 101323- | ASSY, SHG, | 1 | ea | Eliminated |
| 003 | 5 mm X 5 mm X 25 mm | | | |
| | CRYSTAL, HORIZONTAL | | | |
| 100027 | BAG, DESICCANT | 2 | ea | Eliminated |
| 100021 | INDIUM SHEET, .004″-.006″ | 0.8 | 1′In | Eliminated |
| | THICK | | | |
| 101345 | CRYSTAL, LBO, SHG, 5 X 5 X | 1 | ea | |
| | 25 mm | | | |
| 100629 | LABEL, ILM WARRANTY | 1 | ea | Eliminated |
| | VOID SEAL, 0.5″ X 1″ | | | |
| 101323- | SUB-ASSY, SHG, | 1 | ea | Eliminated |
| 000 | NO CRYSTAL | | | |
| 100004 | COVER, TOP, SHG HOUSING | 1 | ea | Replaced |
| | | | | by 101895, |
| | | | | SHG |
| | | | | POCKET |
| | | | | COVER |
| 100009 | PLATE, CLAMP, | 1 | ea | |
| | THERMISTOR | | | |
| 100111 | BEZEL, DUST, .70″ THRU | 2 | ea | Eliminated |
| | HOLE | | | |
| 100023 | MIRROR, SHG INPUT, 1″ X | 1 | ea | |
| | ¼″, HR@532 nm, | | | |
| | HT@1064 nm | | | |
| 100024 | MIRROR, SHG OUTPUT, 1″ X | 1 | ea | |
| | ¼″, HR@1064 nm, | | | |
| | HT@532 nm | | | |
| 101328 | TEC, 27.9W, QMAX, 8.6 V, | 1 | ea | |
| | 20 × 20 × 3.3 mm, SHG | | | |
| 100030 | THERMISTOR, 10K @ 20° C., | 1 | ea | |
| | EPOXY ENCAPSULATED | | | |
| 100034 | TERMINAL, INSULATED | 4 | ea | Eliminated |
| | FEED THROUGH | | | |
| 100196 | SCREW, SHCS, 6-32 X .3125 | 10 | ea | Eliminated |
| | SS | | | |
| 100240 | NUT, KEP, 10-32, SS | 4 | ea | Eliminated |
| 100233 | WASHER, LOCK, #2 | 4 | ea | Eliminated |
| 100235 | WASHER, LOCK, #6 | 4 | ea | Eliminated |
| 101584 | O-RING, .112 X .103, VITON | 4 | ea | Eliminated |
| 100017 | O-RING, 3.737 X .103, | 1 | ea | Eliminated |
| | VITON | | | |
| 100019 | O-RING, .145 X .070, VITON | 4 | ea | Eliminated |
| 100088 | FITTING, 10-32 X ⅛″ HOSE | 2 | ea | Eliminated |
| | BARB, SS | | | |
| 100036 | ASSY, SHG CABLE, 5″ LONG | 1 | ea | Eliminated |
| 100014 | CABLE, 4 COND, #22AWG | 5 | in | Eliminated |
| | SHIELDED | | | |
| 100412 | CONTACT, MALE, CRIMP, | 4 | ea | Eliminated |
| | .093″, 18-22 GA | | | |
| 100410 | CONN, 4 CIRCUIT, .093″, | 1 | ea | Eliminated |
| | PLUG, 4 POS | | | |
| 100554 | WASHER, FENDER, #4, .125 | 4 | ea | Eliminated |
| | ID, .344 OD, SS | | | |
| 100025 | WINDOW .19 mm X 6.35 mm, | 1 | ea | Eliminated |
| | AR@1064 @ 0° C. | | | |
| 100026 | WINDOW, 19 mm X 6.35 mm | 1 | ea | Eliminated |
| | AR@532 @ 0° C. | | | |
| 100018 | O-RING, .551 X .070, VITON | 2 | ea | Eliminated |
| 101310 | SHG HOUSING, ILM MOUNT | 1 | ea | Eliminated |
| 101311 | BLOCK, CRYSTAL MOUNT, | 1 | ea | |
| | SLIM, SHG | | | |
| 101312 | COVER, TERMINALS, | 1 | ea | Eliminated |
| | STACKED, | | | |
| | SHG HOUSING | | | |
| 101314 | PLATE, CRYSTAL | 2 | ea | |
| | MOUNT, .01″ | | | |
| | THICK, 5 X 5 X 18 mm | | | |
| | CRYSTAL, SHG | | | |
| 100031- | SUB-ASSY, 1″ OPTIC | 2 | ea | Eliminated |
| ILM | MOUNT, SHG, TIP/TILT | | | |
| 101035 | PLATE, ADJUSTMENT, 1″ | 1 | ea | Eliminated |
| | OPTIC, STAINLESS STEEL | | | |
| 101036 | PLATE, MOUNTING, | 1 | ea | Eliminated |
| | 1″ OPTIC, | | | |
| | STAINLESS STEEL | | | |
| 101040 | PIN, DOWEL, .0625″ DIA X | 4 | ea | Eliminated |
| | .3125″ LONG | | | |
| 101041 | SPRING, EXTENSION, LOOP | 2 | ea | Eliminated |
| | END, .138″ OD X .602″ LONG, | | | |
| | .027″ THICK, 33.06 LBS, SS | | | |
| 101039 | BALL, .25″ DIA. S.S. | 1 | ea | Eliminated |
| 101557- | SCREW, | 2 | ea | Eliminated |
| 001 | ADJUSTMENT, 3/16- | | | |
| | 120 X 1″, O-RING GROOVE | | | |
| 101322 | WASHER, WAVE, .78 ID X | 2 | ea | Eliminated |
| | 1.004 OD, .071 FREE HEIGHT | | | |
| 101324- | THREAD, | 2 | ea | Eliminated |
| 001 | RETAINING RING, SM1 | | | |
| | 1″ OPTIC MOUNT, | | | |
| | STAINLESS STEEL | | | |
| 101321 | SCREW, FHP, 6-32 X .625, | 4 | ea | Eliminated |
| | SILICONE O-RING | | | |
| 100208 | SCREW, SHCS, 6-32 X .5 SS | 4 | ea | Eliminated |
| 101483 | WASHER, FLAT, #6, .143 ID, | 4 | ea | Eliminated |
| | .267 OD, .015-.018 THK | | | |
| 100200 | SCREW, SHCS, 2-56 X .188 SS | 6 | ea | Eliminated |
| 100251 | SCREW, SHCS, 6-32 X .375 SS | 2 | ea | Eliminated |
| 100726 | SLEEVING, TEFLON, #18 | 0.472 | in | |
| | AWG, .042 ID, .016 WALL | | | |
| 101741 | SPRING, .088 OD, .625 | 1 | ea | |
| | FREE, .25 COMPRESSED, 3.2 | | | |
| | LB/IN, SS | | | |
| 100191 | FITTING, ⅜ BARB X 7/16- | 2 | ea | Eliminated |
| | 20 THREAD, WATER IN, | | | |
| | DIODE PUMP HEAD | | | |
| 100076 | SWITCH, INTERLOCK, | 2 | ea | Eliminated |
| | DEFEATABLE | | | |
| 100088 | FITTING, 10-32 X ⅛″ HOSE | 12 | ea | Eliminated |
| | BARB, SS | | | |
| 100121 | ASSY, DIODE POINTER | 1 | ea | Not |
| | | | | necessary |
| | | | | but is |
| | | | | now |
| | | | | optional for |
| | | | | external |
| | | | | optic |
| | | | | alignment |
| 100073 | PLATE, PINHOLE, DIA. 0.062 | 1 | ea | Not |
| | | | | necessary |
| | | | | but is |
| | | | | now |
| | | | | optional for |
| | | | | external |
| | | | | optic |
| | | | | alignment |
| 100241 | PLATE, | 1 | ea | Not |
| | MOUNTING, DIODE | | | necessary |
| | POINTER | | | but is |
| | | | | now |
| | | | | optional for |
| | | | | external |
| | | | | optic |
| | | | | alignment |
| 100688 | ASSY, IR-FILTERED | 1 | ea | Not |
| | LASER | | | necessary |
| | DIODE | | | but is |
| | | | | now |
| | | | | optional for |
| | | | | external |
| | | | | optic |
| | | | | alignment |
| 100043 | ALIGNMENT LASER DIODE | 1 | ea | Not |
| | | | | necessary |
| | | | | but is |
| | | | | now |
| | | | | optional for |
| | | | | external |
| | | | | optic |
| | | | | alignment |
| 100651 | LENS, AR-IR, 6.5 mm X 1 mm | 1 | ea | Not |
| | | | | necessary |
| | | | | but is |
| | | | | now |
| | | | | optional for |
| | | | | external |
| | | | | optic |
| | | | | alignment |
| 100521 | LUG, FEMALE, | 2 | ea | Not |
| | 24-26 AWG, | | | necessary |
| | YELLOW, 3/16 | | | but is |
| | SPADE, FULLY | | | now |
| | INSULATED | | | optional for |
| | | | | external |
| | | | | optic |
| | | | | alignment |
| 100232 | ADAPTER, | 1 | ea | Not |
| | DIODE POINTER, 1″ | | | necessary |
| | MOUNT | | | but is |
| | | | | now |
| | | | | optional for |
| | | | | external |
| | | | | optic |
| | | | | alignment |
| 100399 | SCREW, SOCKET | 1 | ea | Not |
| | SET, 6-32 X | | | necessary |
| | .25, NYLON TIP | | | but is |
| | | | | now |
| | | | | optional for |
| | | | | external |
| | | | | optic |
| | | | | alignment |
| 100220 | SCREW, SHCS, | 3 | ea | Not |
| | 8-32 X .5625 | | | necessary |
| | SS | | | but is |
| | | | | now |
| | | | | optional for |
| | | | | external |
| | | | | optic |
| | | | | alignment |
| 100236 | WASHER, LOCK #8 | 2 | ea | Not |
| | | | | necessary |
| | | | | but is |
| | | | | now |
| | | | | optional for |
| | | | | external |
| | | | | optic |
| | | | | alignment |
| 100247 | WASHER, FLAT, #8 | 2 | ea | Not |
| | | | | necessary |
| | | | | but is |
| | | | | now |
| | | | | optional for |
| | | | | external |
| | | | | optic |
| | | | | alignment |
| 100083 | SCREW, FHP, 6-32 X .3125 SS | 2 | ea | Not |
| | | | | necessary |
| | | | | but is |
| | | | | now |
| | | | | optional for |
| | | | | external |
| | | | | optic |
| | | | | alignment |
| 101417 | PLATE, SPACER, .25″ THK, | 1 | ea | Not |
| | M1-H MOUNT | | | necessary |
| | | | | but is |
| | | | | now |
| | | | | optional for |
| | | | | external |
| | | | | optic |
| | | | | alignment |
| 101421 | MOUNT, TIP/TILT, 1″, M1-H | 1 | ea | Not |
| | | | | necessary |
| | | | | but is |
| | | | | now |
| | | | | optional for |
| | | | | external |
| | | | | optic |
| | | | | alignment |
| 100122 | ASSY, HR MIRROR | 1 | ea | Eliminated |
| 100224 | BRACKET, MIRROR MOUNT | 1 | ea | Eliminated |
| 100143- | HOLDER, ¾″ MIRROR, .78 | 1 | ea | Eliminated |
| 001 | LONG, BRASS | | | |
| 100163- | ADAPTER, MIRROR HOLDER, | 1 | ea | Eliminated |
| 001 | ⅝-14 THREAD | | | |
| 100249 | WASHER, WAVE, .52″ ID, | 1 | ea | Eliminated |
| | .75″ OD | | | |
| 100297 | MIRROR, HR@1064 nm, | 1 | ea | Eliminated |
| | ¾″ X ⅜″, 2mCC | | | |
| 100208 | SCREW, SHCS, 6-32 X .5 SS | 2 | ea | Eliminated |
| 100031- | SUB-ASSY, 1″ OPTIC MOUNT, | 1 | ea | Eliminated |
| ILM- | HR & OC, TIP/TILT | | | |
| 001 | | | | |
| 101035 | PLATE, ADJUSTMENT, 1″ | 1 | ea | Eliminated |
| | OPTIC, STAINLESS STEEL | | | |
| 101036 | PLATE, MOUNTING, 1″ | 1 | ea | Eliminated |
| | OPTIC, STAINLESS STEEL | | | |
| 101040 | PIN, DOWEL, .0625″ DIA X | 4 | ea | Eliminated |
| | .3125″ LONG | | | |
| 101041 | SPRING, EXTENSION, LOOP | 2 | ea | Eliminated |
| | END, .138″ OD X .602″ LONG, | | | |
| | .027″ THICK, 33.06 LBS, SS | | | |
| 101039 | BALL, .25″ DIA. S.S. | 1 | ea | Eliminated |
| 100508- | SCREW, | 2 | ea | Eliminated |
| 001 | ADJUSTMENT, 3/16- | | | |
| | 120 X .50 | | | |
| 100210 | SCREW, SOCKET SET, 6-32 X | 1 | ea | Eliminated |
| | .25 SS | | | |
| 101279 | ASSY, HEAD, 4 mm ROD, 3- | 1 | ea | Eliminated |
| | STAGE, 4 DIODES-IND. STG. | | | |
| 100071 | APERTURE, | 2 | ea | Eliminated |
| | CERAMIC-3.8 mm, | | | |
| | HEAD | | | |
| 101445 | SCREW, BHCS, 6-32 X .3125 | 8 | ea | Eliminated |
| | SS | | | |
| 100142 | DIODE, 3-BAR, 90W, 806.5 nm | 4 | ea | Replaced |
| | | | | by 101869, |
| | | | | CON- |
| | | | | DUCTION |
| | | | | COOLED |
| | | | | DIODE |
| 100146 | O-RING, .087 X .081, VITON | 16 | ea | Eliminated |
| 100148 | O-RING, .158 X .054, VITON | 24 | ea | Eliminated |
| 100149 | O-RING, .145 X .070, | 2 | ea | Eliminated |
| | TEFLON, 4 mm ROD | | | |
| 100151 | O-RING, .364 X .070, VITON | 4 | ea | Eliminated |
| 100153 | O-RING, 2.487 X .103, | 4 | ea | Eliminated |
| | QUAD-SEAL, VITON | | | |
| 100180 | HOUSING, HOUR METER | 1 | ea | Eliminated |
| 100181- | SPACER INSULATOR, HOUR | 1 | ea | Eliminated |
| 3D | METER | | | |
| 100183 | BEZEL, ROD | 2 | ea | Eliminated |
| | CLAMPING, 4 mm | | | |
| 100190 | FLOW TUBE 7 mm X 6 mm X | 1 | ea | Eliminated |
| | 5.812″ AR COATED | | | |
| 100191 | FITTING, ⅜ BARB X 7/16- | 2 | ea | Eliminated |
| | 20 THREAD, | | | |
| | WATER IN, DIODE | | | |
| | PUMP HEAD | | | |
| 100192 | BEZEL, DUST TUBE & | 2 | ea | Eliminated |
| | APERTURE HOLDER, HEAD | | | |
| 100202 | SCREW, SHCS, 2-56 X .25 SS | 4 | ea | Eliminated |
| 100207 | SCREW, DIODE CAPTIVE | 8 | ea | Eliminated |
| 100214 | BLOCK, HEAD CONNECTOR | 1 | ea | Eliminated |
| | MOUNT | | | |
| 100216 | DIFFUSER, 2-SLOT, | 1 | ea | Eliminated |
| | ADJACENT, CERAMIC | | | |
| 100217 | DU MMY MODULE, 1.68″ | 8 | ea | Eliminated |
| | LONG, HEAD | | | |
| 100218 | PLATE, ROD SUPPORT, 4 mm | 2 | ea | Eliminated |
| | ROD | | | |
| 101581 | PLATE, BASE, HEAD, | 2 | ea | Eliminated |
| | UNIVERSAL | | | |
| 100593 | METER, LCD HOUR, | 1 | ea | |
| | PCB MOUNT | | | |
| 100653 | NdYAG ROD, 4 mm X | 1 | ea | Replaced |
| | 166 mm AR@1064, | | | by 101885, |
| | FLAT/FLAT (SERIAL | | | NdYAG |
| | #:_______________) | | | SLAB |
| 100499 | LUG, #6 RING 10-12AWG, | 8 | ea | Eliminated |
| | YELLOW | | | |
| 100454 | HEATSHRINK, | 1.2 | in | Eliminated |
| | POLY ⅛″ BLK | | | |
| 100503 | WIRE, #22 AWG | 1 | ft | Eliminated |
| | BLACK TEFLON | | | |
| 100504 | WIRE, #22 AWG | 1 | ft | QTY |
| | RED TEFLON | | | changes to |
| | | | | 0.5 ft |
| 100505 | WIRE, #16 AWG | 14 | in | Eliminated |
| | BLACK TEFLON | | | |
| 100507 | WIRE, #16 AWG | 42 | in | Eliminated |
| | GREY TEFLON | | | |
| 100629 | LABEL, ILM | 1 | ea | Eliminated |
| | WARRANTY VOID | | | |
| | SEAL, 0.5″ X 1″ | | | |
| 100311 | O-RING, .277 X .076, VITON | 2 | ea | Eliminated |
| 100946 | RES, 100 OHM ⅛ W 1% | 1 | ea | Eliminated |
| 101780 | SCREW, FHH, 4-40 X .25, SS | 8 | ea | Eliminated |
| 100253 | SCREW, SHCS, 10-32 X .3125 | 4 | ea | Eliminated |
| | SS | | | |
| 101798 | PLATE, HEAD, CENTER | 4 | ea | Eliminated |
| | STAGES, O-RING GROOVE | | | |
| 101283 | PLATE, HEAD, FLOW TUBE | 2 | ea | Eliminated |
| | CLAMP, 4 mm ROD | | | |
| 101280 | END BLOCK, HEAD, SPLIT, | 2 | ea | Eliminated |
| | RING, 3.500″ OD | | | |
| 101797 | END BLOCK, HEAD, SPLIT, | 2 | ea | Eliminated |
| | ROTATION PLATE, | | | |
| | 4 mm ROD | | | |
| 101286 | COVER, HEAD, 3-STAGE, | 1 | ea | Replaced |
| | ELECTRICAL SIDE, | | | by 101894, |
| | BRACKET MOUNT | | | DPM |
| | | | | POCKET |
| | | | | COVER |
| 101287 | COVER, HEAD, 3-STAGE, | 1 | ea | Eliminated |
| | WATER SIDE, | | | |
| | BRACKET MOUNT | | | |
| 101284 | SPACER, HEAD, ALUMINUM, | 12 | ea | Eliminated |
| | 1.360″ X .66″ X .58″ | | | |
| 101285 | BLOCK, COVER MOUNTING, | 4 | ea | Eliminated |
| | HEAD | | | |
| 101294 | O-RING, .426 X .070, QUAD | 2 | ea | Eliminated |
| | SEAL, VITON | | | |
| 101293 | O-RING, 1.301 X .070, QUAD | 2 | ea | Eliminated |
| | SEAL, VITON | | | |
| 100927 | SCREW, SHCS, M2.5 × 0.45 X | 8 | ea | Eliminated |
| | 5 mm LONG, SS | | | |
| 101721 | SCREW, FLAT HEAD TORX- | 40 | ea | Eliminated |
| | PLUS, 6-32 X .50, SS | | | |
| 101437 | SCREW, FHH, 6-32 X .625 SS | 4 | ea | Eliminated |
| 100865 | SCREW, THP, 6-32 X .5, SS | 8 | ea | Eliminated |
| 101392 | FITTING, PLUG, 7/16-20, SS | 2 | ea | Eliminated |
| 101594 | SUB-ASSY, DPM POWER | 1 | ea | Eliminated |
| | CONNECTOR | | | |
| 101686 | LABEL, SYSTEM | 1 | ea | Eliminated |
| | VOLTAGE, 24 V | | | |
| 101684 | SCREW, FLAT HEAD TORX, | 4 | ea | Eliminated |
| | TAMPER-RESISTANT, 6-32 X | | | |
| | .3125, SS | | | |
| 100083 | SCREW, FHP, 6-32 X .3125 SS | 12 | ea | Eliminated |
| 100227 | DIFFUSER, 1-SLOT, | 2 | ea | Eliminated |
| | CERAMIC | | | |
| 100157 | O-RING, 1.114 X .070, | 2 | ea | Eliminated |
| | VITON | | | |
| 100529 | SCREW, SHCS, 4-40 X .25, SS | 6 | ea | Eliminated |
| 101733 | PCB ASSY, DIODE & | 4 | ea | |
| | RESISTOR, DPM | | | |
| 101777 | ASSY, SHUTTER, | 1 | ea | Eliminated |
| | SENSOR PCB, | | | |
| | METER, PHOTODET, 532 nm | | | |
| 100111 | BEZEL, DUST, .70″ THRU | 2 | ea | Eliminated |
| | HOLE | | | |
| 100061 | COVER, TOP, SHUTTER | 1 | ea | Replaced |
| | HOUSING | | | by 101896, |
| | | | | SHUTTER |
| | | | | POCKET |
| | | | | COVER |
| 100063 | SOLENOID, ROTARY, 45° | 1 | ea | |
| | 24 VDC | | | |
| 100067 | LENS, SHUTTER, 12.7 mm X- | 1 | ea | Eliminated |
| | 12.5 mm | | | |
| 100068 | MOUNT, SHUTTER MIRROR | 1 | ea | |
| 100088 | FITTING, 10-32 X ⅛″ HOSE | 4 | ea | Eliminated |
| | BARB, SS | | | |
| 100196 | SCREW, SHCS, 6-32 X .3125 | 4 | ea | Eliminated |
| | SS | | | |
| 100225 | SCREW, SHCS, 6-32 X 1.375 | 4 | ea | |
| | SS | | | |
| 100234 | WASHER, LOCK #4, | 2 | ea | Eliminated |
| | HI-COLLAR | | | |
| 100235 | WASHER, LOCK, #6 | 4 | ea | Eliminated |
| 100246 | SCREW, SOCKET-SET, 4-40 X | 2 | ea | Eliminated |
| | .125 SS | | | |
| 101450 | ASSY, PHOTODETECTOR | 1 | ea | Eliminated |
| 100408 | CONN, 2 CIRCUIT, .093″, | 1 | ea | Eliminated |
| | PLUG, 2 POS | | | |
| 100412 | CONTACT, MALE, CRIMP, | 2 | ea | Eliminated |
| | .093″, 18-22 GA | | | |
| 100597 | LUG, #2 RING, 22-26 AWG, | 1 | ea | Eliminated |
| | CLEAR YELLOW | | | |
| 100248 | PHOTODETECTOR, | 1 | ea | Eliminated |
| | 200-1100 nm, | | | |
| | 1ns RISE TIME, SM1 THREAD | | | |
| 100430 | CABLE, 2COND | 9 | in | Eliminated |
| | 24AWG GRAY | | | |
| 100453 | HEATSHRINK, | 1 | in | Eliminated |
| | POLY 3/16″ BLK | | | |
| 100453- | HEATSHRINK, | 1 | in | Eliminated |
| 001 | POLY 3/16″ | | | |
| | BLK, ADHESIVE | | | |
| 100301 | MIRROR, SHUTTER, | 1 | ea | |
| | HR@532 nm, | | | |
| | 18 mm X 14 mm X 3 mm | | | |
| 100223 | SCREW, SHCS, 6-32 X .625 SS | 2 | ea | Eliminated |
| 100374 | FITTING, PLUG, 10-32, SS | 1 | ea | Eliminated |
| 100443 | TUBING, TYGON, ⅛″ ID, | 4 | in | Eliminated |
| | ¼″ OD, 1/16″ WALL, CLEAR | | | |
| 100057 | POWER METER, | 1 | ea | Replaced |
| | 150W, 532 nm | | | by 101904, |
| | | | | POWER |
| | | | | METER |
| | | | | DISC |
| 101544 | GASKET, 9-PIN D-SUB | 1 | ea | Eliminated |
| 100051- | JACKSCREW, 4-40 X .25, D- | 2 | ea | Eliminated |
| 001 | CONN | | | |
| 101666 | LABEL, SHUTTER, | 1 | ea | Eliminated |
| | 532 nm ONLY | | | |
| 100399 | SCREW, SOCKET SET, 6-32 X | 1 | ea | Eliminated |
| | .25, NYLON TIP | | | |
| 101776 | HOUSING, SHUTTER, | 1 | ea | Eliminated |
| | SENSOR PCB | | | |
| 101768 | HOUSING, 5 mm LED, | 2 | ea | Eliminated |
| | CHROME | | | |
| 101769 | LED, 5 mm, 3 V-12 V, WIRE | 1 | ea | Eliminated |
| | LEADS, RED | | | |
| 101770 | LED, 5 mm, 3 V-12 V, WIRE | 1 | ea | Eliminated |
| | LEADS, YELLOW | | | |
| 101778 | BRACKET, SENSOR | 1 | ea | Eliminated |
| | PCB MOUNT, SHUTTER | | | |
| 101779 | STANDOFF, 2-56 X .50, | 2 | ea | Eliminated |
| | FEMALE, ⅛″ OD, SS | | | |
| 100202 | SCREW, SHCS, 2-56 X .25 SS | 2 | ea | Eliminated |
| 101822 | SCREW, FHP, 2-56 X .50, SS | 2 | ea | Eliminated |
| 101787 | CONN, HOUSING, 2-POS, | 3 | ea | Eliminated |
| | .098″ PITCH, JST | | | |
| 101806 | SOCKET, 26-30 AWG, CRIMP, | 6 | ea | Eliminated |
| | TIN | | | |
| 101881 | SUB-ASSY, SHUTTER PCBS | 1 | ea | |
| 101700 | PCB ASSY, SHUTTER | 1 | ea | |
| 101701 | PCB ASSY, SHUTTER, | 1 | ea | |
| | PROXIMITY SENSORS | | | |
| 101800- | RIBBON, 10COND, 1″ | 1 | ea | |
| CA- | LONG, .098″ PITCH | | | |
| BLE, | | | | |
| 001 | | | | |
| 100194 | SCREW, FHP, 10-32 X .375 SS | 20 | ea | Eliminated |
| 100254 | MANIFOLD, RESONATOR | 1 | ea | Eliminated |
| 100342 | POST, .75″ TALL, | 3 | ea | |
| | RESONATOR SUPPORT | | | |
| 100077 | SCREW, SHCS, ¼-20 X .75 | 19 | ea | Eliminated |
| | SS | | | |
| 100543 | ASSY, OUTPUT COUPLER | 1 | ea | Eliminated |
| 100224 | BRACKET, MIRROR MOUNT | 1 | ea | Eliminated |
| 100143- | HOLDER, ¾″ MIRROR, .78 | 1 | ea | Eliminated |
| 001 | LONG, BRASS | | | |
| 100163- | ADAPTER, MIRROR HOLDER, | 1 | ea | Eliminated |
| 001 | ⅝-14 THREAD | | | |
| 100278 | MIRROR, OUTPUT COUPLER, | 1 | ea | Eliminated |
| | ¾″ X ⅜″ , 70% | | | |
| | REFLECTIVITY AT 1064 nm | | | |
| 100249 | WASHER, WAVE, .52″ ID, | 1 | ea | Eliminated |
| | .75″ OD | | | |
| 100208 | SCREW, SHCS, 6-32 X .5 SS | 2 | ea | Eliminated |
| 100031- | SUB-ASSY, 1″ OPTIC MOUNT, | 1 | ea | Eliminated |
| ILM- | HR & OC, TIP/TILT | | | |
| 001 | | | | |
| 101035 | PLATE, ADJUSTMENT, 1″ | 1 | ea | Eliminated |
| | OPTIC, STAINLESS STEEL | | | |
| 101036 | PLATE, MOUNTING, 1″ | 1 | ea | Eliminated |
| | OPTIC, STAINLESS STEEL | | | |
| 101040 | PIN, DOWEL, .0625″ DIA X | 4 | ea | Eliminated |
| | .3125″ LONG | | | |
| 101041 | SPRING, EXTENSION, LOOP | 2 | ea | Eliminated |
| | END, .138″ OD X .602″ LONG, | | | |
| | .027″ THICK, 33.06 LBS, SS | | | |
| 101039 | BALL, .25″ DIA. S.S. | 1 | ea | Eliminated |
| 100508- | SCREW, | 2 | ea | Eliminated |
| 001 | ADJUSTMENT, 3/16- | | | |
| | 120 X .50 | | | |
| 100210 | SCREW, SOCKET SET, 6-32 X | 1 | ea | Eliminated |
| | .25 SS | | | |
| 100544 | ASSY, TARGET | 1 | ea | Eliminated |
| 100073 | PLATE, PINHOLE, DIA. 0.062 | 1 | ea | Eliminated |
| 100241 | PLATE, MOUNTING, DIODE | 1 | ea | Eliminated |
| | POINTER | | | |
| 100211 | SCREW, FHP, 6-32 X .375 SS | 2 | ea | QTY |
| | | | | increases |
| | | | | to 36 for |
| | | | | pocket |
| | | | | covers |
| 101434 | FITTING, ½ BARB TO ⅝- | 2 | ea | |
| | 18 THREAD, SS | | | |
| 100484 | ASSY, Q-SWITCH MOUNT, | 1 | ea | Eliminated |
| | HORIZONTAL | | | |
| 100242 | PLATE, Q-SWITCH/FIBER | 1 | ea | Eliminated |
| | FOCUS | | | |
| 101158 | PLATE, SPACER, | 1 | ea | Eliminated |
| | HORIZONTAL | | | |
| | Q-SWITCH, .25″ THK | | | |
| 101161 | PLATE, MOUNTING, | 1 | ea | Eliminated |
| | HORIZONTAL | | | |
| | Q-SWITCH, .125″ | | | |
| | THK | | | |
| 100213 | SCREW, SHCS, 8-32 X .5 SS | 3 | ea | Eliminated |
| 100236 | WASHER, LOCK #8 | 3 | ea | Eliminated |
| 100243 | SCREW, SHCS, 6-32 X .25 SS | 3 | ea | Eliminated |
| 101276- | SUB-ASSY, TIP/TILT | 1 | ea | Eliminated |
| 001 | MOUNT, Q-SWITCH | | | |
| 101154- | HORIZONTAL | 1 | ea | Eliminated |
| 001 | BRACKET, ADJUSTMENT, | | | |
| | Q-SWITCH, | | | |
| | STAINLESS STEEL | | | |
| 101155- | HORIZONTAL | 1 | ea | Eliminated |
| 001 | BRACKET, MOUNTING, | | | |
| | Q-SWITCH, | | | |
| | STAINLESS STEEL | | | |
| 101039 | BALL, .25″ DIA. S.S. | 1 | ea | Eliminated |
| 101040 | PIN, DOWEL, .0625″ DIA X | 4 | ea | Eliminated |
| | .3125″ LONG | | | |
| 101041 | SPRING, EXTENSION, LOOP | 2 | ea | Eliminated |
| | END, .138″ OD X .602″ LONG, | | | |
| | .027″ THICK, 33.06 LBS, SS | | | |
| 100508- | SCREW, | 1 | ea | Eliminated |
| 002 | ADJUSTMENT, 3/16- | | | |
| | 120 X .75 | | | |
| 100508- | SCREW, | 1 | ea | Eliminated |
| 003 | ADJUSTMENT, 3/16- | | | |
| | 120 X 1.5″ | | | |
| 101483 | WASHER, FLAT, #6, .143 ID, | 3 | ea | Eliminated |
| | .267 OD, .015-.018 THK | | | |
| 100247 | WASHER, FLAT, | 3 | ea | Eliminated |
| | #8 | | | |
| 101715 | SCREW, FHP, 8-32 X .625, SS | 4 | ea | Eliminated |
| 100443 | TUBING, TYGON, ⅛″ ID, | 10 | ft | Eliminated |
| | ¼″ OD, 1/16″ WALL, CLEAR | | | |
| 100431 | WIRE TIE MOUNT, ¼-20 | 5 | ea | Eliminated |
| | SCREW | | | |
| 100721 | WASHER, SHIM, ¼ ID, ⅜ | 22 | ea | Eliminated |
| | OD, .025 THK, SS | | | |
| 100587 | HOSE CLAMP, ¼″ TO ⅝″ | 4 | ea | Eliminated |
| 100588 | HOSE CLAMP, ⅜″ TO ⅝″ | 2 | ea | Eliminated |
| 100980 | ASSY, LEAK DETECTOR | 1 | ea | Eliminated |
| 100464 | SENSOR, LEAK DETECTOR | 1 | ea | Eliminated |
| 100410 | CONN, 4 CIRCUIT, .093″, | 1 | ea | Eliminated |
| | PLUG, 4 POS | | | |
| 100412 | CONTACT, MALE, CRIMP, | 4 | ea | Eliminated |
| | .093″, 18-22 GA | | | |
| 100504 | WIRE, #22 AWG | 5 | in | Eliminated |
| | RED TEFLON | | | |
| 100503 | WIRE, #22 AWG | 3 | in | Eliminated |
| | BLACK TEFLON | | | |
| 100498 | SCREW, BHCS, ¼-20 X .375 | 1 | ea | Eliminated |
| 100547 | CABLE, 4COND 24AWG | 8 | in | Eliminated |
| | GRAY, SHIELDED | | | |
| 101592- | CLAMP, CABLE, LEAK | 6 | ea | Eliminated |
| 3D | DETECTOR | | | |
| 100453 | HEATSHRINK, | 16 | in | Eliminated |
| | POLY 3/16″ BLK | | | |
| 100454 | HEATSHRINK, | 4 | in | Eliminated |
| | POLY ⅛″ BLK | | | |
| 101855 | CONVERTER, DC-DC, 3.3 V, | 1 | ea | Eliminated |
| | 3.3 W | | | |
| 101856 | RELAY, DPDT, 3 VDC, 1A | 1 | ea | Eliminated |
| 101865 | PCB BARE BOARD, LEAK | 1 | ea | Eliminated |
| | DETECTOR | | | |
| 100609 | TAPE, VINYL PINSTRIPE, 2″, | 2 | in | Eliminated |
| | WHITE | | | |
| 100428 | CLAMP, REFERENCE, ¼ X | 4 | ea | Eliminated |
| | 1.5″ SLOT | | | |
| 101165 | ASSY, Q-SWITCH MOUNT, | 1 | ea | Eliminated |
| | VERTICAL | | | |
| 100242 | PLATE, Q-SWITCH/FIBER | 1 | ea | Eliminated |
| | FOCUS | | | |
| 100161 | PLATE, ADJUSTMENT, | 1 | ea | Eliminated |
| | VERTICAL Q-SWITCH | | | |
| 100162 | PLATE, MOUNTING, | 1 | ea | Eliminated |
| | VERTICAL Q-SWITCH | | | |
| 101090 | POST, HEX, .375 DIA × .625 | 1 | ea | Eliminated |
| | LONG, 6-32 THREAD, Q- | | | |
| | SWITCH LOCKING | | | |
| 101091 | SPACER, #6 CLEARANCE X | 2 | ea | Eliminated |
| | ⅛″ THK X ½″ OD | | | |
| 101092 | BUSHING, BRONZE | 1 | ea | Eliminated |
| | FLANGED, .3135 ID X .502 | | | |
| | OD X ⅜ LONG | | | |
| 101093 | SPRING, COMPRESSION, | 1 | ea | Eliminated |
| | 1.25/.635 LONG X .480 OD X | | | |
| | 58.5 LBS | | | |
| 101094 | SPRING, COMPRESSION, SS, | 1 | ea | Eliminated |
| | .500″/.265″ LONG X .480″ X | | | |
| | 98.0 LBS | | | |
| 101095 | SCREW, ADJUSTMENT, | 1 | ea | Eliminated |
| | ¼-80 X .85″, SS | | | |
| 101100 | SCREW, SHSS, ¼-20 X .438 | 1 | ea | Eliminated |
| | THREAD, .312 | | | |
| | SHOULDER DIA. | | | |
| | X .75 SHOULDER LENGTH | | | |
| 100541 | SCREW, SHCS, 8-32 X .75 SS | 2 | ea | Eliminated |
| 100208 | SCREW, SHCS, 6-32 X .5 SS | 1 | ea | Eliminated |
| 100223 | SCREW, SHCS, 6-32 X .625 SS | 3 | ea | Eliminated |
| 100236 | WASHER, LOCK #8 | 2 | ea | Eliminated |
| 100247 | WASHER, FLAT, #8 | 2 | ea | Eliminated |
| 100721 | WASHER, SHIM, ¼ ID, ⅜ | 2 | ea | Eliminated |
| | OD, .025 THK, SS | | | |
| 100085 | SCREW, BHCS, 6-32 X .625 SS | 1 | ea | Eliminated |
| 100555 | HOSE, ½″ ID, NYLON | 24 | ft | Eliminated |
| | REINFORCED | | | |
| 100556 | HOSE, ⅜″ ID, NYLON | 22 | in | Eliminated |
| | REINFORCED | | | |
| 100907 | Q-SWITCH, 27.12 MHz, | 2 | ea | |
| | 4 mm APERTURE, SHEAR | | | |
| | WAVE, FS, G&H | | | |
| 100907- | Q-SWITCH, 27.12 MHz, 4 mm | 1 | ea | |
| 000 | APERTURE, SHEAR | | | |
| | WAVE, FS, G&H | | | |
| 100230- | BEZEL, Q-SWITCH, PRESS- | 2 | ea | |
| 001 | FIT, G&H | | | |
| 101468 | VIBRATION ISOLATOR, .75″ | 3 | ea | |
| | TALL, ¼-20 STUD TAP, | | | |
| | MALE TO FEMALE, 95LBS | | | |
| 101429 | HOSE CLAMP, 17.8 TO 21 mm | 2 | ea | Eliminated |
| 101587 | HOSE CLAMP, SPRING, ¼ ID | 20 | ea | Eliminated |
| 101826 | TABLE, | 1 | ea | Replaced |
| | BREADBOARD, 18″ X | | | by 101886, |
| | 18″ × 2.3″ | | | RESO- |
| | | | | NATOR |
| | | | | ENCLO- |
| | | | | SURE |
| 101831 | BULKHEAD, 17.25″ X 4.50″ | 1 | ea | Eliminated |
| | OUTPUT | | | |
| 101832 | BULKHEAD, 17.25″ X 4.50″ | 3 | ea | Eliminated |
| | SIDE | | | |
| 101833 | PLATE, ELECTRICAL | 1 | ea | Replaced |
| | CONNECTIONS, | | | by 101887, |
| | RESONATOR | | | CONNEC- |
| | | | | TIONS |
| | | | | PLATE |
| 101834 | COVER, 18″ X 18″ | 1 | ea | Eliminated |
| | RESONATOR | | | |
| 101246 | CONN, BNC-BNC, ISOLATED | 3 | ea | |
| 101838 | CONN, SMA, | 3 | ea | |
| | FEMALE, 50 OHM, | | | |
| | BULKHEAD MOUNT | | | |
| 101842 | GASKET, 25-PIN D-SUB | 1 | ea | Eliminated |
| 101843 | GASKET, DIODE | 1 | ea | Eliminated |
| | POWER CONN | | | |
| 101844 | RETAINING RING, M20.5 X | 1 | ea | Eliminated |
| | 0.5, ALUMINUM | | | |
| 101845 | O-RING, .926 X .070, VITON | 2 | ea | Eliminated |
| 101846 | SCREW, FHP, ¼-20 X .75, | 2 | ea | Eliminated |
| | SILICONE O-RING | | | |
| 101847 | GASKET STRIP, ¾″ X 36″, | 156 | in | Eliminated |
| | SILICONE, ADHESIVE-BACK | | | |
| 101850 | SWITCH, POWER, | 1 | ea | Eliminated |
| | GASKETED, | | | |
| | DIODE POINTER | | | |
| 100016 | O-RING, .208 X .070, VITON | 3 | ea | Eliminated |
| 101852 | O-RING, 4.379 X .070, | 1 | ea | Eliminated |
| | VITON | | | |
| 101851 | ASSY, FOLD MIRROR, 1″ | 2 | ea | Eliminated |
| 100031- | SUB-ASSY, 1″ OPTIC MOUNT, | 1 | ea | Eliminated |
| ILM- | HR & OC, TIP/TILT | | | |
| 001 | | | | |
| 101837 | BRACKET, FOLD MIRROR | 1 | ea | Eliminated |
| 101840 | MIRROR, 1″ X 6 mm, 45° AOI, | 1 | ea | Will be |
| | 99.9%, FS | | | QTY 2 |
| | | | | of this |
| | | | | part only |
| | | | | instead of |
| | | | | QTY 2 |
| | | | | of 101851 |
| | | | | assembly |
| 101324- | RETAINING RING, SM1 | 1 | ea | Eliminated |
| 001 | THREAD, 1″ OPTIC MOUNT, | | | |
| | STAINLESS STEEL | | | |
| 101322 | WASHER, WAVE, .78 ID X | 1 | ea | Eliminated |
| | 1.004 OD, .071 FREE HEIGHT | | | |
| 101848 | SCREW, FHP, 6-32 X .75 SS | 2 | ea | Eliminated |
| 101853 | SCREW, BHCS, ¼-20 X | 1 | ea | Eliminated |
| | .625, SS | | | |
| 100083 | SCREW, FHP, 6-32 X .3125 SS | 4 | ea | Eliminated |
| 100560 | BRACKET, INTERLOCK | 2 | ea | Eliminated |
| | SWITCH, RESONATOR | | | |
| 101857 | SCREW, FHP, M4 × 8 mm, | 4 | ea | Eliminated |
| | VITON O-RING, SS | | | |
| 100298 | LED, RED, 24 VDC, 16 mm | 1 | ea | |
| | PANEL MOUNT, | | | |
| | RESONATOR | | | |
| 100299 | LED, YELLOW, | 1 | ea | |
| | 24 VDC, 16 mm | | | |
| | PANEL MOUNT, | | | |
| | RESONATOR | | | |
| | | 1078.472 | QTYs | |
| | | | Total | |

The various optoelectronic components and assemblies in their respective pockets in an instant enclosure as described herein are to demonstrate the innovative aspects of the present design by way of example only. These components were required to operate an exemplary laser resonator. Depending on the implementation of the present principles, any other optoelectronic device and any types of components/assemblies required to operate it may be enclosed/integrated into an instant monolithic integrated enclosure of the present design.

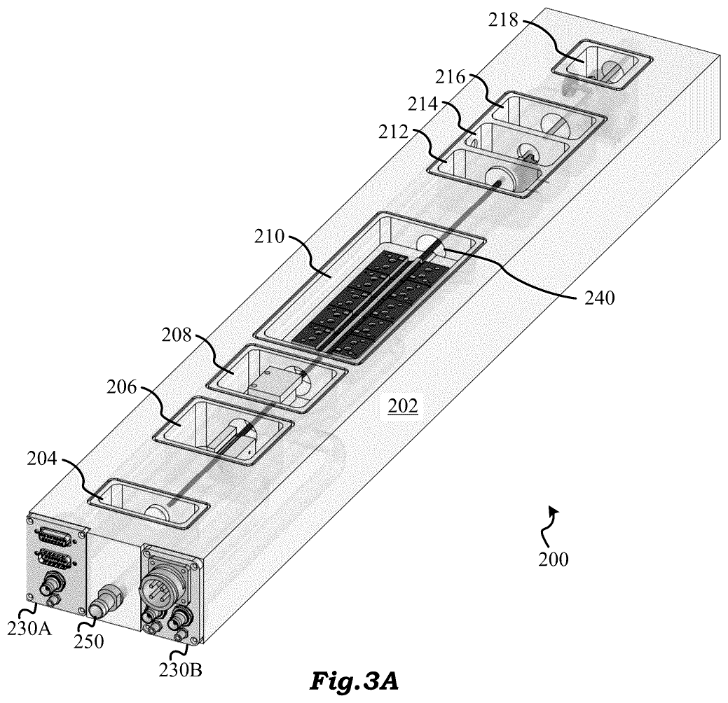

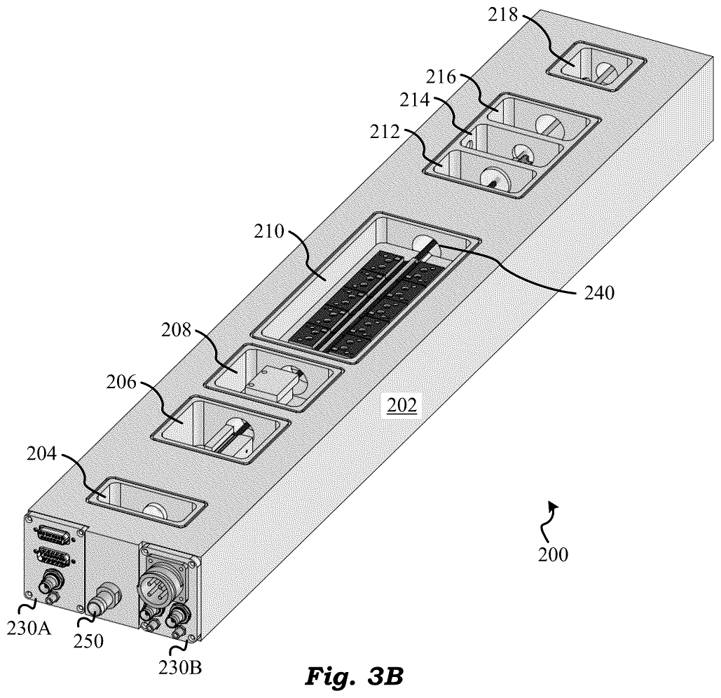

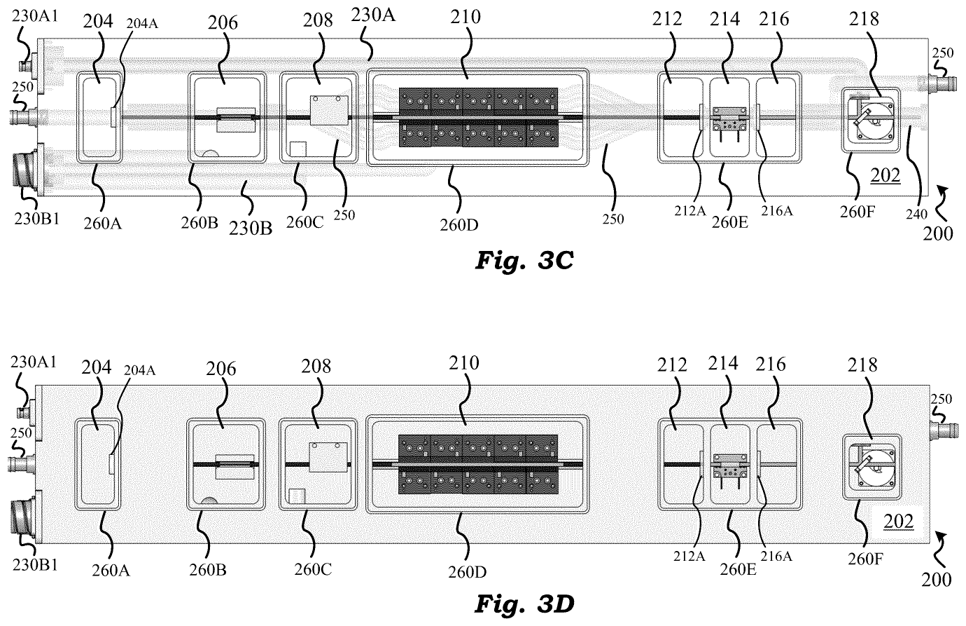

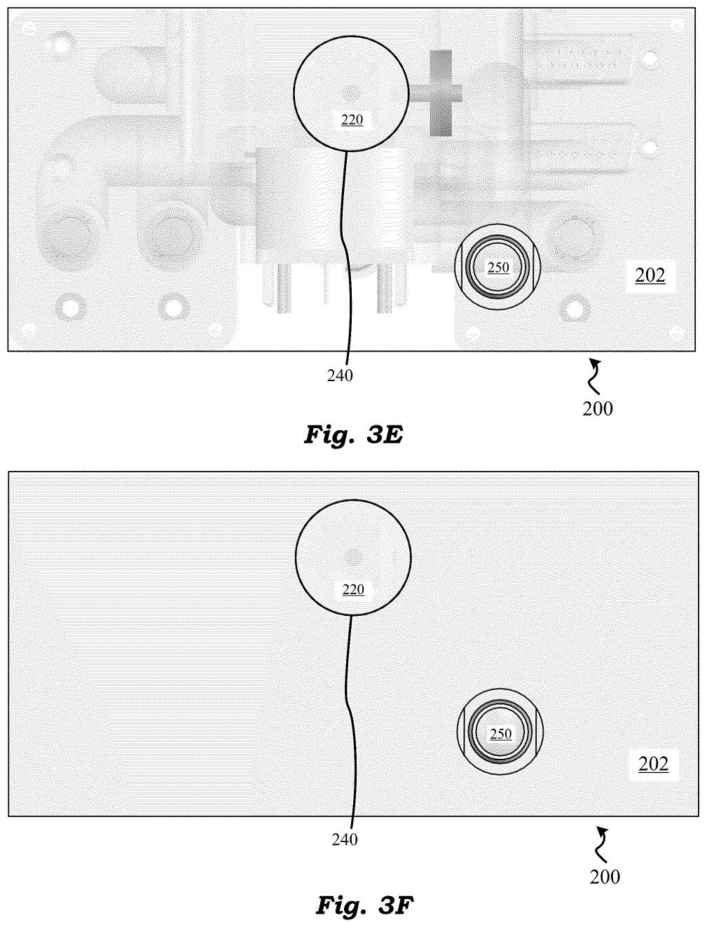

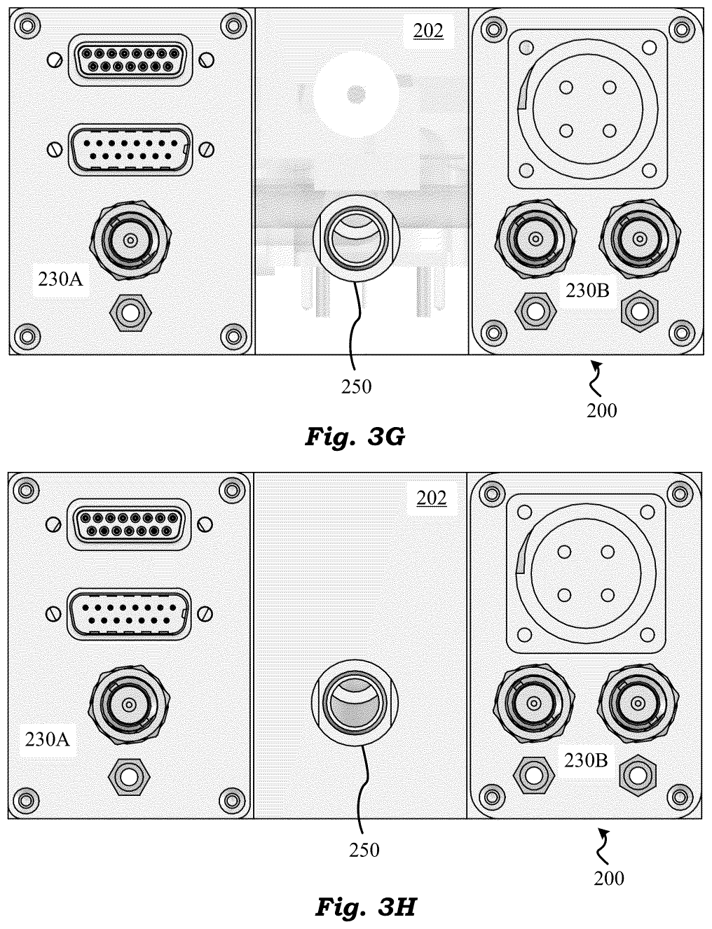

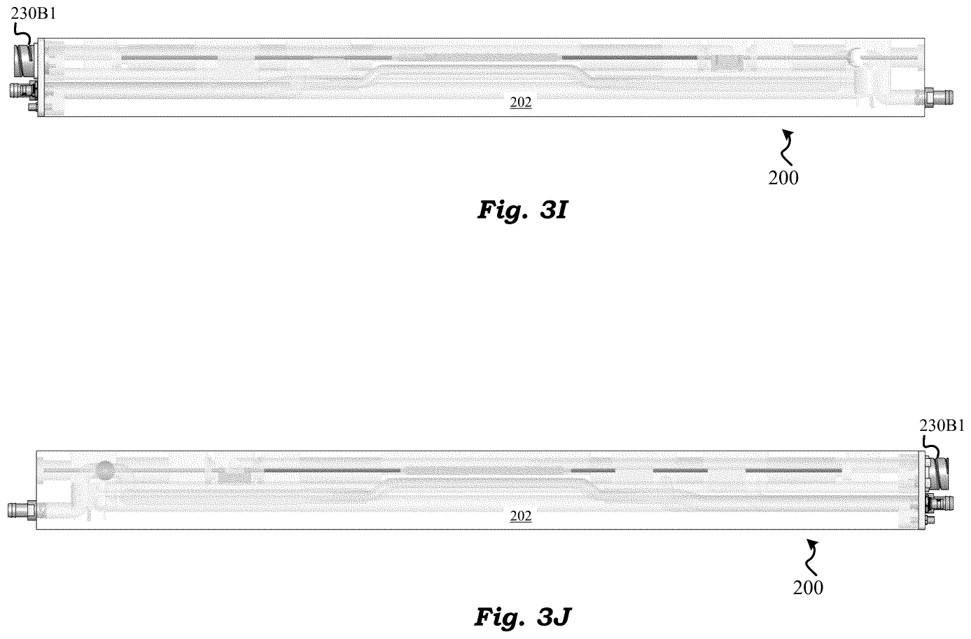

Let us now review another optoelectronic apparatus, device, tool, module, system, instrument or implement 200 integrated into or enclosed/encased/encapsulated/packaged/housed by a monolithic integrated enclosure 202 of the present design as shown in FIG. 3. Device 200 is an optoelectronic device and more specifically a laser generation module or laser resonator. Unlike folded laser resonator 101 of FIG. 2, laser resonator 200 is a straight or an in-line design. FIG. 3A and FIG. 3B respectively show its 3D transparent hidden-lines and solid trimetric views in instant enclosure 202.

In a manner analogous to the previous embodiments shown and discussed in referenced to FIG. 2, there are a number of pockets or cavities and channels designed or constructed into enclosure 202 of FIG. 3. More specifically, there is a pocket/cavity 204 in enclosure 202 in which an HR mirror for laser system 200 is integrated/attached/fastened/housed. There is a pocket 206 that integrates a vertical Q-switch, a pocket 208 that integrates a horizontal Q-switch, a pocket 210 that integrates a diode pump, a pocket 212 that integrates an SHG input mirror, a pocket 214 that integrates an SHG crystal, a pocket 216 that integrates an SHG output mirror and a pocket 218 that integrates a shutter assembly.

Furthermore, and referring to FIG. 3C and FIG. 3D, there is an HR mirror 204A seated against or bonded to a surface/face of pocket 204 as shown. Similarly, there are SHG input and output mirrors 212A and 216A respectively seated against or bonded to the crystal-facing surfaces/faces of pockets 212 and 216 as shown. The laser beam outputted by new shutter assembly in pocket 218 exits as output of laser resonator 200 at the right-hand side of FIG. 3C-D and through optic 220 as shown in FIG. 3E-F. Analogously to optic 122 of the embodiments of FIG. 2, optic 220 is a cover glass that is used to hermetically seal in-line laser apparatus/resonator 200.

There are also connection channels carrying optoelectronic connections or signals for device 200. The outer interfaces of these optoelectronic connections are provided on panels 230A and 230B as shown in FIG. 3A-B. There is an optical channel 240 serving as an optical path for the laser beam to propagate through. There is also a coolant channel 250 whose supply/inflow/ingress is shown and whose outflow/egress is on the far side and not visible in FIG. 3A-B. The outline of these channels can be seen in the interior of enclosure 202 in various views of FIG. 3 including FIG. 3A and FIG. 3C.

FIG. 3C shows a transparent top view of instrument 200 of FIG. 3A-B. Note that the outline of connection channel 230A carrying optoelectronic connections from interface panel 230A of FIG. 3A-B can be seen in the transparent view of FIG. 3C. Similarly, the outline of optoelectronic/optoelectric connection channel 230B in the interior of enclosure 202 carrying electronic/electrical/optical connections from interface panel 230B of FIG. 3A-B can be seen in the transparent view of FIG. 3C. Only two outer ports 230A1 and 230B1 belonging to panels 230A and 230B respectively are visible in the top view of FIG. 3C-D.

The outline of optical path or optical channel is also visible as marked by reference numeral 240 in FIG. 3C. Also visible is the outline of coolant channel 250 in the interior of monolithic enclosure 202 in the transparent view of FIG. 3C. Notice the ingress of coolant channel 250 on the left-hand side and the egress on the right-hand side of laser device 200. FIG. 3D shows a corresponding 3D solid view of the laser device/apparatus of FIG. 3C where various features of the enclosure are hidden by solid surfaces.

FIG. 3E and FIG. 3F show transparent and solid front views respectively of the in-line laser module of FIG. 3A-D. Only optical channel 240 and the egress of water/coolant channel 250 are explicitly marked in FIG. 3E-F for clarity. Similarly, FIG. 3G and FIG. 3H show 3D transparent and solid rear views respectively of laser module 200 of FIG. 3A-D. Electrical connection panels 230A and 230B, as well as ingress of coolant channel 250 are marked in FIG. 3G-H. Finally, FIG. 3I and FIG. 3J show transparent views of the two sides of optoelectronic apparatus 200 of FIG. 3A-H. Optoelectronic/optoelectrical interface ports 230A1 and 230B1 shown earlier in FIG. 3C-D and belonging to panels 230A and 230B respectively are marked in FIG. 3I-J.

Similarly to the embodiments discussed in reference to FIG. 2, not all the elements in various drawings of FIG. 3A-J are explicitly shown or marked by reference numerals for reasons of clarity. In a variation of the present embodiment, there is also a pulse width monitor or pulse width control submodule/function. The purpose of such a submodule which resides in its own pocket/cavity is to monitor and/or control the pulse width of the laser beam outputted from the new shutter assembly in pocket 218 of laser device 200.

In the most preferred embodiments, enclosures 100 and 200 of FIG. 2-3 are printed by a 3D-printer. In these preferred embodiments, respective 3D-models are first created for the instant monolithic enclosures, such as enclosures 100 and 200, using an appropriate modeling software. A 3D-model for an instant enclosure includes all the required features including pockets/cavities for the placement of components, connection channels, optical channels, coolant/cooling channels, recesses, threaded receptacles/boreholes or any other features that will be required by the final/end optoelectronic device to be integrated into the enclosure. The model can also be designed to any custom specifications based on the application needs of the present technology.

The model is then provided to the 3D-printer in order to print or generate an instant enclosure, such as enclosure 100/200 of FIG. 2/3 from an appropriate source material. Depending on the embodiment, the source material may take the form of a metallic precursor powder, a filament, blanks or any other appropriate form suitable for the 3D-printing technology employed. Alternatively, the source material may be a carbon-based material for printing carbon fiber or carbon nanotubes or graphene objects. The end result is enclosure 100 or 200 produced as a single or singular piece or structure or a “monolith”.

The preferred embodiments of the present design employs metal foam for the composition of its instant monolithic enclosures because of the many desirable properties of metal/metallic foam. Many of these properties are shared by carbon-based materials employed by alternative embodiments. The carbon-based materials include but are not limited to carbon fiber, carbon nanotubes and In preferred graphene. various embodiments, the metallic/metal foam comprises an appropriate metal including an alloy or a compound of aluminum, copper, nickel, titanium, steel, magnesium and zinc or another suitable material. The desirable properties of the above materials include but are not limited to high tensile strength, elevated stiffness/rigidity, light weight, high energy absorption and damping, high thermal insulation, large surface area.

In the present embodiments employing 3D-printing to print instant monolithic enclosures or simply instant enclosures 100/200 of FIG. 2-3, the 3D-printer preferably prints one or more infill patterns of a desired type into the enclosures. An instant enclosure, such as enclosure 100 that is composed out of a given source material or simply material which is preferably metal foam but may alternatively be a carbon-based material. Based on the instant principles and as per FIG. 2-3, such an instant enclosure has a built-in geometric structure and patterning employing empty spaces, instead of random/uncontrolled patterning or being a block of solid material. As a result, the infill pattern printed by the 3D-printer for enclosure 100 provides it a predictable density and strength. Depending on the type and sizing of the pattern, a variety of densities and geometrical shapes of infill patterns are possible for instant enclosures.

Regardless of the type and density of the infill pattern, the channels in the instant enclosures that are required to carry a fluid, such as coolant channels 150 and 250 of FIG. 2 and FIG. 3 respectively, have a solid or non-porous or sealed or impermeable inside surface. If that were not the case, the fluid would leak through the enclosure-unless of course the enclosure has a 100% density. Such a design assures that the coolant channels are thus hermetically sealed and leak-proof.

Preferably, the inside surfaces of all the features, including the pockets and the channels are also impermeable/non-porous. Preferably, the inside surfaces are also smooth as well as non-porous/impermeable. Furthermore, any other internal/external surfaces of the enclosure are also solid and smooth for bonding, and for aesthetic purposes. With the covers for the cavities/pockets attached per above teachings, this results in the entire apparatus being hermetically sealed.

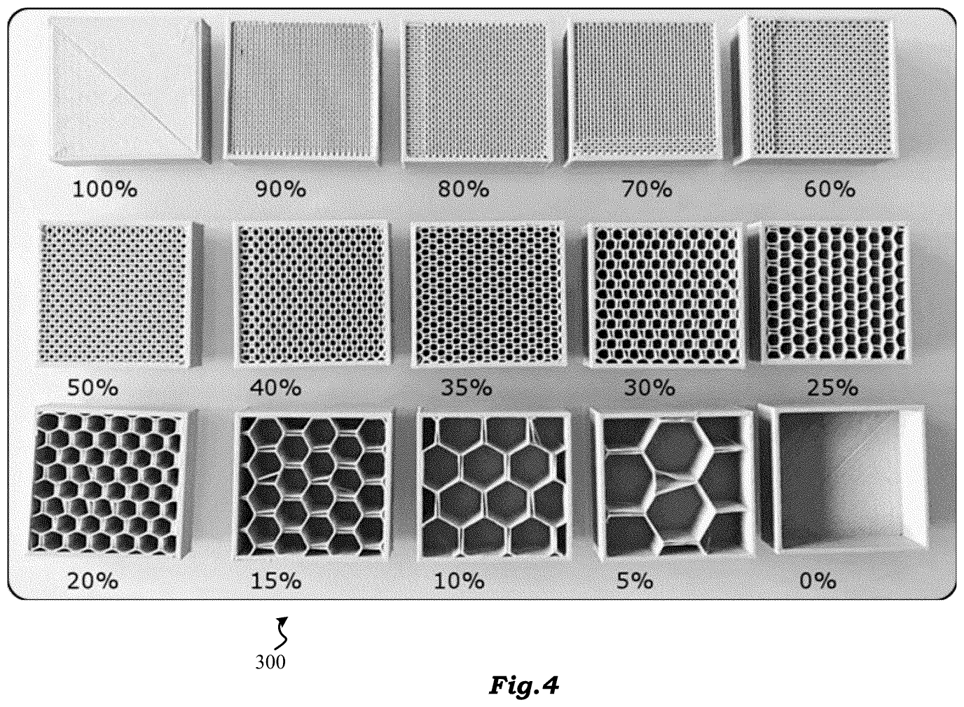

FIG. 4 shows a picture of exemplary infill patterns 300 for enclosures 100/200 of FIG. 2-3 with a variety of densities or porosities that may be printed for the enclosures. Evidently, a density of 100% will produce a purely solid enclosure, whilst a density of 0% is merely shown for theoretical completeness and will be impractical.

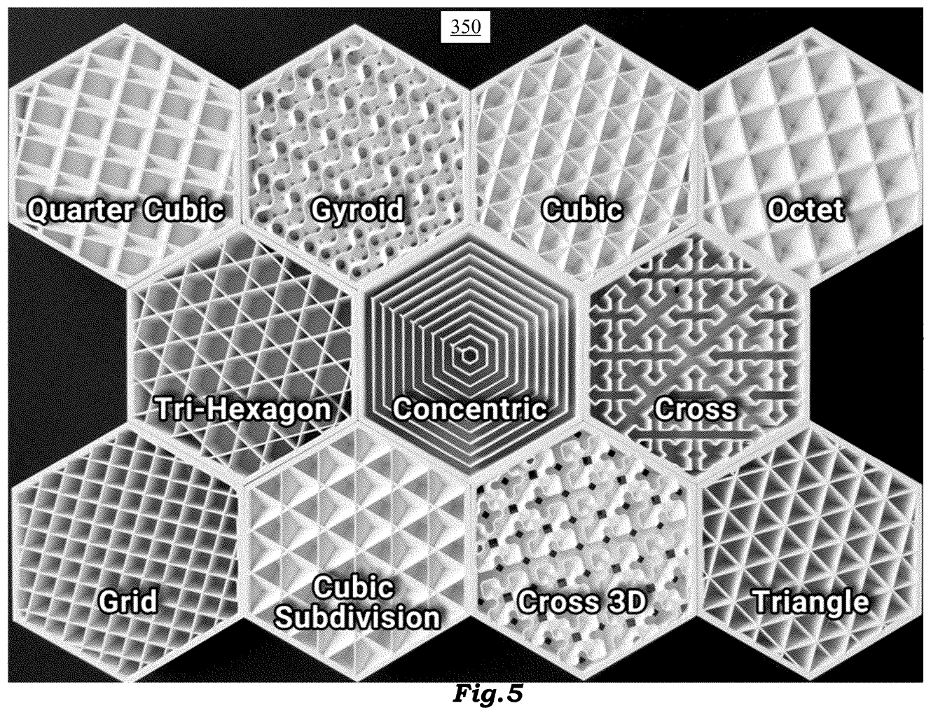

FIG. 5 shows a picture of exemplary infill pattern types or geometric shapes 350 for enclosures 100/200 of FIG. 2-3 with a variety of shapes that may be printed for the enclosures. Any of these shapes and a desirable density may be chosen for enclosure 100 or 200 depending on the application of the present techniques.

In alternative embodiments, the instant monolithic enclosure is produced by other manufacturing techniques rather than 3D-printing. Thus, in one alternate embodiment, the present enclosure may also be machined from a slab of the source material, preferably metal foam. The metal foam slab may itself have a desired infill pattern. Those skilled in the art will appreciate that metal machining is a subtractive manufacturing process for shaping metal workpieces into desired forms by removing material from the workpiece. Metal machining involves the use of cutting tools and machinery to cut, drill, grind, or otherwise remove excess material from the metal workpiece, resulting in the final product with the required shape, dimensions, and surface finish.

Exemplarily in the present metal foam-based embodiments, an instant enclosure is machined by utilizing the following machining steps:
1. Setup: The metal foam slab with the desired porosity and infill pattern is securely mounted on the machining equipment, such as a lathe, milling machine, or a Computer Numerical Control (CNC) machine.
2. Tooling: Depending on the complexity of the instant monolithic enclosure, different types of cutting tools may be chosen depending on the machining operation and the metal foam being employed. Exemplarily, the tools may include drills, end mills, turning tools, reamers, and any other tools.
3. Cutting: The cutting tool subtracts or removes material from the workpiece following a predetermined path and at specific depths or feed rates.
4. Chip cleaning: As the cutting tool removes material, chips (small pieces of metal) are formed and must be effectively evacuated to prevent interference with the machining process.
5. Different machining operations: Depending on the enclosure, various types of machining operations can be performed, including turning, milling, drilling, grinding, boring, and threading, among others.
6. Finishing: After the primary machining operations are completed, additional finishing techniques known in the art may be applied to achieve the desired surface texture and accuracy.

Per above teachings, it is important that the inside surfaces of all features, and especially the coolant channels, are impermeable or non-porous. For this purpose, and as/if needed, a separate finishing step may be performed at the end. Exemplarily, such a step may involve applying liquid metal or another suitable material to the desired inside surfaces. Alternatively, closed cell metal foam slabs/materials may also be employed in the present embodiment and from which an instant enclosure is machined.

Metal machining can be performed manually by skilled operators using conventional machines or through computer-controlled processes using CNC machines. CNC machining offers greater precision, repeatability, and the ability to produce complex shapes with high efficiency.

Still alternatively, the instant monolithic enclosure of the present metal foam-based embodiments may be produced by a casting process that utilizes liquid metal foam poured into a mold to produce the instant enclosure. Exemplarily, such a casting process involves the following steps:
1. Mold creation: The first step is the creation of a mold for an instant enclosure that contains all its features, whether they are easily accessible or hidden/obscured. It is also possible that some of the features are machined into the enclosure after casting. The mold may be made of sand, plaster, ceramic, or other refractory materials, depending on the complexity of the instant enclosure and the metal being cast.
2. Melting the metal: The metal foam compound or alloy is heated to a molten state.
3. Pouring: Once the metal is molten, it is poured into the mold through a gating system. The gating system allows the metal to flow smoothly into the mold and helps to avoid any defects. Some of the features of the enclosure and consequently of its mold may be hard to access. It is therefore important to ensure that molten metal reaches all the features. Mechanical vibrations, or other metal pouring techniques may be required to accomplish this.
4. Solidification: As the molten metal cools down, it solidifies and takes the shape of the mold of the enclosure. The cooling rate and solidification time determine the quality and properties of the final casting.
5. Further cooling and removal: After solidification, the casting is allowed to cool further. Once it has solidified completely, it is removed from the mold, and any excess material including gates and risers are trimmed off.
6. Finishing: The final step involves removing any remaining imperfections, such as burrs or rough edges, and applying surface treatments or coatings to enhance the properties of the casting. At this stage additional features may be machined into the instant enclosure as needed.

More specifically for the present metal foam embodiments, one of the following methods may be used to create metal foam from molten metal: Gas Injection Method, Powder Metallurgical Method, Replication Method, Hollow Sphere Method, Direct Foaming Method, Electrodeposition Method, Centrifugal Process Method.

Per above teachings, it is important that the inside surfaces of all features, and especially the coolant channels, are impermeable or non-porous. For this purpose, and as/if needed, a separate finishing step may be performed at the end. Exemplarily, such a step may involve applying liquid metal or another suitable material to the desired inside surfaces. In still other embodiments, the instant enclosures may be produced by a combination of 3D-printing, machining and casting techniques.

In various preferred embodiments employing metal foam based instant enclosures, the metal foam comprises an aluminum compound or alloy. Alternatively, the metal foam may comprise any other suitable metal compounds or alloys including those of copper, nickel, titanium, steel, magnesium and zinc or a combination of the above.

Alternative embodiments employing carbon-based materials for producing the instant enclosures, may employ any or a combination of available of techniques that are suitable for the formation, manufacturing or 3D-printing of the carbon-based material. Thus, a carbon fiber-based instant enclosure may be 3D-printed analogously to an instant metal foam enclosure according to the teachings provided herein. A carbon nanotubes-based instant enclosure may employ one or more of the following manufacturing techniques: Arc Discharge (Carbon Arc Method), Laser Ablation, Floating Catalyst Method, Plasma Enhanced Chemical Vapor Deposition (PECVD) and Electrochemical Deposition. A graphene-based instant enclosure may employ one or more of the following manufacturing techniques: Mechanical Exfoliation (Scotch Tape Method), Chemical Vapor Deposition (CVD), Liquid-Phase Exfoliation (LPE), Oxidation-Reduction Method), (Hummers' Chemical Synthesis (Bottom-Up Approach), Epitaxial Growth and Plasma Enhanced Chemical Vapor Deposition (PECVD).

The present technology of creating a monolithic enclosure can be used for integrating or encapsulating or encasing various types of devices employing a variety of components including electronic components, electrical components, mechanical components or a combination of the above. Optoelectronic or optoelectrical devices utilizing optical and electronics/electrical components are particularly suited for the present design.

This is because the housing, mounting, alignment and maintenance/upkeep of optical elements cause a variety of hardships in the prevailing art. These difficulties are either completely eliminated or substantially alleviated by the present design. Per above teachings, an instant monolithic enclosure includes integrated optics pre-aligned or pre-registered to each other, a sealed optical channel/path, coolant/cooling channels, connection/wiring channels, and electronics. Thus, the present design eliminates the laborious step of alignment/registration required in the prior art.

The various source materials for the instant enclosure provided herein, also allow for the enclosure to be lightweight, robust, and hermetically sealed. This reduces the need for additional optical mounts, housings, dust tubes, and dust couplers. Further, the integrated design greatly reduces part count and inventory requirements, leading to reduced production time and cost per above discussion. The present enclosure affords guaranteed alignment, power, and pulse width even under rough handling, thus reducing the need for shipping or handling precautions.

The present invention provides an innovative and efficient method of manufacturing and using industrial laser systems. It not only provides a cost-effective solution but also guarantees better performance and ease of use compared to existing systems. While the invention has been described with respect to a limited number of embodiments, these should not be construed as limitations on the scope of the invention, but rather as exemplifications of some of the preferred embodiments. Other possible variations, modifications, and applications are also within the scope of the invention.

Further, while the invention has been described using specific terms and examples, it is to be understood that the terminology used is for the purpose of describing particular embodiments only and is not intended to limit the scope of the invention. It will be obvious to those skilled in the art that various changes may be made without departing from the scope of the invention, and the invention is not to be considered limited to what is shown in the description and drawings.

In general, the instant design accrues a number of benefits to a practitioner. These benefits of instant monolithic enclosures apply universally to any type of laser or any optoelectronic apparatus in general, and include:

### 1. Light Weight:

Achieving approximately one-tenth the weight of similar or equivalent prior art optoelectronic systems. Notice again the dramatic elimination of parts from Table 3 for the folded laser resonator. Per above teachings, the flexibility of choosing various densities and types of infill patterns allows a practitioner to control the robustness and weight of the enclosure.

### 2. Extremely Reliable:

The dramatic reduction in the number of parts and the simplicity of the end product/system means less points of failure and overall increase in reliability.

### 3. Extreme Mechanical Stability:

Source material, such as metal foam affords an extremely high level of rigidity and mechanical stability to the optoelectronic devices based on the present technology than the honeycomb-based systems of the prior art.

### 4. Extreme Optical Stability:

As explained above, the optoelectronic components in an instant enclosure are a lot less prone to misalignment as compared to prior art. Moreover, the dramatic reduction in the number of parts means less points of failure and overall increase in the reliability of the system.

### 5. Extreme Energy Absorption:

An instant enclosure can absorb a lot more energy as compared to the air-filled honey-comb based designs of the prior art.

### 6. Extreme Vibration Absorption:

The optoelectronic apparatus is integrated or embedded directly into the instant enclosure, because there are no separate mounts and housings for the components. As a result, the apparatus has a lot more rigidity and the ability to absorb shocks and vibrations as compared to the prior art.

### 7. Excellent Heat Transfer Stability:

The entire enclosure of the present design acts as a heat sink with a lot bigger surface area for heat transfer than prior techniques. This results in a lot more efficient cooling of the heated components than otherwise possible.

### 8. Excellent Electromagnetic Interference (EMI) Shielding:

The instant enclosure also acts as an excellent EMI shield for the integrated components as compared to the air-filled designs of the prior art.

### 9. Hermetically Sealed:

Per above, since the inner surfaces of all the features are impermeable, this results in the entire apparatus being hermetically sealed once covers are applied to the pockets.

### 10. Lower Height and Extremely Small Footprint:

Recall from FIG. 1D that in the prior art techniques, the honey comb plate is kept high or thick in order to afford rigidity to the apparatus. That is no longer the case with the instant enclosure in which the apparatus is integrated or embedded. This results in a substantially thinner apparatus with a much smaller footprint/height and of course weight. Elimination of the separate housings and mounts further reduces the footprint and weight of the enclosure as the optics are mounted inside the instant rigid enclosure or platform itself.
   11. Integrated Optics with all Optical Faces Pre-Aligned to Each Other by the Enclosure:
Per above, there is no longer a need for a separate alignment step as the optics of the optoelectronic components are bonded to the faces/walls of the instant enclosure in an aligned posture/position. As a result of being integrated into the enclosure, the components are pre-aligned or pre-registered to each other, or just pre-aligned for short, within or by the enclosure. This obviates the need for a separate step of alignment or registration.

### 12. Can be Frequency Doubled, Tripled, or Quadrupled or More:

The robust mechanical nature of the present design imparts a high degree of optical precision to the components. As a result, despite its compact size/structure, the apparatus can be easily configured/upgraded to be frequency-multiplied. That means it can easily be frequency-doubled, frequency-tripled, frequency-quadrupled or to a higher frequency multiple, as well as being able to produce ultrafast lasers. This is a major improvement of the present design over the prior art.

### 13. Simple Diode-Pumped Slab:

A monolithic enclosure of the present design greatly simplifies the optoelectronic circuitry required for the various components of the laser apparatus. Per above, the DPM is also greatly simplified based on a much simpler diode pump design whereby the requisite number of diodes are used to drive a simple diode-pumped slab. Recall the new DPM in pockets 110 and 210 of FIG. 2 and FIG. 3 respectively as compared to complex DPM assembly and its subassemblies of the prior art of FIG. 1.

### 14. Alignment, Power, and Pulse Width Stability are Guaranteed:

The precise alignment of the optics and mechanical rigidity of the device results in a lot more stable operation than the prior art. This greatly reduces variability in the pulse width of the output laser beam and its consequent power.

### 15. Low Water PSI Operation:

Because of the highly efficient heat exchange characteristics of the present enclosure, the pressure requirement for the coolant/water flow is greatly reduced. Exemplarily, the required pounds per square inch (PSI) of the water pressure is reduced from a range of 40-60 PSI in the prior art to 5-10 PSI in the present design.

### 16. Deionized Water Unnecessary:

As noted, the present enclosure has excellent heat exchange/transfer properties. Further, per the instant design, water/coolant does not come into contact or flow through the optical path or optical flow tube. Nor is the water/coolant required to cool a cylindrical laser rod, the laser rod itself, or the laser diodes as in the prior art. As a result, a practitioner can use non-deionized or simply tap water for cooling the apparatus integrated in/into/inside an instant enclosure. This further results in parts reduction of the cooler and in operational cost savings.

### 17. Dust Tubes and Dust Couplers Unnecessary:

This is because the system is hermetically sealed per above.
   18. Much lower shipping cost:
Per above discussion, the present approach greatly reduces the weight and footprint of the apparatus. This often results in obviating the need for a specialized freight company for shipping, thus further improving business economics.

The benefits of the present design further include:
19. Integrated sealed optical path
20. Integrated coolant/cooling channels
21. Integrated connection/wiring channels and cable management
22. Integrated electronics
23. Optical mounts unnecessary
24. Optical housings unnecessary
25. No internal water hoses/lines/tubing or risk of leaks
26. Extremely robust/ruggedized end apparatus
27. Greatly reduced part count and inventory requirements
28. Greatly reduced production time and cost
29. Alignment of optics resilient to disturbances caused by shipping and rough handling since the optics are pre-aligned by the instant enclosure itself, per above teachings.

The prior art of FIG. 1 as well as the laser devices in instant enclosures of FIG. 2 and FIG. 3 are nanosecond lasers, which are chosen for elucidating the instant principles for the sake of simplicity only. lasers Ultrafast such as picosecond, femtosecond and attosecond lasers are much more complex, with many more components and mounts, and are more critical in the alignment, and will benefit even more from the present technology.

It is possible to have a plurality of instant monolithic enclosures for a single optoelectronic system. In such a scenario, utilizing known techniques, a subset or all of the plurality of instant monolithic enclosures may be strongly or loosely connected to each other mechanically, or may not be connected to each other at all. Regardless, in order to accrue the benefits of the present principles, it is imperative to have an individual optoelectronic module of the larger optoelectronic system to be integrated into a single monolithic enclosure.

This way, the mechanical advantages including rigidity, robustness and other technical benefits of the instant design can be imparted to the specific optoelectronic module in a (single) monolithic enclosure. For instance, a separate alignment step for the optoelectronic components of that module will not be required per above teachings.

The present techniques may also be used to produce enclosures for any devices that have a large number of mechanical components. They may be used to produce monolithic integrated enclosures that integrate power supply/supplies for the end optoelectronic system/device as well as its cooling system(s). In addition, the typically separate power supply/control assembly and cooler assembly can both be integrated into one extremely light-weight 3D-printed enclosure. The water tank, heat exchanger, filter housings, pump housing, cooling channels, and the plumbing connections between them can all be 3D-printed into the enclosure itself.

Furthermore, all the electronics, power supplies, and control circuitry can be mounted around the sides of this integrated cooling enclosure using 3D-printed mounting holes, pockets, and cavities as needed. These electronic components can be conduction cooled by the 3D-printed water tank and the cooling channels that they are surrounding. All the electrical connections between the electronic components can be routed through 3D-printed channels integrated into the enclosure itself. This design eliminates the requirement for fans and heatsinks, making the electronic components themselves much more compact as well as the overall enclosure more compact and light-weight.

In view of the above teachings, a person skilled in the art will recognize that the methods of present invention can be embodied in many different ways in addition to those described without departing from the principles of the invention. Therefore, the scope of the invention should be judged in view of the appended claims and their legal equivalents.

What is claimed is:

1. A monolithic enclosure comprising:
(a) one or more pockets for integrating components of an optoelectronic system;
(b) at least one connection channel for connecting two or more of said components;
(c) at least one optical channel for propagating light between two or more of said components; and
(d) at least one coolant channel for transporting a coolant to and from at least one of said components.

2. The monolithic enclosure of claim 1 composed of a material including a metal foam, carbon fiber, carbon nanotubes and graphene.

3. A monolithic enclosure comprising:
(a) one or more pockets for integrating components of an optoelectronic apparatus;
(b) at least one connection channel for connecting two or more of said components;
(c) at least one optical channel for propagating light between two or more of said components; and
(d) at least one coolant channel for transporting a coolant to and from at least one of said components;
wherein said monolithic enclosure is composed of a metallic foam.

4. The monolithic enclosure of claim 3 wherein said coolant is non-deionized water.

5. The monolithic enclosure of claim 3 wherein said metallic foam is composed of a metal comprising aluminum, copper, nickel, titanium, steel, magnesium and zinc.

6. The monolithic enclosure of claim 3 wherein said optoelectronic apparatus is a laser module.

7. The monolithic enclosure of claim 3 wherein a plurality of optics of said components are pre-aligned by said monolithic enclosure.

8. The monolithic enclosure of claim 3 printed by a 3D-printer.

9. The monolithic enclosure of claim 8 wherein said 3D-printer prints an infill pattern in said monolithic enclosure, said infill pattern chosen in accordance to an application of said optoelectronic apparatus.

10. The monolithic enclosure of claim 8 wherein a 3D-model of said monolithic enclosure is used by said 3D-printer for printing said monolithic enclosure.

11. The monolithic enclosure of claim 3 machined from a slab of said metallic foam.

12. The monolithic enclosure of claim 3 produced from a casting poured with said metallic foam.

13. A method comprising the steps of:
(a) integrating components of an optoelectronic device into one or more cavities of a monolithic enclosure;
(b) connecting two or more of said components via a first channel of said monolithic enclosure;
(c) propagating light between two or more of said components in a second channel of said monolithic enclosure; and
(d) transporting in a third channel of said monolithic enclosure, a coolant to and from at least one of said components.

14. The method of claim 13 providing said coolant to be non-deionized water.

15. The method of claim 13 providing said monolithic enclosure to be composed of a material including a metal foam, carbon fiber, carbon nanotubes and graphene.

16. The method of claim 13 producing said monolithic enclosure by one of a metal casting process and metal machining process.

17. The method of claim 13 printing said monolithic enclosure by a 3D-printer.

18. The method of claim 17 printing by said 3D-printer an infill pattern of said monolithic enclosure, and choosing said infill pattern according to an application of said optoelectronic device.

19. The method of claim 13 wherein said optoelectronic device is a laser device.

20. The method of claim 13 pre-aligning by said monolithic enclosure a plurality of optics of said components.
